(19) United States
(12) Patent Application Publication
(10) Pub. No.: US 2009/0242012 A1
(43) Pub. Date: Oct. 1, 2009

(54) Method and system for converting light to electric power

(75) Inventor: Jordin T. Kare, Seattle, WA (US)

Correspondence Address: IV - SUITER SWANTZ PC LLO, 14301 FNB PARKWAY , SUITE 220, OMAHA, NE, 68154, US

(73) Assignee: Searete LLC, a limited liability corporation of the State of Delaware

(21) Appl. No.: 12/322,606

(22) Filed: Feb. 4, 2009

Related U.S. Application Data
(63) Continuation-in-part of application No. 12/229,719, filed on Aug. 26, 2008.
Application No. 12/229,719 is a continuation-in-part of application No. 12/313,026, filed on Nov. 14, 2008.
Application No. 12/313,026 is a continuation-in-part of application No. 12/313,007, filed on Nov. 14, 2008.
Application No. 12/313,007 is a continuation-in-part of application No. 12/313,009, filed on Nov. 14, 2008.
Application No. 12/313,009 is a continuation-in-part of application No. 12/313,022, filed on Nov. 14, 2008.
Application No. 12/313,022 is a continuation-in-part of application No. 12/322,611, filed on Feb. 3, 2009.
(60) Provisional application No. 60/999,817, filed on Oct. 18, 2007.

(51) Int. Cl. H01L 31/052

(52) U.S. Cl. 136/246; 136/244

(57) ABSTRACT

A method and system for converting light to electric power including coupling in parallel at least two devices in a first plurality of devices suitable to convert light to electric power, coupling in parallel at least two devices in at least one additional plurality of devices suitable to convert light to electric power, and coupling in series the first plurality of devices suitable to convert light electricity with the at least one additional plurality of devices suitable to convert light to electric power. A method for converting electromagnetic flux to electric power. A method for optimizing the electric power output of a system including determining the expected illumination pattern of incident laser radiation, and optimizing the amount of laser radiation incident on the surface of the devices suitable to convert light to electric power by distributing the devices according to the expected illumination pattern of the incident laser beam.

### CROSS-REFERENCE TO RELATED APPLICATIONS

The present application constitutes a regular (non-provisional) patent application of U.S. Patent Provisional Application No. 60/999,817, entitled PHOTOVOLTAIC ARRAY, naming JORDIN T. KARE as inventor, filed 18 Oct. 2007.

### BACKGROUND

Known in the art of electrical power generation are various devices and methods used for the conversion of light to electric power. For example, photovoltaic devices, thermovoltaic devices, thermophotovoltaic devices, optical rectenna devices and the like are known to convert light to electric power. Furthermore, the conversion of light to electric power using series coupled light-to-electric power converting devices is known.

### SUMMARY

In one aspect, a method for converting light to electric power includes but is not limited to coupling in parallel at least two devices in a first plurality of devices suitable to convert light to electric power, coupling in parallel at least two devices in at least one additional plurality of devices suitable to convert light to electric power, and coupling in series the first plurality of devices suitable to convert light electricity with the at least one additional plurality of devices suitable to convert light to electric power.

In another aspect, a method for converting electromagnetic flux to electric power includes but is not limited to electrically coupling at least a first set of parallel paths, combining in series the electrically coupled first set of parallel paths with at least one additional set of parallel coupled paths, receiving a portion of electromagnetic flux and providing electric power to the first set of coupled parallel paths, and receiving a portion of electromagnetic flux and providing electric power to at least one additional set of coupled parallel paths.

In another aspect, a method for optimizing the electric power output of a system includes but is not limited to determining the expected illumination pattern of the incident laser radiation, and optimizing the amount of laser radiation incident on the surface of the devices suitable to convert light to electric power by distributing the devices according to the expected illumination pattern of the incident laser beam.

In addition to the foregoing, other method aspects are described in the claims, drawings, and text forming a part of the present disclosure.

In one or more various aspects, related systems include but are not limited to circuitry and/or programming for effecting the herein referenced method aspects; the circuitry and/or programming can be virtually any combination of hardware, software, and/or firmware configured to effect the herein referenced method aspects depending upon the design choices of the system designer.

In one aspect, a system includes but is not limited to a system suitable for converting light to electric power having a first plurality of devices suitable to convert light to electric power, at least two devices of the first plurality of devices suitable to convert light to electric power are coupled in parallel, at least one additional plurality of devices suitable to convert light to electric power, at least two of the devices of the at least one additional plurality of devices suitable to convert light to electric power are coupled in parallel, in which the first plurality of devices suitable to convert light to electric power and the at least one additional plurality of devices suitable to convert light to electric power are coupled in series.

In addition to the foregoing, other system aspects are described in the claims, drawings, and text forming a part of the present disclosure. In addition to the foregoing, various other method and/or system and/or program product aspects are set forth and described in the teachings such as text (e.g., claims and/or detailed description) and/or drawings of the present disclosure.

The foregoing is a summary and thus may contain simplifications, generalizations, inclusions, and/or omissions of detail; consequently, those skilled in the art will appreciate that the summary is illustrative only and is NOT intended to be in any way limiting. Other aspects, features, and advantages of the devices and/or processes and/or other subject matter described herein will become apparent in the teachings set forth herein.

### BRIEF DESCRIPTION OF THE FIGURES

FIG. 1 is a schematic illustrating the parallel coupling of a first device and a second device in a first plurality of devices suitable to convert light to electrical power and the series coupling of the first plurality of devices with an additional plurality of devices;

FIG. 2 is a flow diagram illustrating the first and second devices of the first plurality of devices may be adapted to receive light from a light source;

FIG. 3 is a flow diagram illustrating the first and second devices of the first plurality of devices may be adapted to receive light transmitted through a transmission medium;

FIG. 4 is a flow diagram illustrating the types of light-to-electric power conversion devices;

FIG. 5 is a schematic illustrating the construction of a device of the first set of devices from a series coupled set of devices suitable to convert light to electrical power;

FIG. 6 is a flow diagram illustrating the first and second devices of the first plurality of devices may have different characteristic properties;

FIG. 7 is a flow diagram illustrating the characteristics of the first device of the first plurality of devices may vary in response to an operating characteristic;

FIG. 8 is a flow diagram illustrating the first and second devices of the first plurality of devices having different surface normal orientations;

FIG. 9 is a schematic illustrating the parallel coupling of a first device and a second device in a first plurality of devices suitable to convert light to electrical power and the series coupling of a first plurality of devices with a second plurality of devices using at least one electrical connection between at least one device of the first plurality of devices and at least one device of the second plurality of devices;

FIG. 10 is a flow diagram illustrating the first and second devices of the first plurality of devices suitable to convert light to electric power may be adapted to receive light processed by an optical device;

FIG. 11 is a schematic illustrating the distribution of one device of the first plurality of devices, one device of a second plurality of devices, one device of a third plurality of devices and one device of a fourth plurality of devices in a first spatially discrete region and distributing one device of the first plurality of devices, one device of a second plurality of devices, one device of a third plurality of devices, and one device of a fourth plurality of devices, where the first spatially discrete region and the second spatially discrete region define a substantially contiguous receiving region;

FIG. 12 is a table illustrating spatial positions of the devices of the first plurality of devices suitable to convert light to electric power;

FIGS. 13A and 13B are flow diagrams illustrating the coupling of the first plurality of devices suitable to convert light to electric power with an energy storage device, energy storage protection circuitry, energy storage switching circuitry, operational protection circuitry and power management circuitry;

FIG. 14 is a schematic illustrating the parallel coupling of a bypass diode with the first plurality of devices, the parallel coupling of a bypass diode with the second plurality of devices, the parallel coupling of a bypass diode with the Mth plurality of devices, the series coupling of a fuse with the second device of the first plurality of devices, the series coupling of a fuse with the third device of the first plurality of devices, the series coupling of a fuse with first device of the second plurality of devices, the series coupling of the fourth device of the second plurality of devices, and the series coupling of a fuse with the Nth device of the Mth plurality of devices.

FIG. 15A is a flow diagram illustrating the coupling of the first and/or the additional plurality of devices suitable to convert light to electric power with one or more than one reserve device suitable to convert light to electric power and the coupling of the first and/or the additional plurality of devices suitable to convert light to electric power with a combination of one or more than one reserve device suitable to convert light electric power and reserve actuation circuitry;

FIG. 15B is a schematic illustrating the coupling of the first and/or the additional plurality of devices suitable to convert light to electric power with a combination of one or more than one reserve device suitable to convert light electric power and reserve actuation circuitry.

FIG. 16 is a high-level flowchart of a method for converting light to electric power;

FIG. 17 through 68 are high-level flowcharts depicting alternate implementations of FIG. 16;

FIG. 69 is a high-level flow chart of a method for converting electromagnetic flux into electric power;

FIG. 70 is a high-level flowchart depicting alternate implementations of FIG. 69; and

FIG. 71 is a high-level flowchart of a method for optimizing the electric power output of a system.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here.

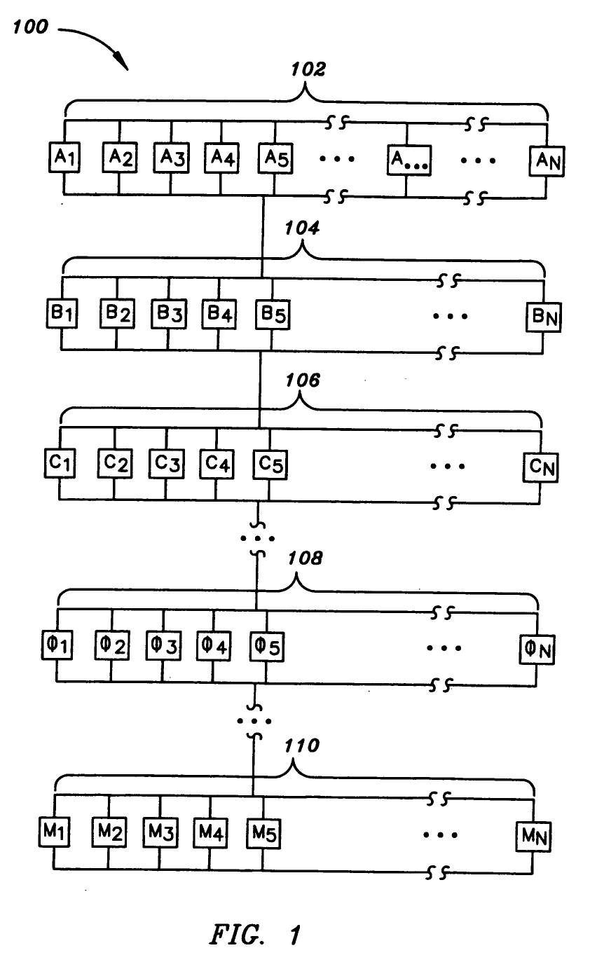

Referring generally to FIGS. 1 through 15, a system 100 for converting light to electric power is described in accordance with the present disclosure. The system 100 for converting light to electric power may include a first set 102 of devices suitable to convert light to electric power electrically coupled in series to a second set 104 of devices suitable to convert light to electric power. In a further embodiment, the system 100 may include an additional set of devices, up to and including an Mth set 110 of devices suitable to convert light to electric power. Further, the sets of devices, for example the first set of devices 102, may include a first device (e.g. A₁) suitable to convert light to electric power parallel coupled to a second device (e.g. A₂) suitable to convert light to electric power. In a further embodiment, the sets of devices 102-110 may include additional devices suitable to convert light to electric power, up to and including an Nth device (e.g. A_{N}). In an embodiment, the first device A₁ of the first set of devices 102 may have a first shape (e.g. square, rectangle, parallelogram, polygon, ellipse, circle, or irregular shape) and the second device A₂ of the first set of devices 102 may have a second shape different than the first shape. In an additional embodiment, the first device A₁ of the first set of devices 102 may have a first surface area and the second device A₂ may have a second surface area different than the first surface area.

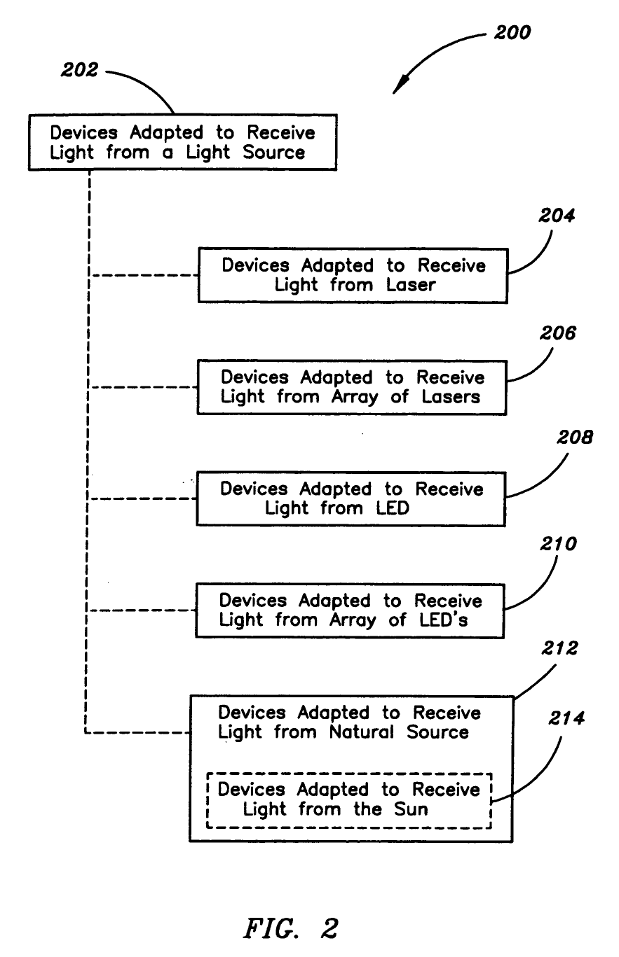

In an embodiment illustrated in FIG. 2, the system 100 suitable to convert light to electric power includes devices adapted to receive light from a light source 200. For example, the light source may include a laser 204, an array of lasers 206, a light emitting diode (LED) 208, an array of LEDs 210, and a natural light source 212, such as the Sun 214.

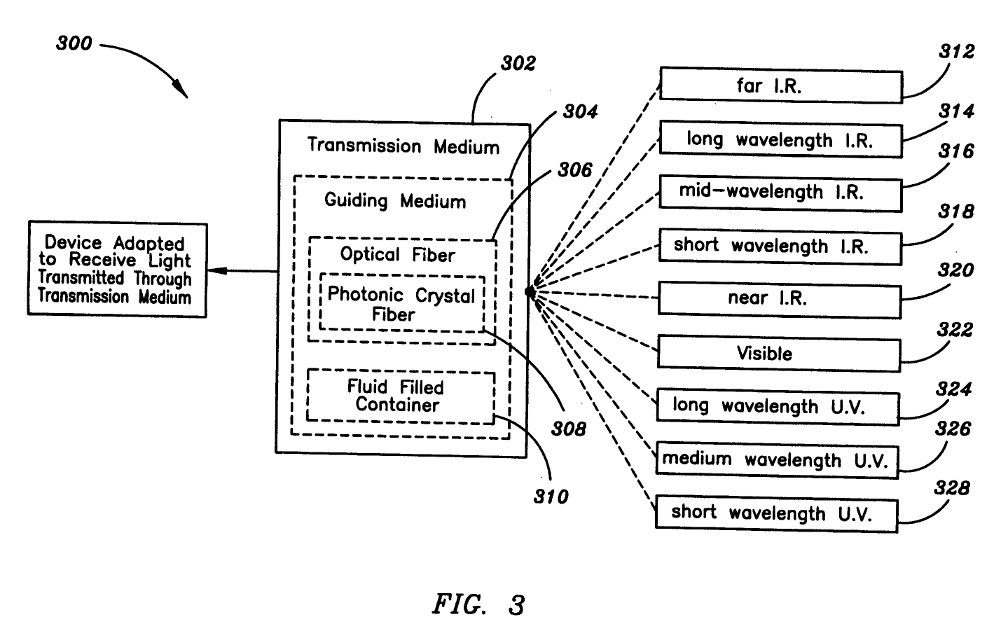

In an embodiment illustrated in FIG. 3, the system 100 suitable to convert light to electric power includes devices adapted to receive light transmitted through a transmission medium 302. For example, the transmission medium may include a guiding medium 304, such as an optical fiber 306. In a further embodiment, the optical fiber 306 may include a photonic crystal fiber 308. Further, the guiding medium 304 may include a fluid (e.g. water or oil) filled container 310. In an additional embodiment, the light converted to electric power by the system 100 may include far infrared (I.R.) light 312, long wavelength I.R. light 314, mid-wavelength I.R. light 316, short wavelength I.R. light 318, near I.R. light 320, visible light 322, long wavelength ultraviolet (U.V.) light 324, medium wavelength U.V., and short wavelength U.V. 328.

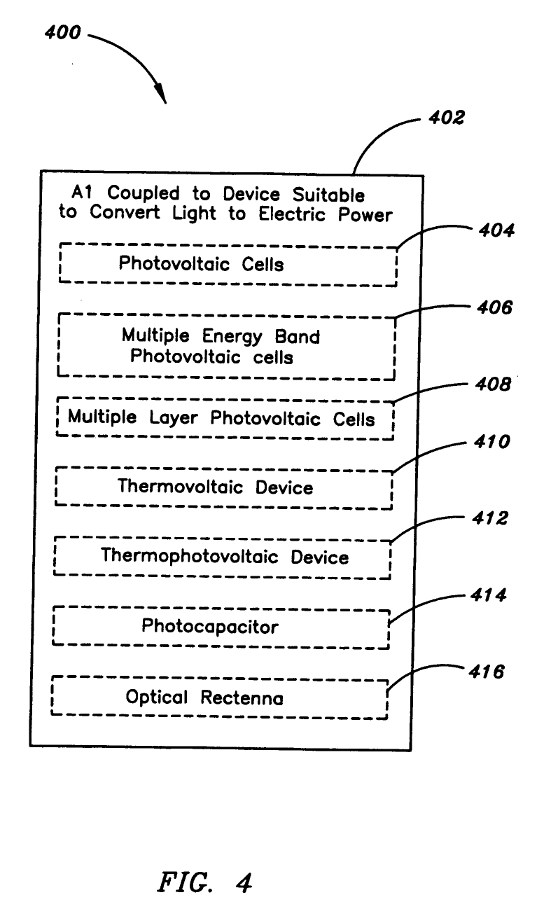

In an embodiment illustrated in FIG. 4, the system 100 suitable to convert light to electric power includes devices suitable to convert light to electric power 402. For example, the system 100 may include at least one photovoltaic cell 404, at least one multiple energy band photovoltaic cell 406, at least one multiple layer photovoltaic cell 408, at least one thermovoltaic devices 410, at least one thermophotovoltaic device 412, at least one photocapacitor 414, or at least one optical rectenna 416.

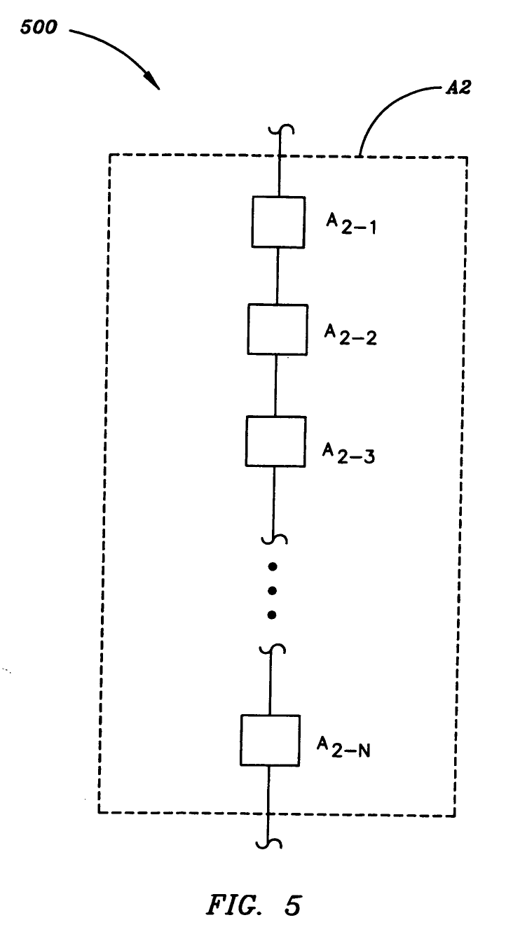

In an additional embodiment illustrated in FIG. 5, the sets of devices 102-110 of system 100 suitable to convert light to electric power may include at least one series set of devices suitable to convert light to electric power. For example, the second device A₂ of the first set of devices may include a series connected set of devices 500, including A₂₋₁ through A_{2-N}, suitable to convert light to electric power.

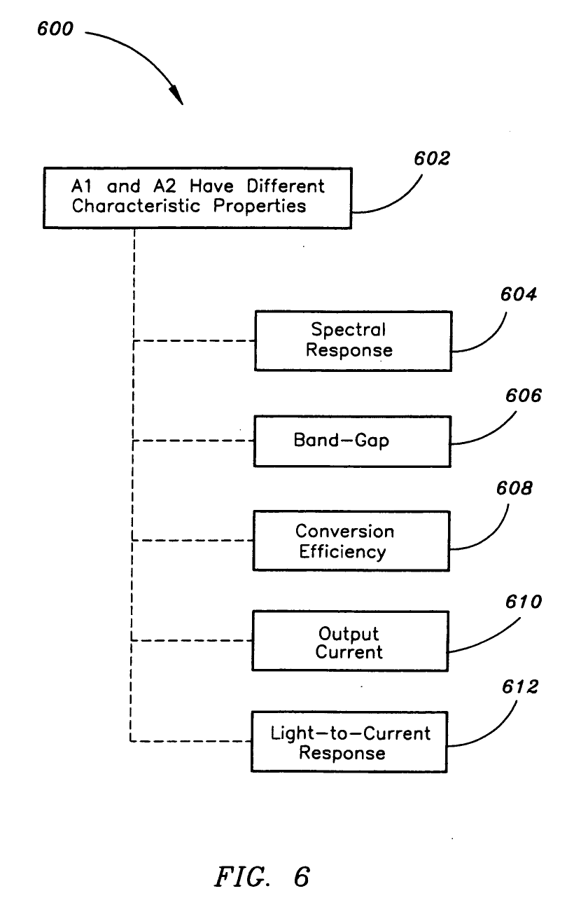

In an embodiment illustrated in FIG. 6, a first set of devices 102 may include a first device A₁ having a first characteristic property 602 and a second device A₂ having a second characteristic property 602. For example, device A₁ and device A₂ of the first set of devices may have different spectral responses 604, different band-gaps 606, different conversion efficiencies 608, different output currents 610, or different light-to-current response 612. In further embodiments, the second set of devices 104 and up to and including the Mth set of devices 110 may include devices (e.g. B₁ through B_{N} and M₁ through M_{N}) with different characteristic properties 602.

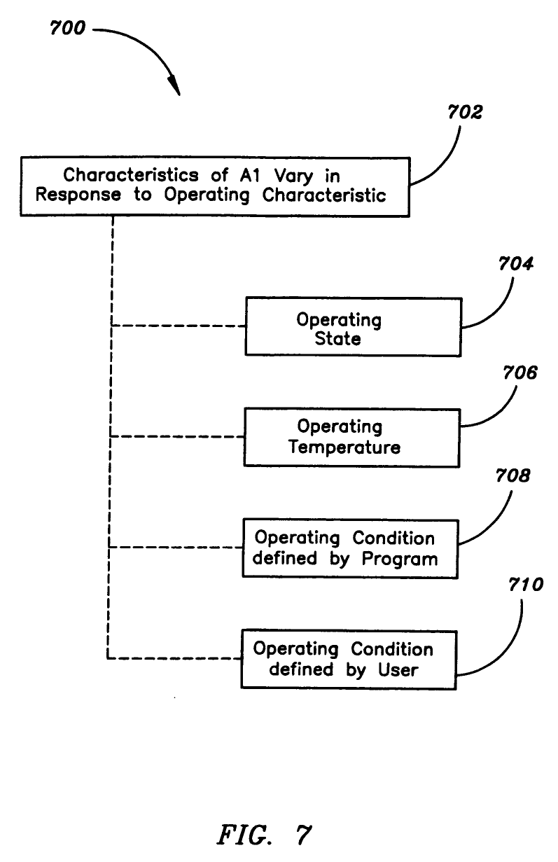

In a further embodiment illustrated in FIG. 7, the characteristics of the first device A₁ of the first set of devices 102 may vary in response to a selected operating characteristic 702. For example, a characteristic of the first device A₁ of the first set of devices 102 may vary in response to an operating state 704, operating temperature 706, an operating condition defined by a program 708, or an operating condition defined by a user.

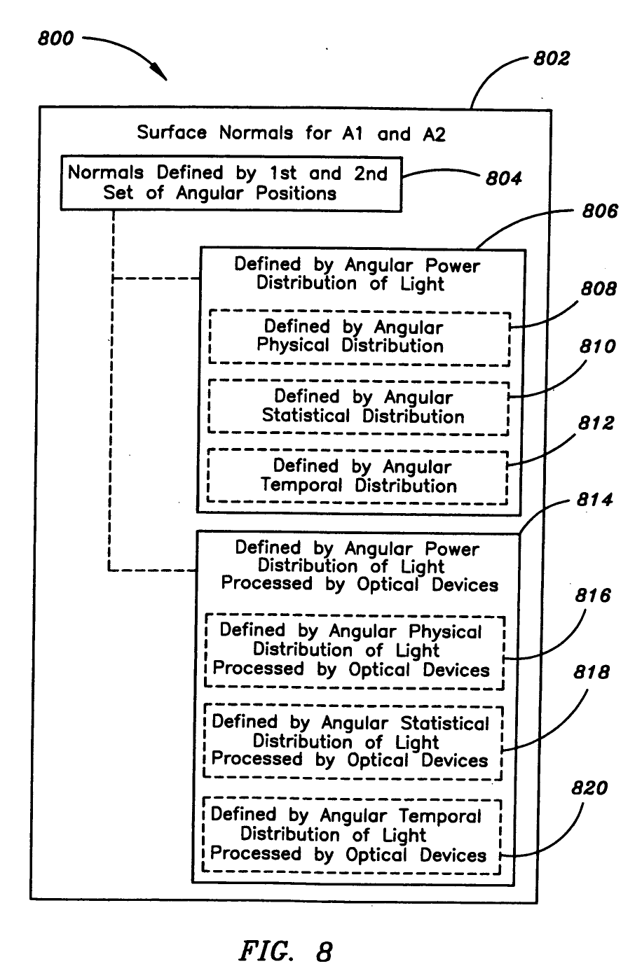

In an additional embodiment illustrated in FIG. 8, the surface normal of the first device A1 of the first set of devices and the surface normal of the second device A2 of the first set of devices may be oriented using a set of angular positions 804. For example, the set of angular positions may be defined in accordance with the angular power distribution 806 of the light from a selected light source. Further, the angular positions may be defined in accordance with the physical distribution 808 of the light, the statistical distribution 810 of the light, or the temporal variation 812 of the light. In addition, the set of angular positions may be defined in accordance with the angular power distribution 806 of the light from a selected light source. In a further embodiment, the set of angular positions may be defined in accordance with the angular power distribution 814 of the light processed by at least one optical device. For example, the angular positions may be defined in accordance with the physical distribution 816 of the light processed by optical devices, the statistical distribution 818 of the light processed by optical devices, or the temporal variation 820 of the light processed by optical devices.

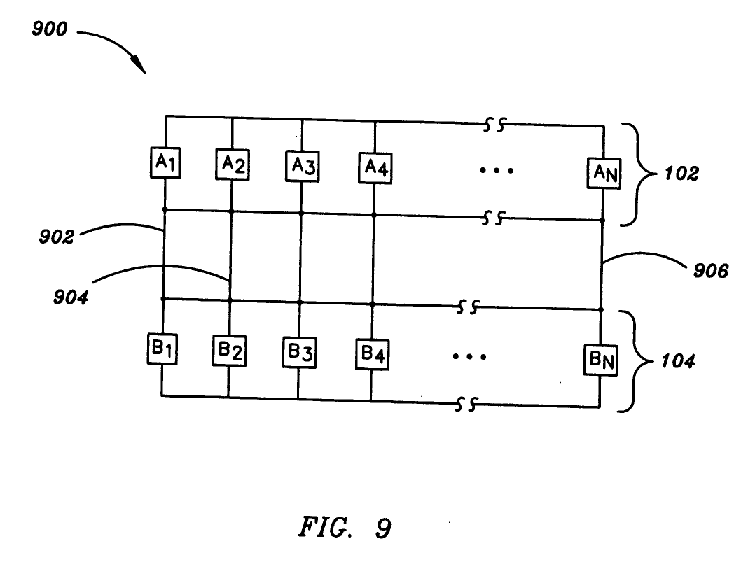

In a further embodiment illustrated in FIG. 9, the first device A₁ of the first set of devices suitable to convert light to electric power may be electrically connected 902 to one of the devices of the second set of devices suitable to convert light to electric power, such as the first device B₁ of the second set of devices. Further, the second device A₂ of the first set of devices may be electrically connected 904 to one of the devices of the second set of devices, such as the second device B₂ of the second set of devices. In a further embodiment, any device of the group A₁ through A_{N} of the first set of devices may be electrically connected 906 to any of the group B₁ through B_{N} of the second set of devices.

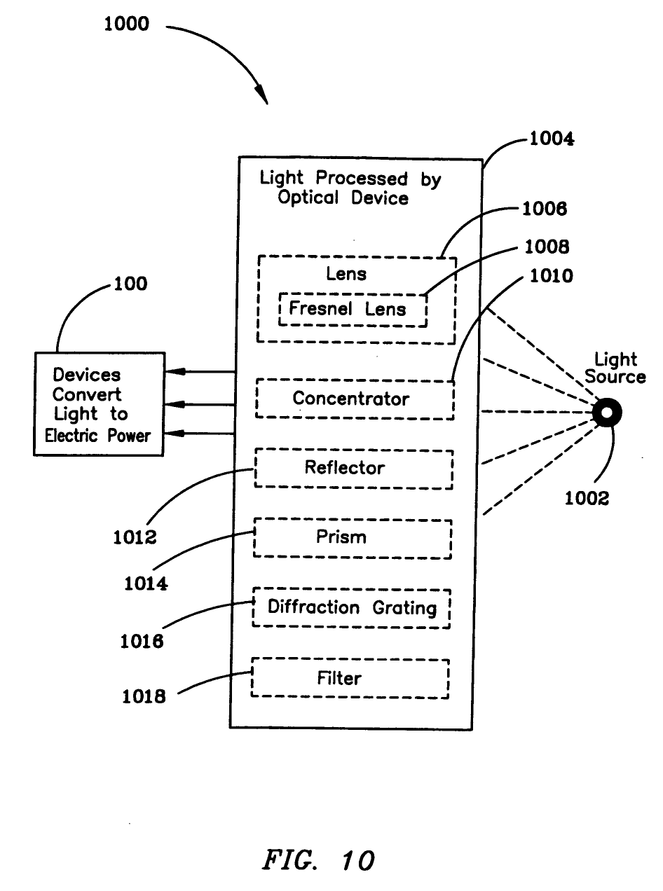

In another embodiment illustrated in FIG. 10, an optical device 1004 may be used to process light from a light source 1002 prior to the light impinging on the devices of system 100. In one embodiment, the light from a light source 1002 may be processed using a lens 1006. For example, the lens may include a Fresnel lens 1008. In additional embodiments, the light from a light source 1002 may be processed using a concentrator 1010, reflector 1012, prism 1014, diffraction grating 1016, or filter 1018. For example, the incident light 1002 may be processed by a prism 1014 or diffraction grating 1016 in order to direct light of constituent wavelengths to devices (e.g. A₁ through A_{N} of the first set of devices 102) optimized to convert light of a selected wavelength to electric power.

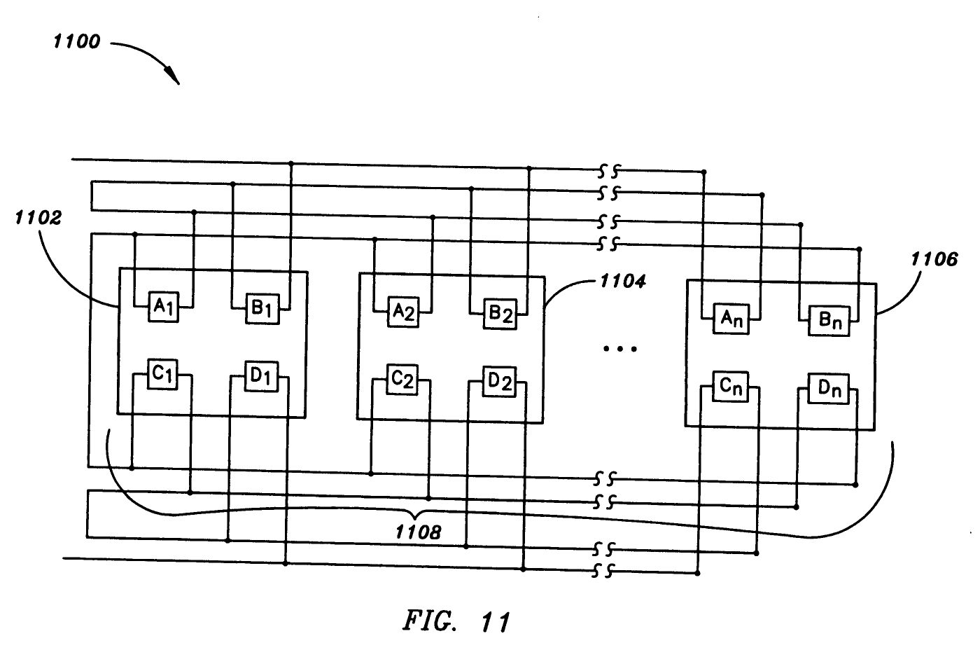

In a further embodiment illustrated in FIG. 11, the first device A₁ of the first set of devices 102 may be distributed such that it spatially resides in a first spatially discrete region 1102 and the second device B₁ of the second set of devices 104 may be distributed such that it spatially resides in the first spatially discrete region 1102. Further, the second device A₂ of the first set of devices 102 may be distributed such that it spatially resides in a second spatially discrete region 1104 and the first device B₁ of the second set of devices 104 may be distributed such that it spatially resides in the second spatially discrete region 1104. Further, the first spatially discrete region 1102 and the second spatially discrete region 1104 may be arranged to form a region of devices 1106 suitable to convert light to electric power that is substantially contiguous. For example, device A1 of the first set of devices and device B₂ of the second set of devices may be placed within a first region, demarked by a first rectangular boundary. Further, device A₂ of the first set of devices and device B1 of the second set of devices may be place with in a second region, demarked by a second rectangular boundary. In addition, the first rectangular region and the second rectangular region may be situated such that they are within close proximately to one another, forming a substantially contiguous region of devices suitable to convert light to electric power.

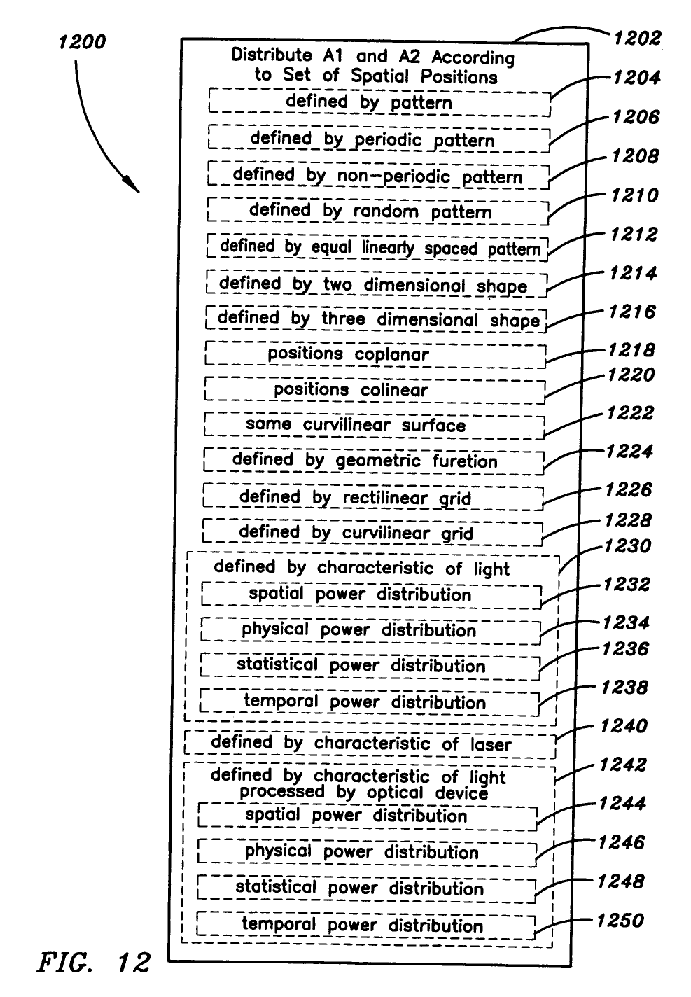

In a further embodiment illustrated in FIG. 12, the first device A₁ and the second device A₂ of the first set of devices 102 may be distributed according to a set of spatial positions 1202. For example, the set of spatial positions may be determined according to a pattern 1204, a periodic pattern 1206, a non-periodic pattern 1208, a random pattern 1210, an equal linearly space pattern 1212, a two dimensional shape 1214, a three dimensional shape 1216, a geometric function 1224, a rectilinear grid 1226, or a curvilinear grid 1228. Further, the set of spatial positions may be coplanar 1218, colinear 1220, or lie on the same curvilinear surface 1222. In an additional embodiment, the set of spatial positions 1202 may be defined by a characteristic of the light from a light source 1230 (e.g. spatial power distribution 1232, physical power distribution 1234, statistical power distribution 1236, or temporal power distribution 1238). For example, the set of spatial positions 1202 may be defined by a characteristic of the tight from a laser 1240. In an embodiment, the set of spatial positions 1202 may be defined by a characteristic of the light processed by an optical device 1242.

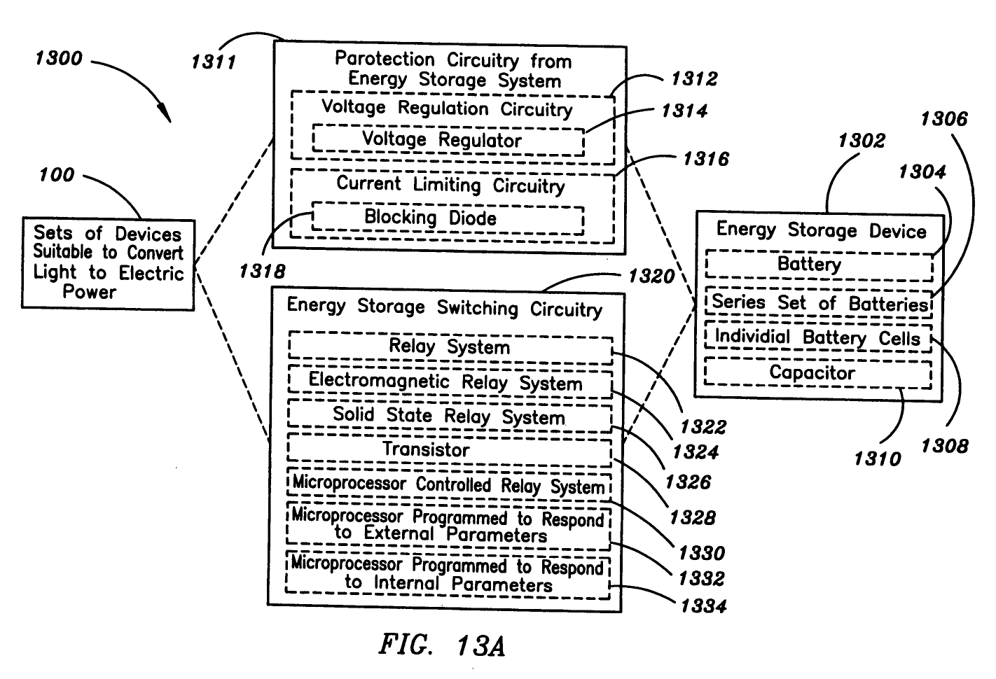

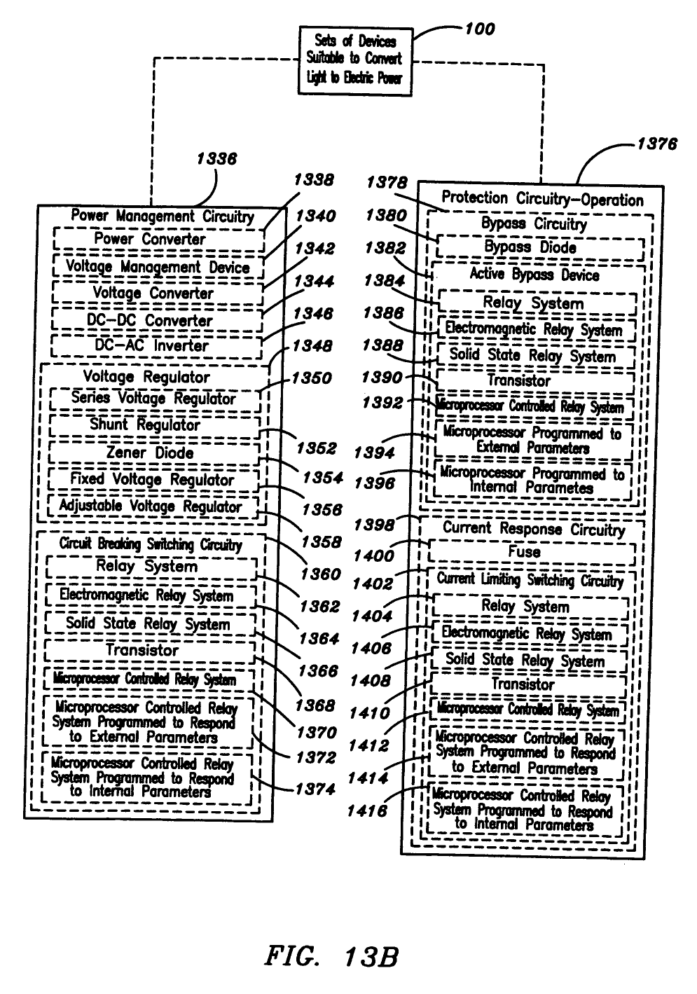

In an embodiment illustrated in FIG. 13A, the system 100 of devices suitable to convert light to electric power may be coupled to an energy storage device 1302. For example, the energy storage device 1302 may include a battery 1304, a series set of batteries 1306, an individual battery cell 1308, or a capacitor 1310. For example, one or more sets (e.g. 102 through 110) of devices suitable to convert light to electric power may be parallel coupled to one or more battery cells of a battery. In a further embodiment, protection circuitry 1311 may be coupled to one of more sets of devices of the system 100. In one embodiment, the sets of devices 102-110 may be coupled to voltage regulation circuitry 1312. For example, the voltage regulation circuitry may include a voltage regulator. In an additional embodiment the sets of devices 102-110 may include current limiting circuitry 1316. For example, the current limiting circuitry 1316 may include a blocking diode. In a further embodiment, switching circuitry 1320 may be coupled between the sets of devices (102-110) and the energy storage device 1302 in order to selectively open and close the circuit between the sets of devices (102-110) and the energy storage device 1302. For example, the switching circuitry may include a relay system 1322, an electromagnetic relay system 1324, a solid state relay system 1326, a transistor 1328, a microprocessor controlled relay system 1330, a microprocessor controlled relay system programmed to respond to a selected external parameter 1332 (e.g. light flux, or battery charge), or a microprocessor controlled relay system programmed to respond to a selected internal parameter 1334 (e.g. output current, output voltage or device operation status).

In an additional embodiment, the sets of devices 102-110 may be coupled to power management circuitry. For example, the power management circuitry may include a power converter 1338, a voltage management device 1340, a voltage converter 1342, a DC-DC converter 1344, or a DC-AC inverter 1346. Further, the power management circuitry may include a voltage regulator 1348. For example, the voltage regulator 1348 may include a series voltage regulator 1350, a shunt regulator 1352, a Zener diode 1354, a fixed voltage regulator 1356, or an adjustable voltage regulator 1358. Further, the power management circuitry 1336 may include circuit breaking switching circuitry 1360. For example, the switching circuitry may include a relay system 1362, an electromagnetic relay system 1364, a solid state relay system 1366, a transistor 1368, a microprocessor controlled relay system 1370, a microprocessor controlled relay system programmed to respond to a selected external parameter 1372 (e.g. load demand), or a microprocessor controlled relay system programmed to respond to a selected internal parameter 1374 (e.g. output current or output voltage).

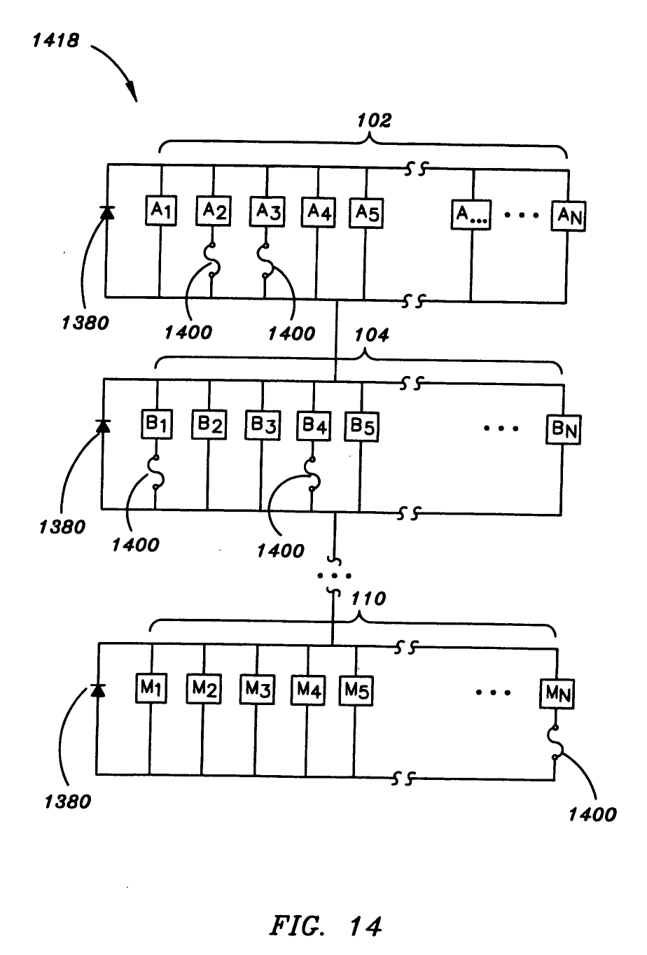

In a further embodiment illustrated in FIG. 13B and FIG. 14, the sets of devices 102-110 may be coupled to device operation protection circuitry 1376 to maintain maximum system 100 power output during device (e.g. A₁ through A_{N}) open circuit or short circuit malfunction. Further, the operation protection circuitry 1376 may include bypass circuitry 1378 to bypass a set of devices 102-110 during open circuit malfunction. For example, as illustrated in FIG. 13B and FIG. 14, the bypass circuitry 1378 may include a bypass diode 1380. Further, the bypass circuitry 1378 may include an active bypass device 1382. For example, the active bypass device 1382 may include a relay system 1384, an electromagnetic relay system 1386, a solid state relay system 1388 a transistor 1390, a microprocessor controlled relay system 1392, a microprocessor controlled relay system programmed to respond to a selected external parameter 1394 (e.g. light flux) or a microprocessor controlled relay system programmed to respond to a selected internal parameter 1396 (e.g. current flow through device). In an additional embodiment, the operation protection circuitry 1376 may include current response circuitry 1398 in order to isolate a device or number of devices of system 100 during short circuit failure. For example, as illustrated in FIG. 13B and FIG. 14, the current response circuitry may include a fuse 1400. Further, the current response circuitry 1398 may include current limiting switching circuitry 1402 to selectively disconnect a portion of one of the sets of devices 102-110 from the operational portion of the sets of devices 102-110 during short circuit failure. For example, the current limiting switching circuitry may include a relay system 1404, an electromagnetic relay system 1406, a solid state relay system 1408, a transistor 1410, a microprocessor controlled relay system 1412, a microprocessor controlled relay system programmed to respond to a selected external parameter 1414, or a microprocessor controlled relay system programmed to respond to a selected internal parameter 1416.

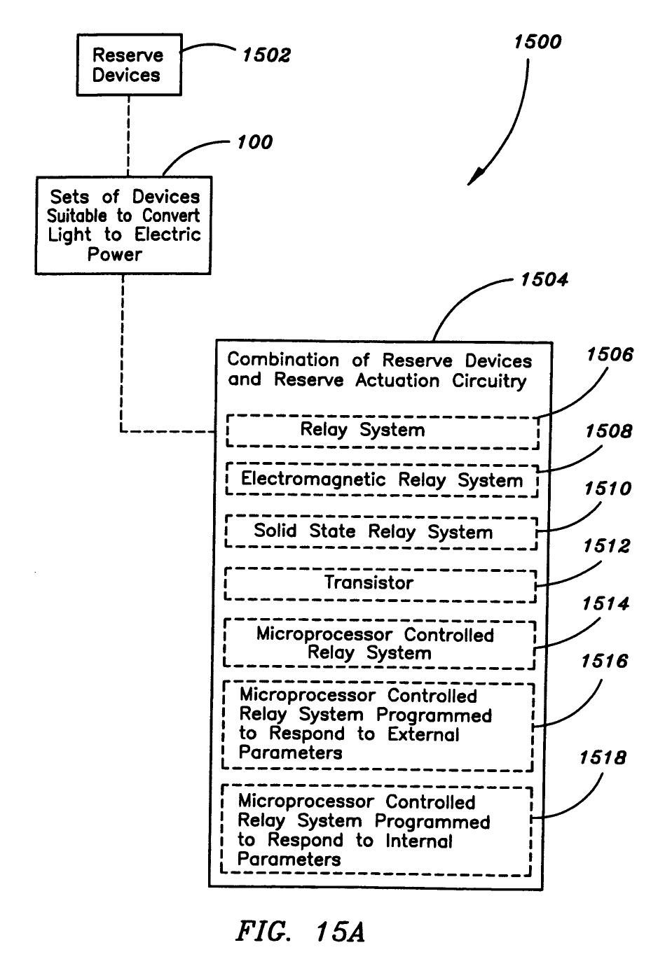

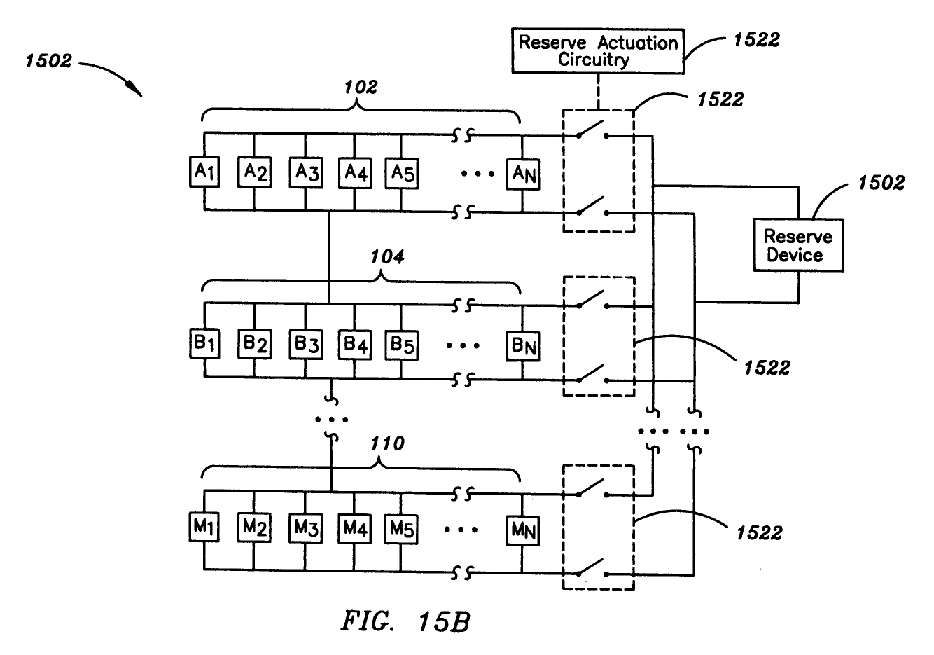

In a further embodiment illustrated in FIG. 15A, the sets of devices 102-110 of the system 100 may be individually or collectively coupled to one or more than one reserve device suitable to convert light to electric power. For example, a reserve device 1502 may be coupled to the first set 102 of devices of system 100 in order to provide supplemental power to the first set 102 of devices during partial or total malfunction or low illumination. In an additional embodiment illustrated in FIG. 15A and FIG. 15B, the sets of devices 102-110 of the system 100 may be individually or collectively coupled to a combination 1504 of at least one reserve device 1502 and reserve actuation circuitry 1522. For example, the reserve actuation circuitry 1522 may include a relay system 1506, an electromagnetic relay system 1508, a solid state relay system 1510, a transistor 1512, a microprocessor controlled relay system 1514, a microprocessor controlled relay system programmed to respond to a selected external parameter 1516 (e.g. illumination levels), or a microprocessor controlled relay system programmed to respond to a selected internal parameter 1518 (e.g. device current or voltage output).

Following are a series of flowcharts depicting implementations. For ease of understanding, the flowcharts are organized such that the initial flowcharts present implementations via an example implementation and thereafter the following flowcharts present alternate implementations and/or expansions of the initial flowchart(s) as either sub-component operations or additional component operations building on one or more earlier-presented flowcharts. Those having skill in the art will appreciate that the style of presentation utilized herein (e.g., beginning with a presentation of a flowchart(s) presenting an example implementation and thereafter providing additions to and/or further details in subsequent flowcharts) generally allows for a rapid and easy understanding of the various process implementations. In addition, those skilled in the art will further appreciate that the style of presentation used herein also tends itself well to modular and/or object-oriented program design paradigms.

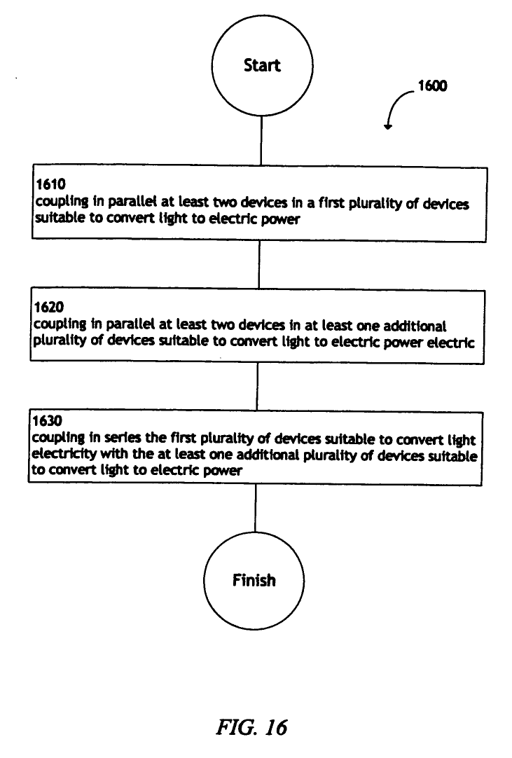

FIG. 16 illustrates an operational flow 1600 representing example operations related to the system and method to convert light to electrical power. In FIG. 16 and in following figures that include various examples of operational flows, discussion and explanation may be provided with respect to the above-described examples of FIGS. 1 through 15, and/or with respect to other examples and contexts. However, it should be understood that the operational flows may be executed in a number of other environments and contexts, and/or in modified versions of FIGS. 1 through 15. Also, although the various operational flows are presented in the sequence(s) illustrated, it should be understood that the various operations may be performed in other orders than those which are illustrated, or may be performed concurrently.

After a start operation, the operational flow 1600 moves to an operation 1610. Operation 1610 depicts coupling in parallel at least two devices in a first plurality of devices suitable to convert light to electric power. For example, as shown in FIG. 1, a first device A₁ in a first set of devices 102 suitable to convert light to electric power may be coupled in parallel with a second device A₂.

Then, operation 1620 depicts coupling in parallel at least two devices in at least one additional plurality of devices suitable to convert light to electric power electric. For example, as shown in FIG. 1, a first device B₁. In an additional set of devices suitable to convert light to electric power 104 may be coupled in parallel with a second device B₂.

Then, operation 1630 depicts coupling in series the first plurality of devices suitable to convert light electricity with the at least one additional plurality of devices suitable to convert light to electric power. For example, as shown in FIG. 1, the first set of devices 102 suitable to convert light to electric power may be coupled in series with the second set of devices 104 suitable to convert light to electric power.

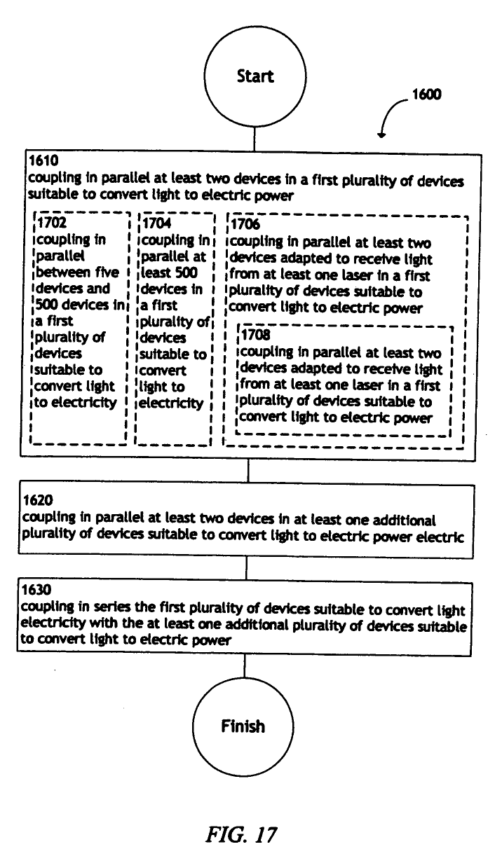

FIG. 17 illustrates alternative embodiments of the example operational flow 1600 of FIG. 16. FIG. 17 illustrates example embodiments where the operation 1610 may include at least one additional operation. Additional operations may include an operation 1702, an operation 1704, an operation 1706, and/or an operation 1708.

The operation 1702 illustrates coupling in parallel between five devices and 500 devices in a first plurality of devices suitable to convert light to electricity. For example, as shown in FIG. 1, the first device A₁ may be coupled in parallel with a number of devices, such as the second device A₂, including at least a fifth device A₅ and up to and including a 500th device A₅₀₀.

The operation 1704 illustrates coupling in parallel at least 500 devices in a first plurality of devices suitable to convert light to electricity. For example, as shown in FIG. 1, the first device may be coupled in parallel with a number of devices, including at least a 500th device A₅₀₀ and up to a Nth device A_{N}.

The operation 1706 illustrates coupling in parallel at least two devices adapted to receive light from a light source in a first plurality of devices suitable to convert light to electric power. For example, as shown in FIG. 2, the first device A₁ in the first set of devices 102 and the second device A₂ in the first set of devices 102 may be adapted to receive light from a light source 202. Further, the operation 1708 illustrates coupling in parallel at least two devices adapted to receive light from at least one laser in a first plurality of devices suitable to convert light to electric power. For example, as shown in FIG. 2, the first device A₁ in the first set of devices 102 and the second device A₂ in the first set of devices 102 may be adapted to receive light from a laser 204.

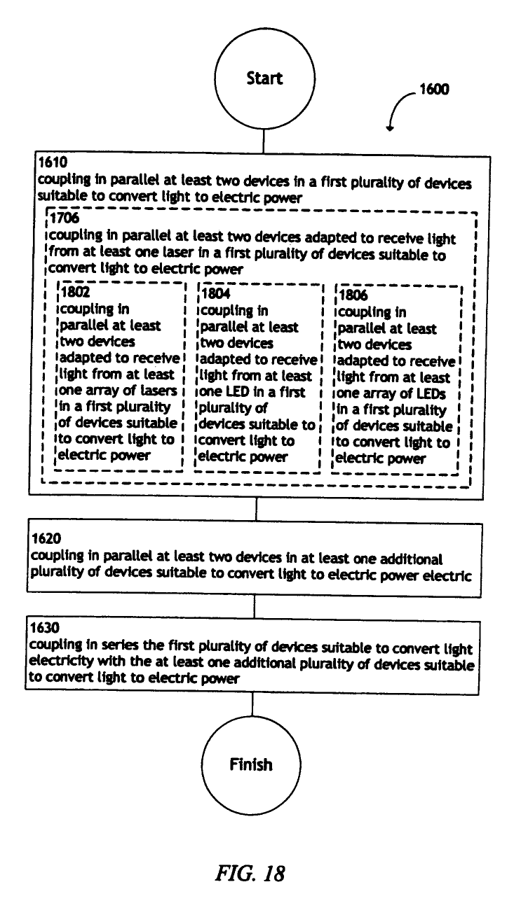

FIG. 18 illustrates alternative embodiments of the example operational flow 1600 of FIG. 16. FIG. 18 illustrates example embodiments where the operation 1610 may include at least one additional operation. Additional operations may include an operation 1802, an operation 1804, and/or an operation 1806. Further, the operation 1802 illustrates coupling in parallel at least two devices adapted to receive light from at least one array of lasers in a first plurality of devices suitable to convert light to electric power. For example, as shown in FIG. 2, the first device A₁ in the first set of devices 102 and the second device A₂ in the first set of devices 102 may be adapted to receive light from an array of lasers 206. Further, the operation 1804 illustrates coupling in parallel at least two devices adapted to receive light from at least one LED in a first plurality of devices suitable to convert light to electric power. For example, as shown in FIG. 2, the first device A₁ in the first set of devices 102 and the second device A₂ in the first set of devices 102 may be adapted to receive light from a light Emitting Diode (LED) 208. Further, the operation 1806 illustrates coupling in parallel at least two devices adapted to receive light from at least one array of LEDs in a first plurality of devices suitable to convert tight to electric power. For example, as shown in FIG. 2, the first device A₁ in the first set of devices 102 and the second device A₂ in the first set of devices 102 may be adapted to receive tight from an array of LEDs 210.

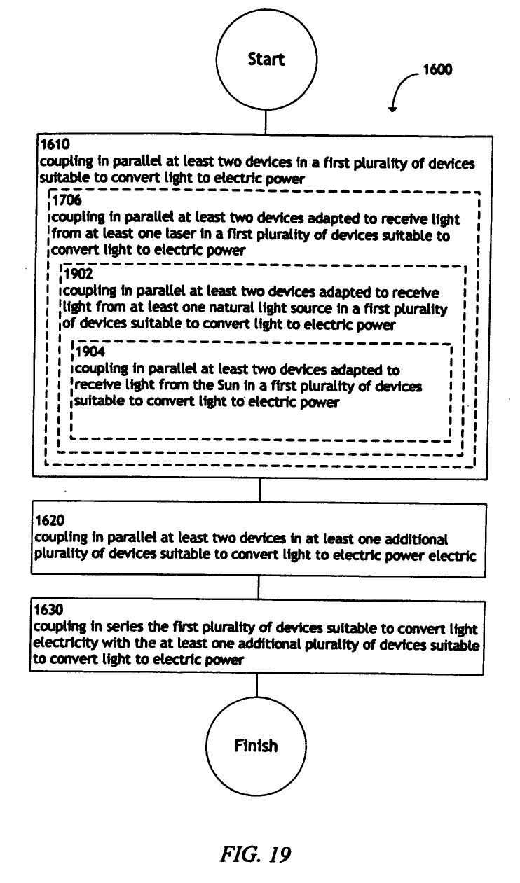

FIG. 19 illustrates alternative embodiments of the example operational flow 1600 of FIG. 16. FIG. 19 illustrates example embodiments where the operation 1610 may include at least one additional operation. Additional operations may include an operation 1902, and/or an operation 1904. Further, the operation 1902 illustrates coupling in parallel at least two devices adapted to receive light from at least one natural light source in a first plurality of devices suitable to convert light to electric power. For example, as shown in FIG. 2, the first device A₁ in the first set of devices 102 and the second device A₂ in the first set of devices 102 may be adapted to receive light from a natural light source 212. Further, the operation 1904 illustrates coupling in parallel at least two devices adapted to receive light from the Sun in a first plurality of devices suitable to convert light to electric power. For example, as shown in FIG. 2, the first device A₁ in the first set of devices 102 and the second device A₂ in the first set of devices 102 may be adapted to receive light from the Sun 214.

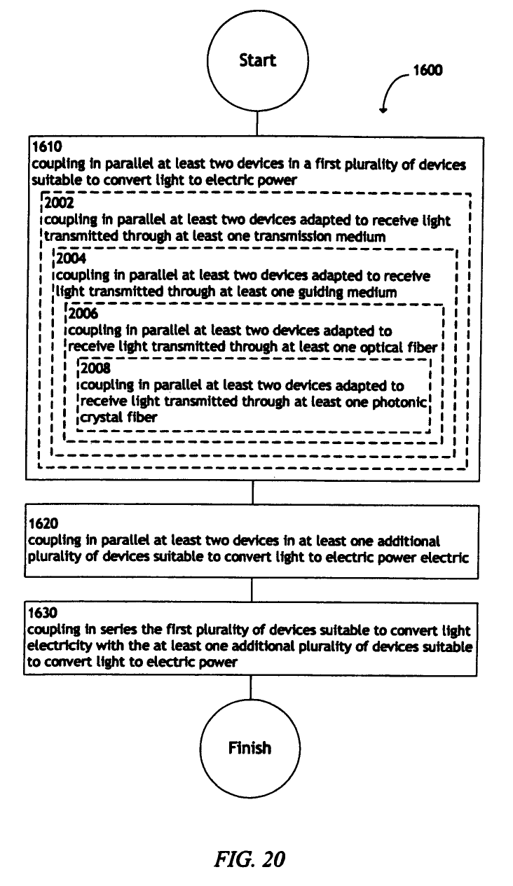

FIG. 20 illustrates alternative embodiments of the example operational flow 1600 of FIG. 16. FIG. 20 illustrates example embodiments where the operation 1610 may include at least one additional operation. Additional operations may include an operation 2002, an operation 2004, an operation 2006, and/or an operation 2008.

The operation 2002 illustrates coupling in parallel at least two devices adapted to receive light transmitted through at least one transmission medium. For example, as shown in FIG. 3, the first device A₁ in the first set of devices 102 and the second device A₂ in the first set of devices 102 may be adapted to receive light transmitted through a transmission medium 302 (e.g., vacuum, gas, air, liquid, or solid). Further, the operation 2004 illustrates coupling in parallel at least two devices adapted to receive light transmitted through at least one guiding medium. For example, as shown in FIG. 3, the first device A₁ in the first set of devices 102 and the second device A₂ in the first set of devices 102 may be adapted to receive light transmitted through a guiding medium 304. Further, the operation 2006 illustrates coupling in parallel at least two devices adapted to receive light transmitted through at least one optical fiber. For example, as shown in FIG. 3, the first device A₁ in the first set of devices 102 and the second device A₂ in the first set of devices 102 may be adapted to receive light transmitted through an optical fiber 306. Further, the operation 2008 illustrates coupling in parallel at least two devices adapted to receive light transmitted through at least one photonic crystal fiber. For example, as shown in FIG. 3, the first device A₁ in the first set of devices 102 and the second device A₂ in the first set of devices 102 may be adapted to receive light transmitted through a photonic crystal fiber 308.

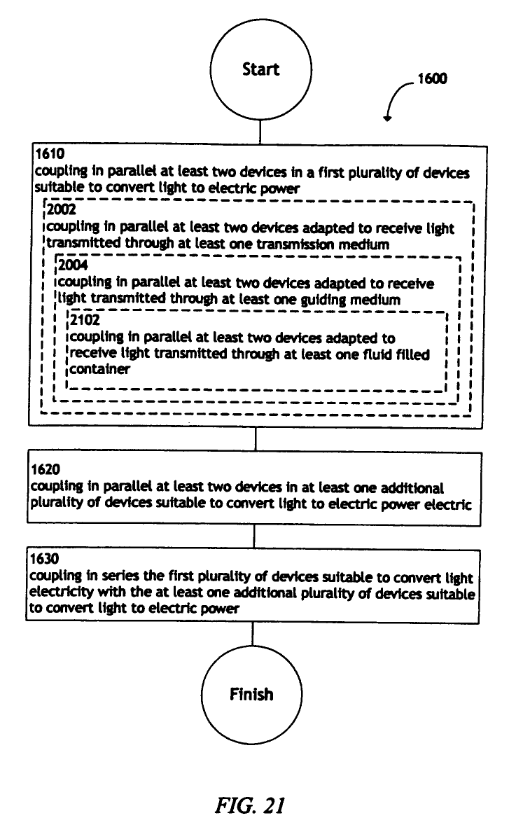

FIG. 21 illustrates alternative embodiments of the example operational flow 1600 of FIG. 16. FIG. 21 illustrates example embodiments where the operation 1610 may include at least one additional operation. Additional operations may include an operation 2102. Further, the operation 2102 illustrates coupling in parallel at least two devices adapted to receive light transmitted through at least one fluid filled container. For example, as shown in FIG. 3, the first device A₁ in the first set of devices 102 and the second device A₂ in the first set of devices 102 may be adapted to receive light transmitted through a fluid (e.g. water or oil) filled container 310.

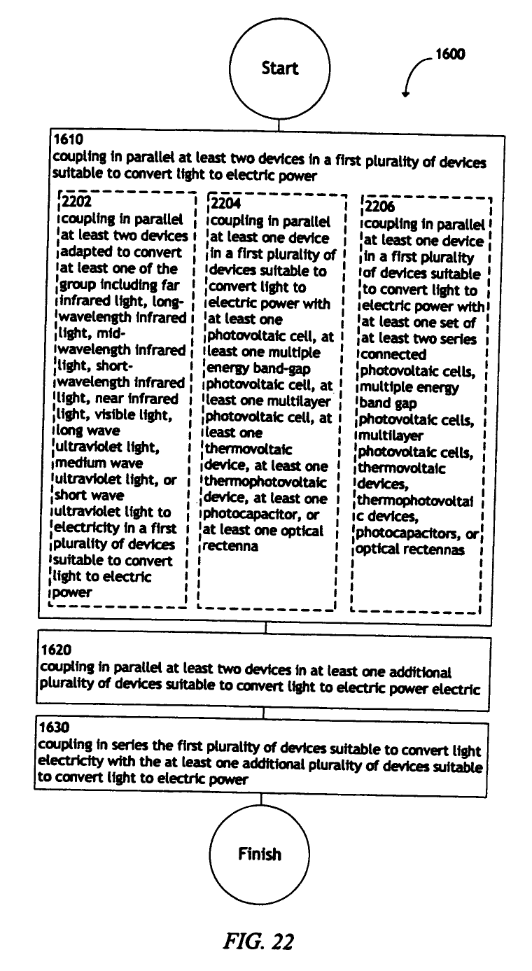

FIG. 22 illustrates alternative embodiments of the example operational flow 1600 of FIG. 16. FIG. 22 illustrates example embodiments where the operation 1610 may include at least one additional operation. Additional operations may include an operation 2202, an operation 2204, and/or an operation 2206.

The operation 2202 illustrates coupling in parallel at least two devices adapted to convert at least one of the group including far infrared light, long-wavelength infrared light, mid-wavelength infrared light, short-wavelength infrared light, near infrared light, visible light, long wave ultraviolet light, medium wave ultraviolet light, or short wave ultraviolet light to electricity in a first plurality of devices suitable to convert light to electric power. For example, as shown in FIG. 3, the first device A₁ in the first set of devices 102 and the second device A₂ in the first set of devices 102 may be adapted to convert far infrared light 312, long-wavelength infrared light 314, mid-wavelength infrared light 316, short-wavelength infrared light 318, near infrared light 320, visible light 322, tong wave ultraviolet light 324, medium wave ultraviolet light 326, or short wave ultraviolet light 328 to electric power.

The operation 2204 illustrates coupling in parallel at least one device in a first plurality of devices suitable to convert light to electric power with at least one photovoltaic cell, at least one multiple energy band-gap photovoltaic cell, at least one multilayer photovoltaic cell, at least one thermovoltaic device, at least one thermophotovoltaic device, at least one photocapacitor, or at least one optical rectenna. For example, as shown in FIG. 4, the first device A₁ in the first set of devices 102 may be coupled in parallel with at least one device suitable to convert light to electric power 402. For example, as shown in FIG. 4, the first device A₁ in the first set of devices 102 may be coupled in parallel with at least one photovoltaic cell 404, at least one multiple energy band-gap photovoltaic cell 406, at least one multilayer photovoltaic cell 408, at least one thermovoltaic device 410, at least one thermophotovoltaic device 412, at least one photocapacitor 414, or at least one optical rectenna 416. In one embodiment, the photovoltaic cell 406 in the first set of devices 102 may include a single crystal silicon photovoltaic cell, a polycrystalline photovoltaic cell, or an amorphous silicon photovoltaic cell.

The operation 2206 illustrates coupling in parallel at least one device in a first plurality of devices suitable to convert light to electric power with at least one set of at least two series connected photovoltaic cells, multiple energy band gap photovoltaic cells, multilayer photovoltaic cells, thermovoltaic devices, thermophotovoltaic devices, photocapacitors, or optical rectennas. For example, as shown in FIG. 5, the first device A₁ in the first set of devices 102 may be coupled in parallel with a second device A₂ comprising a first device A₂₋₁ suitable to convert light to electric power series coupled to at least a second device A₂₋₂ suitable to convert light to electric power. Further, A₂₋₁ may be coupled to a number of devices suitable to convert light to electric power, up to and including an Nth device A_{2-N} suitable to convert light to electric power.

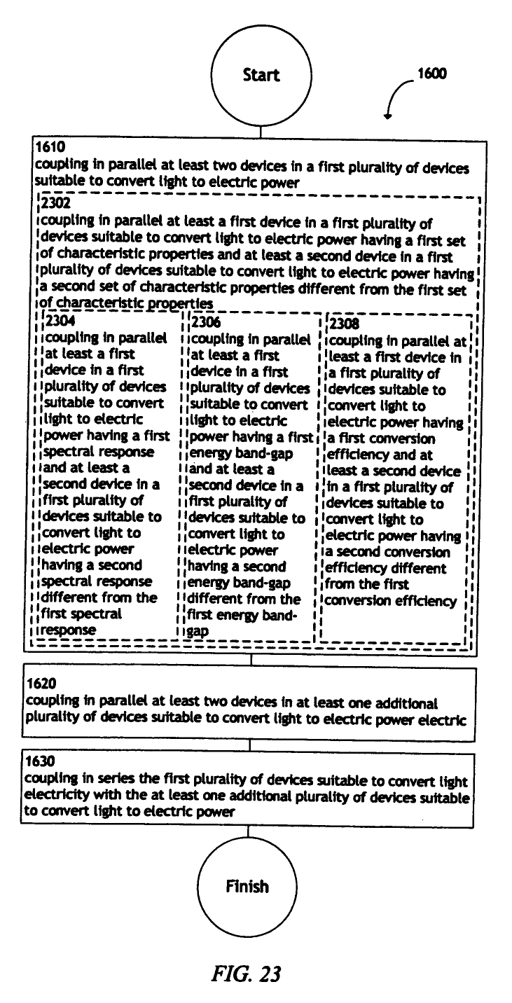

FIG. 23 illustrates alternative embodiments of the example operational flow 1600 of FIG. 16. FIG. 23 illustrates example embodiments where the operation 1610 may include at least one additional operation. Additional operations may include an operation 2302, an operation 2304, an operation 2306, and/or an operation 2308.

The operation 2302 illustrates coupling in parallel at least a first device in a first plurality of devices suitable to convert light to electric power having a first set of characteristic properties and at least a second device in a first plurality of devices suitable to convert light to electric power having a second set of characteristic properties different from the first set of characteristic properties. For example, as shown in FIG. 6, the first device A₁ in the first set of devices 102 may have a first set of characteristic properties 602 and the second device A₂ in the first set of devices 102 may have a second set of characteristic properties 602 different than the first set of characteristic properties 602. Further, the operation 2304 illustrates coupling in parallel at least a first device in a first plurality of devices suitable to convert light to electric power having a first spectral response and at least a second device in a first plurality of devices suitable to convert light to electric power having a second spectral response different from the first spectral response. For example, as shown in FIG. 6, the first device A₁ in the first set of devices 102 may have a first spectral response 604 and the second device A₂ in the first set of devices 102 may have a second spectral response 604 different than the first spectral response 604. Further, the operation 2306 illustrates coupling in parallel at least a first device in a first plurality of devices suitable to convert light to electric power having a first energy band-gap and at least a second device in a first plurality of devices suitable to convert light to electric power having a second energy band-gap different from the first energy band-gap. For example, as shown in FIG. 6, the first device A₁ in the first set of devices 102 may have a first energy band-gap 606 and the second device A₂ in the first set of devices 102 may have a second energy band-gap 606 different than the first energy band-gap 606. Further, the operation 2308 illustrates coupling in parallel at least a first device in a first plurality of devices suitable to convert tight to electric power having a first conversion efficiency and at least a second device in a first plurality of devices suitable to convert light to electric power having a second conversion efficiency different from the first conversion efficiency. For example, as shown in FIG. 6, the first device A₁ in the first set of devices 102 may have a first conversion efficiency 608 and the second device A₂ in the first set of devices 102 may have a second conversion efficiency 608 different than the first conversion efficiency 608.

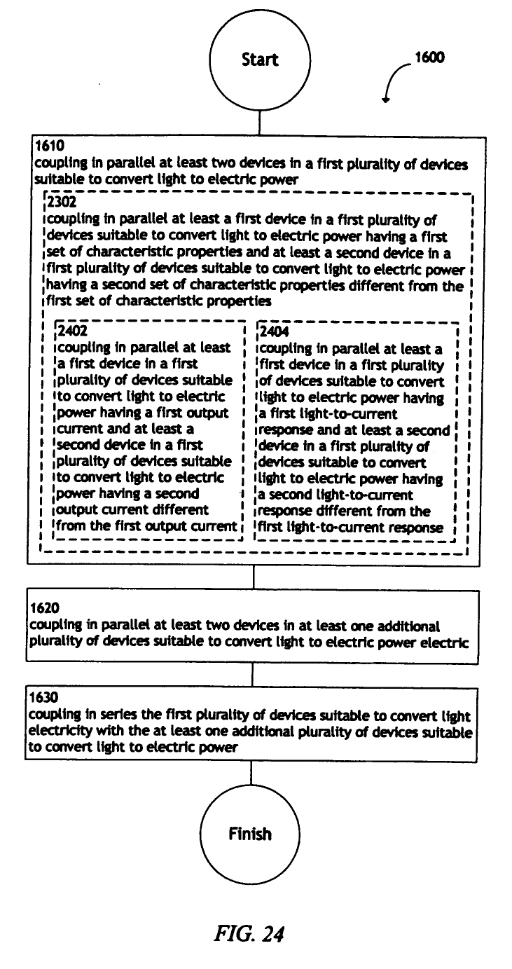

FIG. 24 illustrates alternative embodiments of the example operational flow 1600 of FIG. 16. FIG. 24 illustrates example embodiments where the operation 1610 may include at least one additional operation. Additional operations may include an operation 2402, and/or an operation 2404. Further, the operation 2402 illustrates coupling in parallel at least a first device in a first plurality of devices suitable to convert light to electric power having a first output current and at least a second device in a first plurality of devices suitable to convert light to electric power having a second output current different from the first output current. For example, as shown in FIG. 6, the first device A₁ in the first set of devices 102 may have a first output current 610 and the second device A₂ in the first set of devices 102 may have a second output current 610 different than the first output current 610. Further, the operation 2404 illustrates coupling in parallel at least a first device in a first plurality of devices suitable to convert light to electric power having a first light-to-current response and at least a second device in a first plurality of devices suitable to convert light to electric power having a second light-to-current response different from the first light-to-current response. For example, as shown in FIG. 6, the first device A₁ in the first set of devices 102 may have a first light-to-current response 612 and the second device A₂ in the first set of devices 102 may have a second light-to-current response 612 different than the first light-to-current response 612.

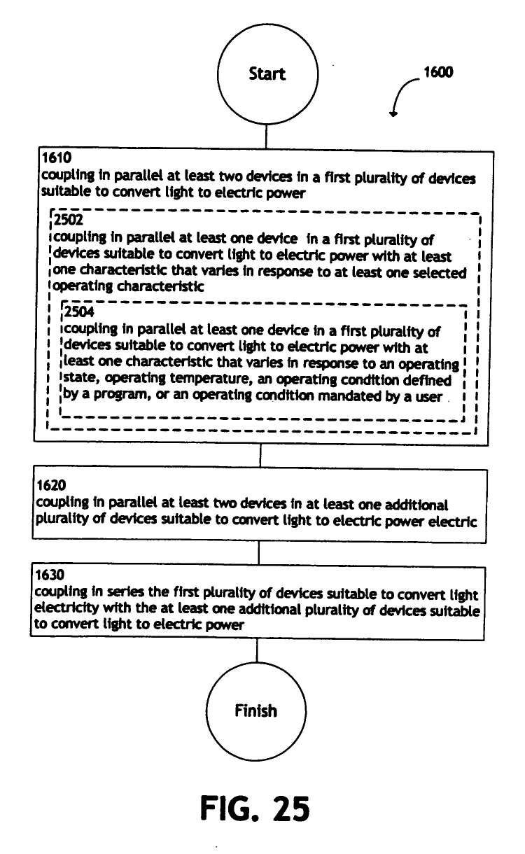

FIG. 25 illustrates alternative embodiments of the example operational flow 1600 of FIG. 16. FIG. 25 illustrates example embodiments where the operation 1610 may include at least one additional operation. Additional operations may include an operation 2502, and/or an operation 2504.

The operation 2502 illustrates coupling in parallel at least one device in a first plurality of devices suitable to convert light to electric power with at least one characteristic that varies in response to at least one selected operating characteristic. For example, as shown in FIG. 7, the first device A₁ parallel coupled in the first set of devices 102 suitable to convert light to electric power may have at least one characteristic that varies in response to at least one selected operating characteristic 702. Further, the operation 2504 illustrates coupling in parallel at least one device in a first plurality of devices suitable to convert light to electric power with at least one characteristic that varies in response to an operating state, operating temperature, an operating condition defined by a program, or an operating condition mandated by a user. For example, as shown in FIG. 7, the first device A₁ parallel coupled in the first set of devices 102 suitable to convert light to electric power may have at least one characteristic that varies in response to an operating state 704, operating temperature 706, an operating condition defined by a program 708, or an operating condition mandated by a user 710.

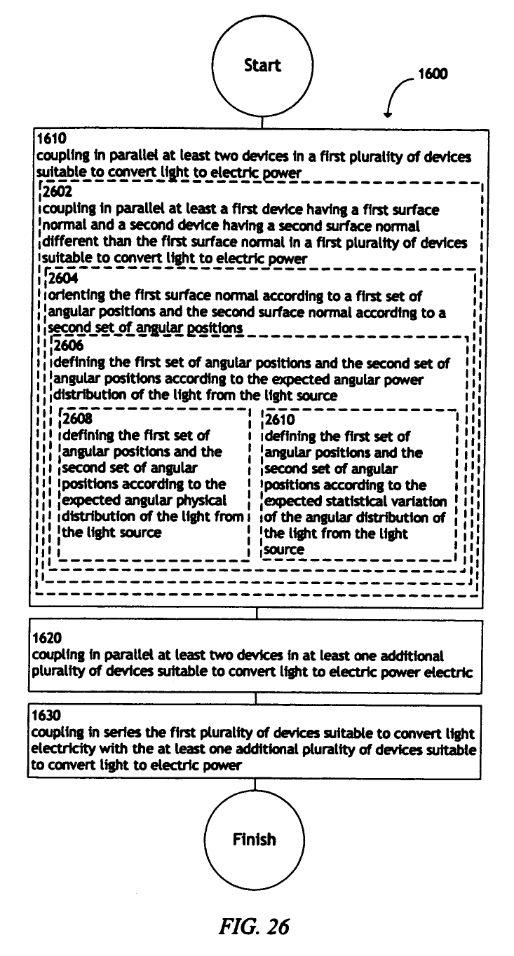

FIG. 26 illustrates alternative embodiments of the example operational flow 1600 of FIG. 16. FIG. 26 illustrates example embodiments where the operation 1610 may include at least one additional operation. Additional operations may include an operation 2602, an operation 2604, an operation 2606, an operation 2608, and/or an operation 2610.

The operation 2602 illustrates coupling in parallel at least a first device having a first surface normal and a second device having a second surface normal different than the first surface normal in a first plurality of devices suitable to convert light to electric power. For example, as shown in FIG. 8, the first device A₁ in the first set of devices 102 may have a first surface normal 802 and the second device A₂ in the first set of devices 102 may have a second surface normal 802 different than the first surface normal 802. Further, the operation 2604 illustrates orienting the first surface normal according to a first set of angular positions and the second surface normal according to a second set of angular positions. For example, as shown in FIG. 8, the surface normal of the first device A₁ in the first set of devices 102 may be oriented according to a first set of angular positions 804 and the surface normal of the second device A₂ in the first set of devices 102 may be oriented according to a second set of angular positions 804. Further, the operation 2606 illustrates defining the first set of angular positions and the second set of angular positions according to the expected angular power distribution of the light from the light source. For example, as shown in FIG. 8, the first set of angular positions 804 of the surface normal of the first device A₁ and the second set of angular positions 804 of the surface normal of the second device A₂ may be defined according to the expected angular power distribution 806 of the light from the light source. Further, the operation 2608 illustrates defining the first set of angular positions and the second set of angular positions according to the expected angular physical distribution of the light from the light source. For example, as shown in FIG. 8, the first set of angular positions 804 of the surface normal of the first device A₁ and the second set of angular positions 804 of the surface normal of the second device A₂ may be defined according to the expected angular physical distribution 808 of the light from the light source. Further, the operation 2610 illustrates defining the first set of angular positions and the second set of angular positions according to the expected statistical variation of the angular distribution of the light from the light source. For example, as shown in FIG. 8, the first set of angular positions 804 of the surface normal of the first device A₁ and the second set of angular positions 804 of the surface normal of the second device A₂ may be defined according to the expected statistical variation of the angular distribution 810 of the light from the light source.

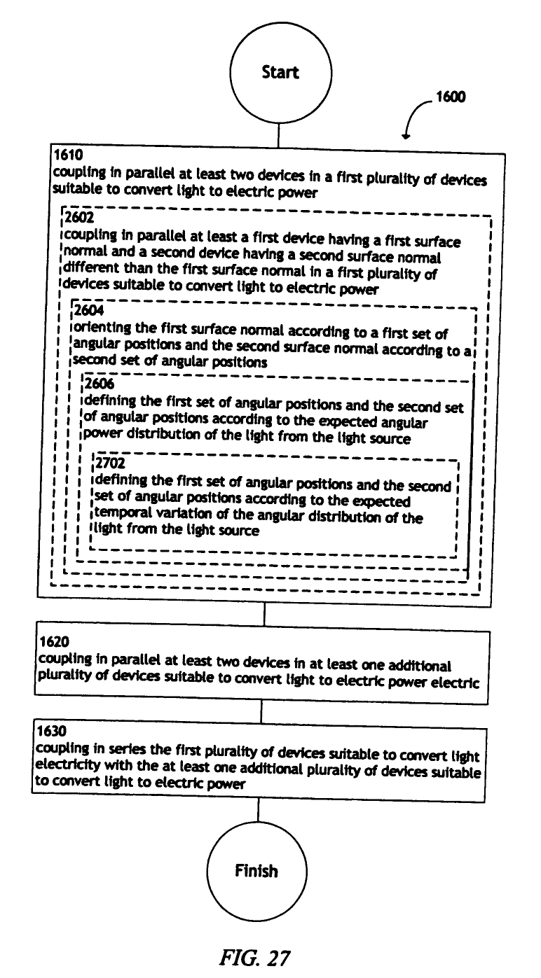

FIG. 27 illustrates alternative embodiments of the example operational flow 1600 of FIG. 16. FIG. 27 illustrates example embodiments where the operation 1610 may include at least one additional operation. Additional operations may include an operation 2702. Further, the operation 2702 illustrates defining the first set of angular positions and the second set of angular positions according to the expected temporal variation of the angular distribution of the light from the light source. For example, as shown in FIG. 8, the first set of angular positions 804 of the surface normal of the first device A₁ and the second set of angular positions 804 of the surface normal of the second device A₂ may be defined according to the expected angular temporal distribution 812 of the light from the tight source.

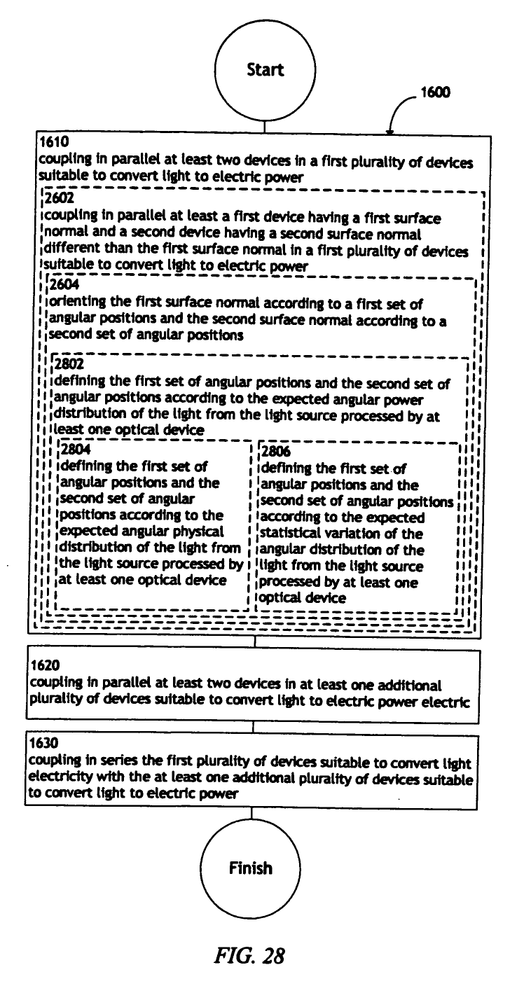

FIG. 28 illustrates alternative embodiments of the example operational flow 1600 of FIG. 16. FIG. 28 illustrates example embodiments where the operation 1610 may include at least one additional operation. Additional operations may include an operation 2802, an operation 2804, and/or an operation 2806. Further, the operation 2802 illustrates defining the first set of angular positions and the second set of angular positions according to the expected angular power distribution of the light from the light source processed by at least one optical device. For example, as shown in FIG. 8, the first set of angular positions 804 of the surface normal of the first device A₁ and the second set of angular positions 804 of the surface normal of the second device A₂ may be defined according to the expected angular power distribution 814 of the light processed by an optical device. Further, the operation 2804 illustrates defining the first set of angular positions and the second set of angular positions according to the expected angular physical distribution of the light from the light source processed by at least one optical device. For example, as shown in FIG. 8, the first set of angular positions 804 of the surface normal of the first device A₁ and the second set of angular positions 804 of the surface normal of the second device A₂ may be defined according to the expected angular physical distribution 816 of the light processed by an optical device. Further, the operation 2806 illustrates defining the first set of angular positions and the second set of angular positions according to the expected statistical variation of the angular distribution of the light from the light source processed by at least one optical device. For example, as shown in FIG. 8, the first set of angular positions 804 of the surface normal of the first device A₁ and the second set of angular positions 804 of the surface normal of the second device A₂ may be defined according to the expected angular statistical distribution 818 of the light processed by an optical device.

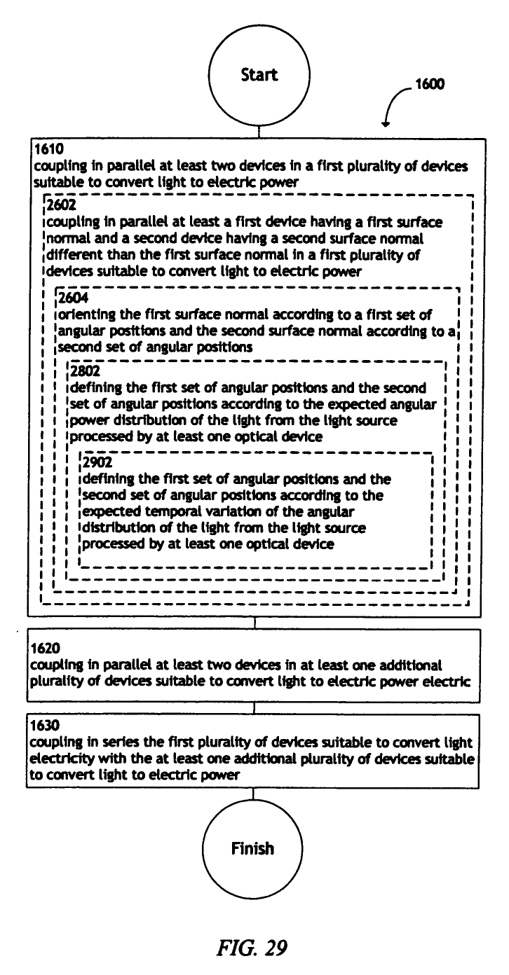

FIG. 29 illustrates alternative embodiments of the example operational flow 1600 of FIG. 16. FIG. 29 illustrates example embodiments where the operation 1610 may include at least one additional operation. Additional operations may include an operation 2902. Further, the operation 2902 illustrates defining the first set of angular positions and the second set of angular positions according to the expected temporal variation of the angular distribution of the light from the light source processed by at least one optical device. For example, as shown in FIG. 8, the first set of angular positions 804 of the surface normal of the first device A₁ and the second set of angular positions 804 of the surface normal of the second device A₂ may be defined according to the expected angular temporal distribution 820 of the light processed by an optical device.

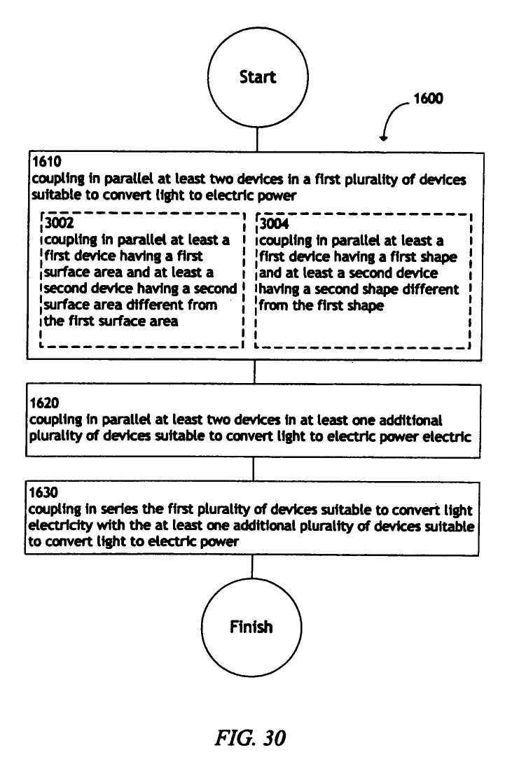

FIG. 30 illustrates alternative embodiments of the example operational flow 1600 of FIG. 16. FIG. 30 illustrates example embodiments where the operation 1610 may include at least one additional operation. Additional operations may include an operation 3002, and/or an operation 3004.

The operation 3002 illustrates coupling in parallel at least a first device having a first surface area and at least a second device having a second surface area different from the first surface area. For example, as shown in FIG. 1, the first device A₁ of the first set of devices 102 suitable to convert light to electric power may have a first surface area and the second device A₂ of the first set of devices 102 suitable to convert light to electric power may have a second surface area.

The operation 3004 illustrates coupling in parallel at least a first device having a first shape and at least a second device having a second shape different from the first shape. For example, as shown in FIG. 1, the first device A₁ of the first set of devices 102 suitable to convert light to electric power may have a first shape (e.g., square, rectangle, parallelogram, polygon, ellipse, circle, or irregular shape), and the second device A₂ of the first set of devices 102 suitable to convert light to electric power may have a second shape.

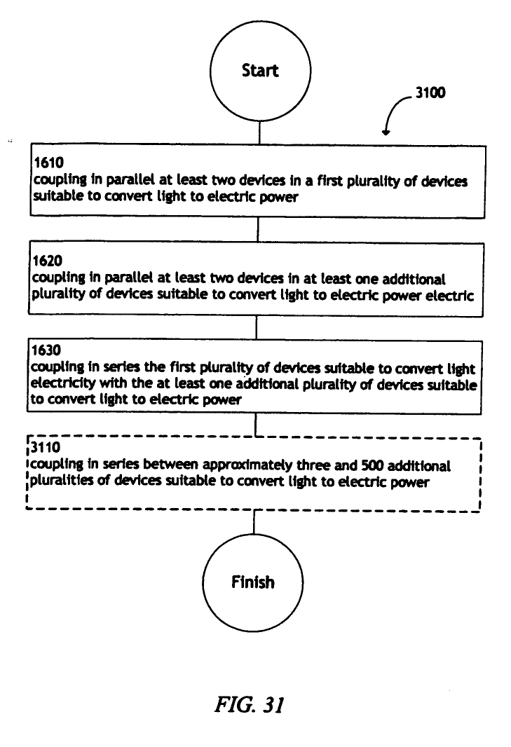

FIG. 31 illustrates an operational flow 3100 representing example operations related to the system and method to convert light to electrical power. FIG. 31 illustrates an example embodiment where the example operational flow 1600 of FIG. 16 may include at least one additional operation. Additional operations may include an operation 3110.

After a start operation, an operation 1610, an operation 1620, and an operation 1630, the operational flow 3100 moves to an operation 3110. Operation 3110 illustrates coupling in series between approximately three and 500 additional pluralities of devices suitable to convert light to electric power. For example, as shown in FIG. 1, the first set of devices 102 may be coupled in series with a number of additional sets of devices, such as the second set of devices 104, including at least a third set of devices 106, and up to and including a 500th set of devices 108.

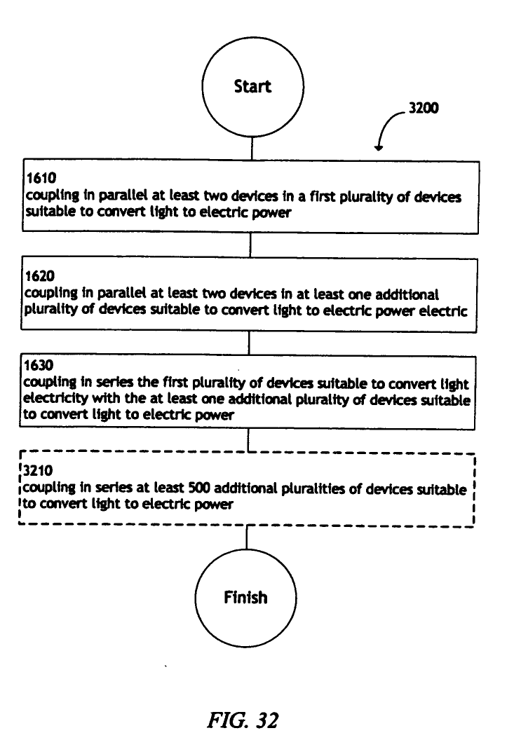

FIG. 32 illustrates an operational flow 3200 representing example operations related to the system and method to convert light to electrical power. FIG. 32 illustrates an example embodiment where the example operational flow 1600 of FIG. 16 may include at least one additional operation. Additional operations may include an operation 3210.

After a start operation, an operation 1610, an operation 1620, and an operation 1630, the operational flow 3200 moves to an operation 3210. Operation 3210 illustrates coupling in series at least 500 additional pluralities of devices suitable to convert light to electric power. For example, as shown in FIG. 1, the first set of devices 102 may be coupled in series with a number of additional sets of devices, such as the second set of devices 104, including at least a 500th set of devices 108, and up to a Mth set of devices 110.

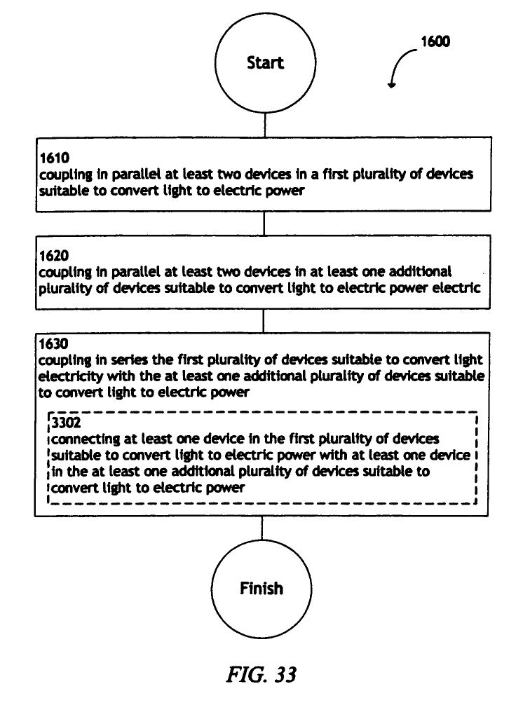

FIG. 33 illustrates alternative embodiments of the example operational flow 1600 of FIG. 16. FIG. 33 illustrates example embodiments where the operation 1630 may include at least one additional operation. Additional operations may include an operation 3302.

The operation 3302 illustrates connecting at least one device in the first plurality of devices suitable to convert light to electric power with at least one device in the at least one additional plurality of devices suitable to convert light to electric power. For example, as shown in FIG. 9, the first device A₁ of the first set of devices suitable to convert light to electric power may be electrically connected 902 to one of the devices of the second set of devices suitable to convert light to electric power, such as the first device B₁ of the second set of devices. Further, the second device A₂ of the first set of devices may be electrically connected 904 to one of the devices of the second set of devices, such as the second device B₂ of the second set of devices. In general, A_{N} of the first set of devices may be electrically connected 906 to B_{N} of the second set of devices.

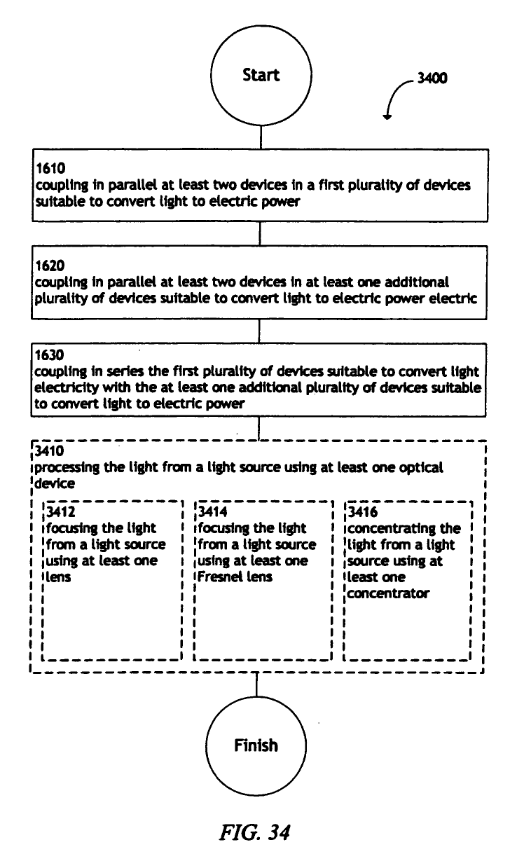

FIG. 34 illustrates an operational flow 3400 representing example operations related to the system and method to convert light to electrical power. FIG. 34 illustrates an example embodiment where the example operational flow 1600 of FIG. 16 may include at least one additional operation. Additional operations may include an operation 3410, an operation 3412, an operation 3414, and/or an operation 3416.

After a start operation, an operation 1610, an operation 1620, and an operation 1630, the operational flow 3400 moves to an operation 3410. Operation 3410 illustrates processing the light from a light source using at least one optical device. For example, as shown in FIG. 10, the light from the light source 1002 may be processed by one or more optical devices 1004 before impinging on the first device A₁ of the first set of devices 102 suitable to convert light to electric.

The operation 3412 illustrates focusing the tight from a tight source using at least one lens. For example, as shown in FIG. 10, the light from the light source 1002 may be processed by one or more tenses 1006 before impinging on the first device A₁ of the first set of devices 102 suitable to convert light to electric.

The operation 3414 illustrates focusing the light from a light source using at least one Fresnel lens. For example, as shown in FIG. 10, the light from the light source 1002 may be processed by one or more Fresnel lenses 1008 before impinging on the first device A₁ of the first set of devices 102 suitable to convert light to electric.

The operation 3416 illustrates concentrating the light from a light source using at least one concentrator. For example, as shown in FIG. 10, the light from the light source 1002 may be processed by one or more concentrators 1010 before impinging on the first device A₁ of the first set of devices 102 suitable to convert light to electric.

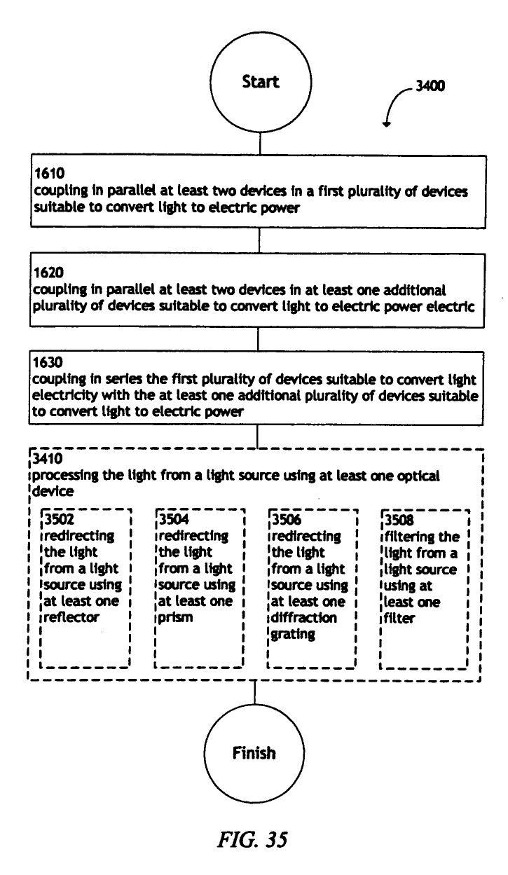

FIG. 35 illustrates alternative embodiments of the example operational flow 3400 of FIG. 34. FIG. 35 illustrates example embodiments where the operation 3410 may include at least one additional operation. Additional operations may include an operation 3502, an operation 3504, an operation 3506, and/or an operation 3508.

The operation 3502 illustrates redirecting the light from a light source using at least one reflector. For example, as shown in FIG. 10, the light from the tight source 1002 may be processed by one or more reflectors 1012 before impinging on the first device A₁ of the first set of devices 102 suitable to convert light to electric.

The operation 3504 illustrates redirecting the light from a light source using at least one prism. For example, as shown in FIG. 10, the light from the light source 1002 may be processed by one or more prisms 1014 before impinging on the first device A₁ of the first set of devices 102 suitable to convert light to electric.

The operation 3506 illustrates redirecting the light from a light source using at least one diffraction grating. For example, as shown in FIG. 10, the light from the light source 1002 may be processed by one or more diffraction gratings 1014 before impinging on the first device A₁ of the first set of devices 102 suitable to convert light to electric.

The operation 3508 illustrates filtering the light from a light source using at least one filter. For example, as shown in FIG. 10, the light from the light source 1002 may be processed by one or more filters 1018 before impinging on the first device A₁ of the first set of devices 102 suitable to convert light to electric.

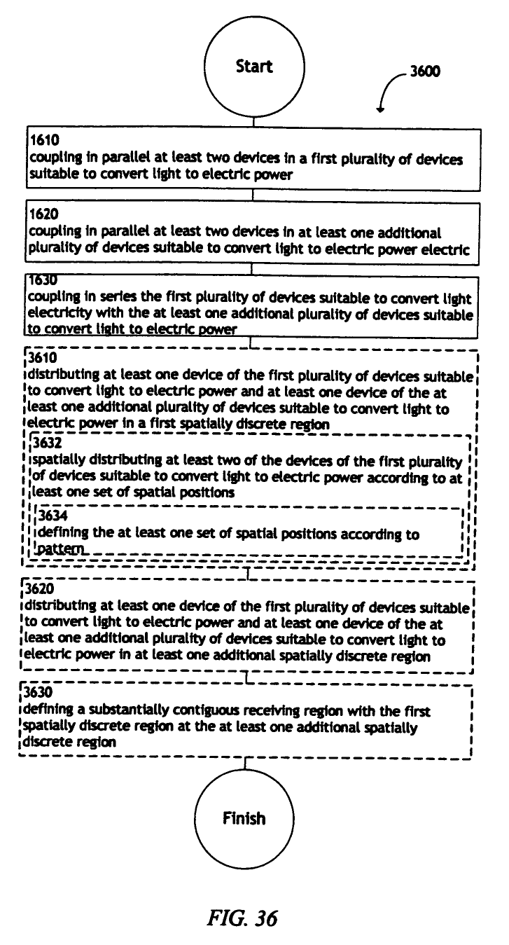

FIG. 36 illustrates an operational flow 3600 representing example operations related to the system and method to convert light to electrical power. FIG. 36 illustrates an example embodiment where the example operational flow 1600 of FIG. 16 may include at least one additional operation. Additional operations may include an operation 3610, an operation 3620, an operation 3630, an operation 3632, and/or an operation 3634.

After a start operation, an operation 1610, an operation 1620, and an operation 1630, the operational flow 3600 moves to an operation 3610. Operation 3610 illustrates distributing at least one device of the first plurality of devices suitable to convert light to electric power and at least one device of the at least one additional plurality of devices suitable to convert light to electric power in a first spatially discrete region. For example, as shown in FIG. 11, the first device A₁ of the first set of devices 102 may be distributed such that it spatially resides in a first spatially discrete region 1102, the first device B₁ of the second set of devices 104 may be distributed such that it spatially resides in the first spatially discrete region 1102, the first device C₁ of the third set of devices 106 may be distributed such that it spatially resides in a first spatially discrete region 1102, and the first device D₁ of the fourth set of devices may be distributed such that it spatially resides in a first spatially discrete region 1102. Further, up to and including an Nth device M_{N} of the Mth set of devices 110 of devices may be distributed such that it spatially resides in a first spatially discrete region 1102.

Then, operation 3620 illustrates distributing at least one device of the first plurality of devices suitable to convert light to electric power and at least one device of the at least one additional plurality of devices suitable to convert light to electric power in at least one additional spatially discrete region. For example, as shown in FIG. 11, the second device A₂ of the first set of devices 102 may be distributed such that it spatially resides in a second spatially discrete region 1104, the second device B₂ of the second set of devices 104 may be distributed such that it spatially resides in the second spatially discrete region 1104, the second device C₂ of the third set of devices 106 may be distributed such that it spatially resides in the second spatially discrete region 1104, and the second device D₂ of the fourth set of devices may be distributed such that it spatially resides in the second spatially discrete region 1104. Further, up to and including an Nth device M_{N} of the Mth set of devices 110 may be distributed such that it spatially resides in a second spatially discrete region 1104.

Further, the Nth device A_{N} of the first set of devices 102 may be distributed such that it spatially resides in a Nth spatially discrete region 1106, the Nth device B_{N} of the second set of devices 104 may be distributed such that it spatially resides in the Nth spatially discrete region 1106, the Nth device C_{N} of the third set of devices 106 may be distributed such that it spatially resides in the Nth spatially discrete region 1106, and the Nth device D_{N} of the fourth set of devices may be distributed such that it spatially resides in the Nth spatially discrete region 1106. Further, up to and including an Nth device M_{N} of the Mth set of devices 110 may be distributed such that it spatially resides in a Nth spatially discrete region 1106.

Then, operation 3630 illustrates defining a substantially contiguous receiving region with the first spatially discrete region at the at least one additional spatially discrete region. For example, as shown in FIG. 11, the first spatially discrete region 1102, the second spatially discrete region 1104, and up to and including the Nth spatially discrete region 1106 may be arranged to form a region of devices 1108 suitable to convert light to electric power that is substantially contiguous.

The operation 3632 illustrates spatially distributing at least two of the devices of the first plurality of devices suitable to convert light to electric power according to at least one set of spatial positions. For example, as shown in FIG. 12, the first device A₁ of the first set 102 of devices suitable to convert light to electric power, the second device A₂ of the first set of 102 of devices suitable to convert light to electric power, and up to the Nth device A_{N} of the first set 102 of devices suitable to convert light to electric power may be distributed with respect to each other according to a set of positions 1202 in three-dimensional space. Further, the operation 3634 illustrates defining the at least one set of spatial positions according to pattern. For example, as shown in FIG. 12, the first device A₁ of the first set 102 of devices suitable to convert light to electric power, the second device A₂ of the first set of 102 of devices suitable to convert light to electric power, and up to the Nth device A_{N} of the first set 102 of devices suitable to convert light to electric power may be distributed with respect to each other according to a pattern 1204.

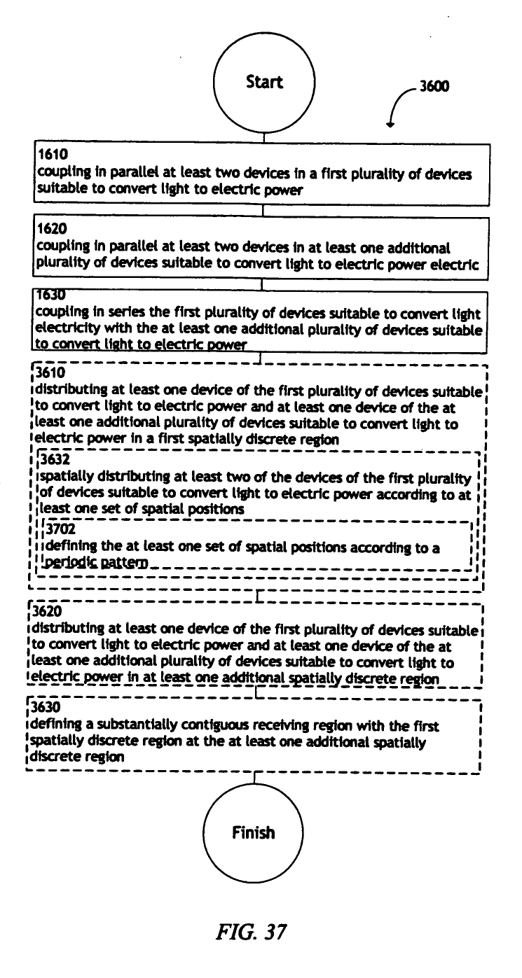

FIG. 37 illustrates alternative embodiments of the example operational flow 3600 of FIG. 36. FIG. 37 illustrates example embodiments where the operation 3610 may include at least one additional operation. Additional operations may include an operation 3702. Further, the operation 3702 illustrates defining the at least one set of spatial positions according to a periodic pattern. For example, as shown in FIG. 12, the first device A₁ of the first set 102 of devices suitable to convert light to electric power, the second device A₂ of the first set of 102 of devices suitable to convert light to electric power, and up to the Nth device A_{N} of the first set 102 of devices suitable to convert light to electric power may be distributed with respect to each other according to a periodic pattern 1206.

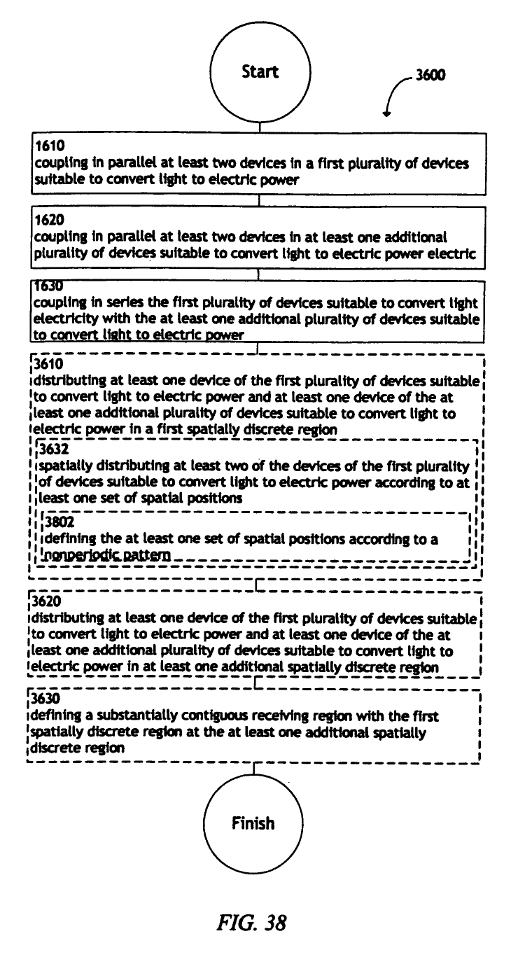

FIG. 38 illustrates alternative embodiments of the example operational flow 3600 of FIG. 36. FIG. 38 illustrates example embodiments where the operation 3610 may include at least one additional operation. Additional operations may include an operation 3802. Further, the operation 3802 illustrates defining the at least one set of spatial positions according to a nonperiodic pattern. For example, as shown in FIG. 12, the first device A₁ of the first set 102 of devices suitable to convert light to electric power, the second device A₂ of the first set of 102 of devices suitable to convert light to electric power, and up to the Nth device A_{N} of the first set 102 of devices suitable to convert light to electric power may be distributed with respect to each other according to a non-periodic pattern 1208.

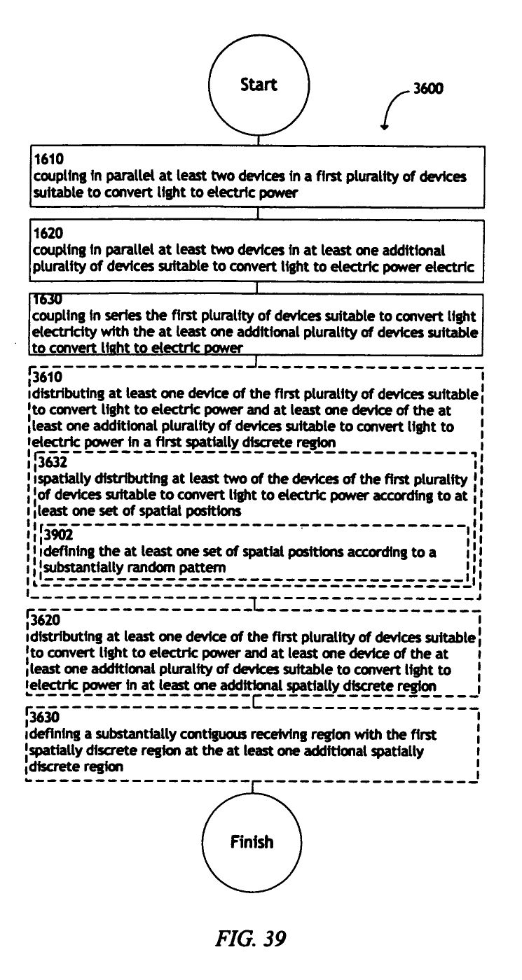

FIG. 39 illustrates alternative embodiments of the example operational flow 3600 of FIG. 36. FIG. 39 illustrates example embodiments where the operation 3610 may include at least one additional operation. Additional operations may include an operation 3902. Further, the operation 3902 illustrates defining the at least one set of spatial positions according to a substantially random pattern. For example, FIG. 12, the first device A₁ of the first set 102 of devices suitable to convert light to electric power, the second device A₂ of the first set of 102 of devices suitable to convert light to electric power, and up to the Nth device A_{N} of the first set 102 of devices suitable to convert light to electric power may be distributed with respect to each other according to a random pattern 1210.

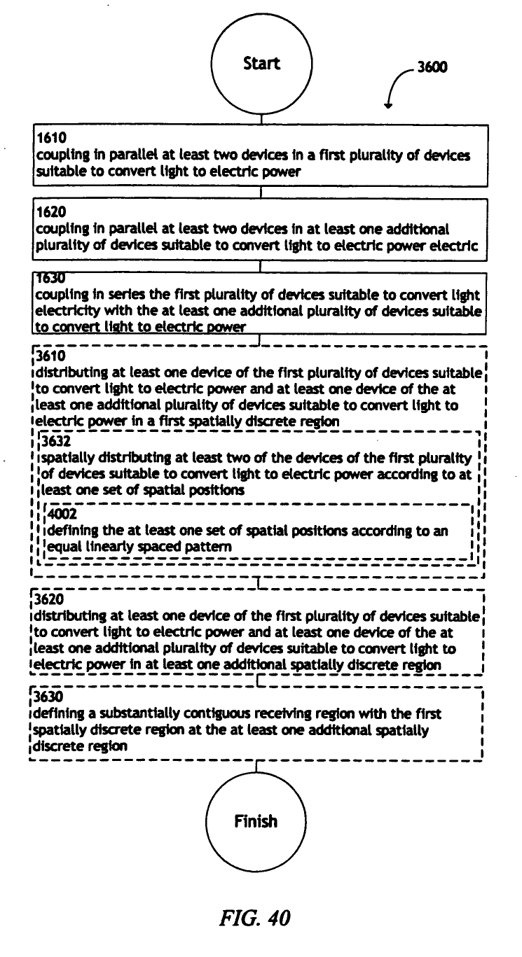

FIG. 40 illustrates alternative embodiments of the example operational flow 3600 of FIG. 36. FIG. 40 illustrates example embodiments where the operation 3610 may include at least one additional operation. Additional operations may include an operation 4002. Further, the operation 4002 illustrates defining the at least one set of spatial positions according to an equal linearly spaced pattern. For example, as shown in FIG. 12, the first device A₁ of the first set 102 of devices suitable to convert light to electric power, the second device A₂ of the first set of 102 of devices suitable to convert light to electric power, and up to the Nth device A_{N} of the first set 102 of devices suitable to convert light to electric power may be distributed with respect to each other according to an equal linearly spaced pattern 1212.

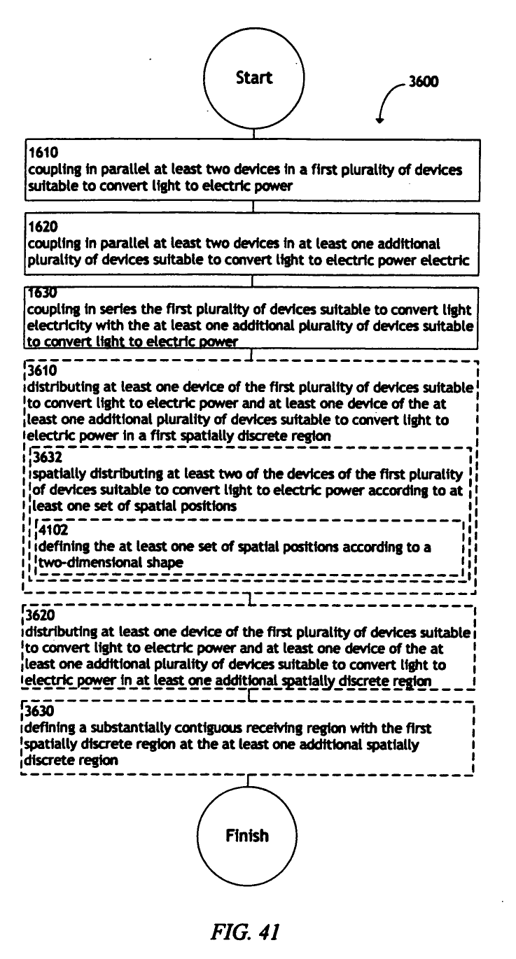

FIG. 41 illustrates alternative embodiments of the example operational flow 3600 of FIG. 36. FIG. 41 illustrates example embodiments where the operation 3610 may include at least one additional operation. Additional operations may include an operation 4102. Further, the operation 4102 illustrates defining the at least one set of spatial positions according to a two-dimensional shape. FIG. 12, the first device A₁ of the first set 102 of devices suitable to convert light to electric power, the second device A₂ of the first set of 102 of devices suitable to convert light to electric power, and up to the Nth device A_{N} of the first set 102 of devices suitable to convert light to electric power may be distributed with respect to each other according to a two-dimensional shape 1214.

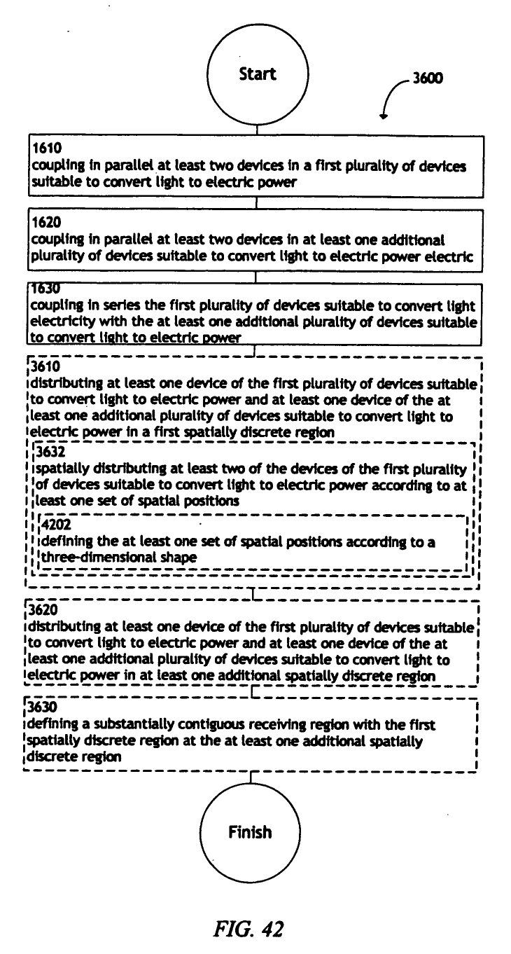

FIG. 42 illustrates alternative embodiments of the example operational flow 3600 of FIG. 36. FIG. 42 illustrates example embodiments where the operation 3610 may include at least one additional operation. Additional operations may include an operation 4202. Further, the operation 4202 illustrates defining the at least one set of spatial positions according to a three-dimensional shape. For example, as shown in FIG. 12, the first device A₁ of the first set 102 of devices suitable to convert tight to electric power, the second device A₂ of the first set of 102 of devices suitable to convert light to electric power, and up to the Nth device A_{N} of the first set 102 of devices suitable to convert light to electric power may be distributed with respect to each other according to a three-dimensional shape 1216.

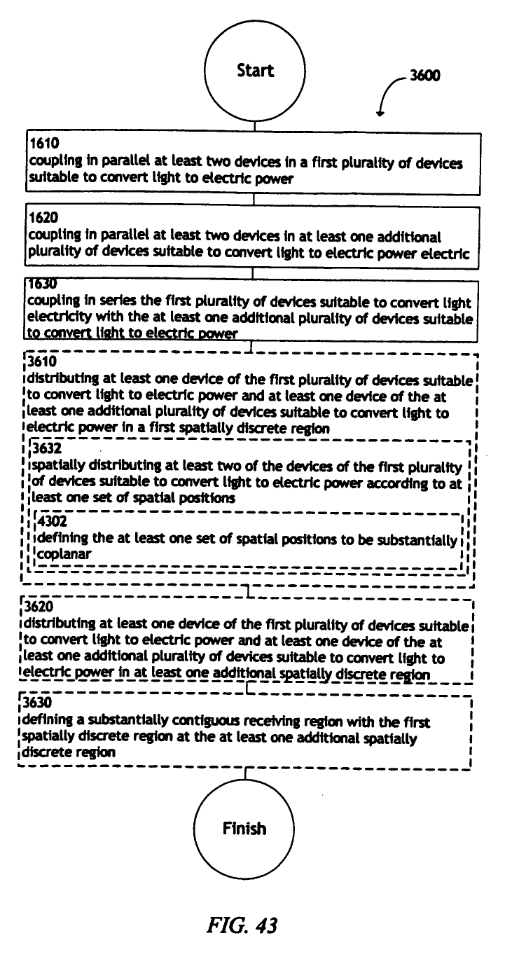

FIG. 43 illustrates alternative embodiments of the example operational flow 3600 of FIG. 36. FIG. 43 illustrates example embodiments where the operation 3610 may include at least one additional operation. Additional operations may include an operation 4302. Further, the operation 4302 illustrates defining the at least one set of spatial positions to be substantially coplanar. For example, as shown in FIG. 12, the first device A₁ of the first set 102 of devices suitable to convert light to electric power, the second device A₂ of the first set of 102 of devices suitable to convert light to electric power, and up to the Nth device A_{N} of the first set 102 of devices suitable to convert light to electric power may be distributed such that the spatial positions of the devices are substantially coplanar 1218.

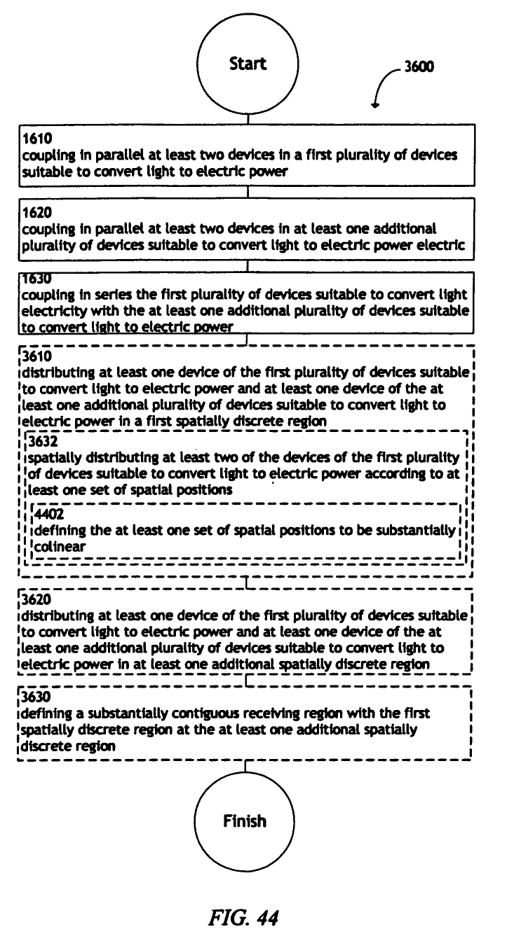

FIG. 44 illustrates alternative embodiments of the example operational flow 3600 of FIG. 36. FIG. 44 illustrates example embodiments where the operation 3610 may include at least one additional operation. Additional operations may include an operation 4402. Further, the operation 4402 illustrates defining the at least one set of spatial positions to be substantially colinear. For example, as shown in FIG. 12, the first device A₁ of the first set 102 of devices suitable to convert light to electric power, the second device A₂ of the first set of 102 of devices suitable to convert light to electric power, and up to the Nth device A_{N} of the first set 102 of devices suitable to convert light to electric power may be distributed such that spatial positions of the devices are substantially colinear 1220.

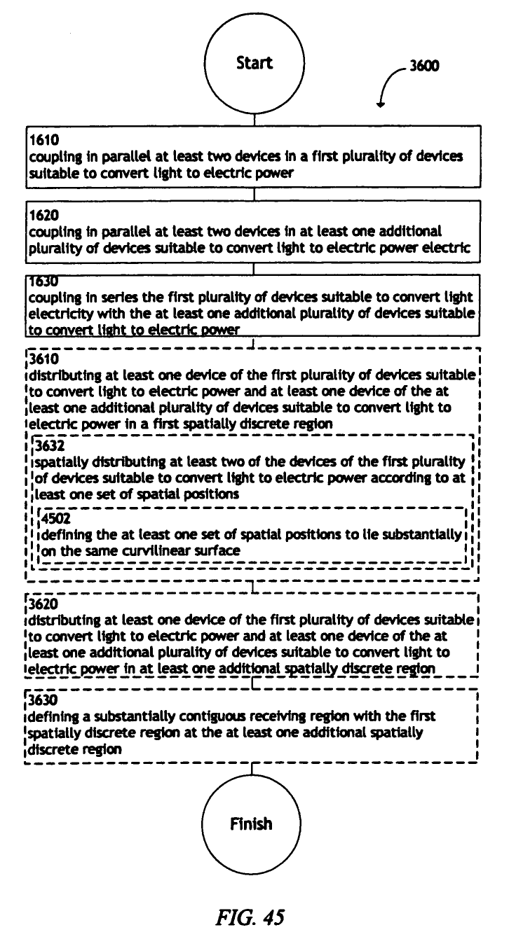

FIG. 45 illustrates alternative embodiments of the example operational flow 3600 of FIG. 36. FIG. 45 illustrates example embodiments where the operation 3610 may include at least one additional operation. Additional operations may include an operation 4502. Further, the operation 4502 illustrates defining the at least one set of spatial positions to lie substantially on the same curvilinear surface. For example, as shown in FIG. 12, the first device A₁ of the first set 102 of devices suitable to convert light to electric power, the second device A₂ of the first set of 102 of devices suitable to convert light to electric power, and up to the Nth device A_{N} of the first set 102 of devices suitable to convert light to electric power may be distributed such that the spatial positions of the devices lie on the same curvilinear surface 1222.

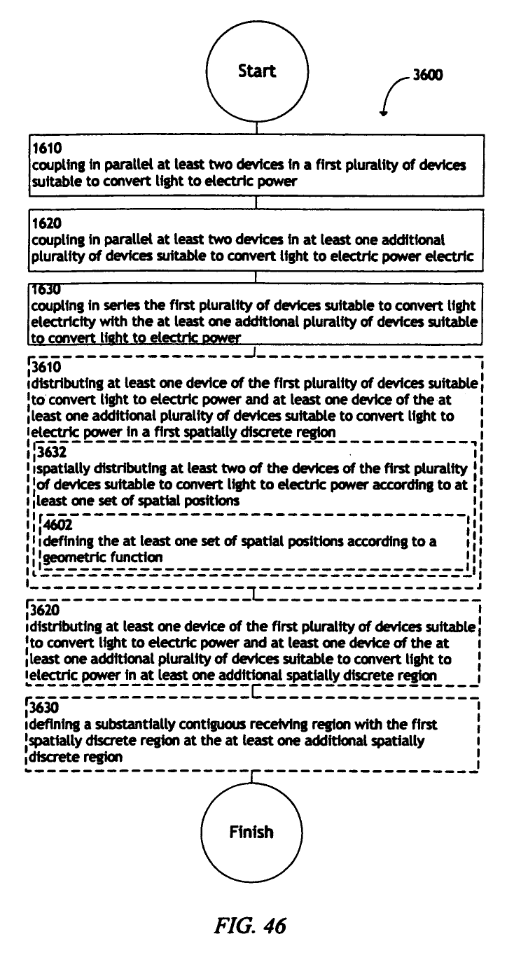

FIG. 46 illustrates alternative embodiments of the example operational flow 3600 of FIG. 36. FIG. 46 illustrates example embodiments where the operation 3610 may include at least one additional operation. Additional operations may include an operation 4602. Further, the operation 4602 illustrates defining the at least one set of spatial positions according to a geometric function. For example, as shown in FIG. 12, the first device A₁ of the first set 102 of devices suitable to convert light to electric power, the second device A₂ of the first set of 102 of devices suitable to convert tight to electric power, and up to the Nth device A_{N} of the first set 102 of devices suitable to convert light to electric power may be distributed with respect to each other according to a geometric function 1224.

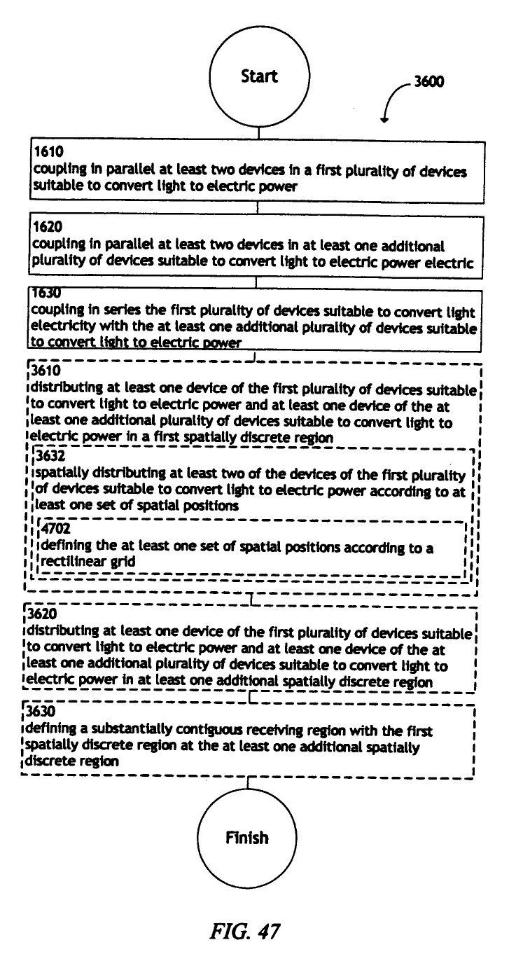

FIG. 47 illustrates alternative embodiments of the example operational flow 3600 of FIG. 36. FIG. 47 illustrates example embodiments where the operation 3610 may include at least one additional operation. Additional operations may include an operation 4702. Further, the operation 4702 illustrates defining the at least one set of spatial positions according to a rectilinear grid. For example, as shown in FIG. 12, the first device A₁ of the first set 102 of devices suitable to convert light to electric power, the second device A₂ of the first set of 102 of devices suitable to convert light to electric power, and up to the Nth device A_{N} of the first set 102 of devices suitable to convert light to electric power may be distributed with respect to each other according to a rectilinear grid 1226.

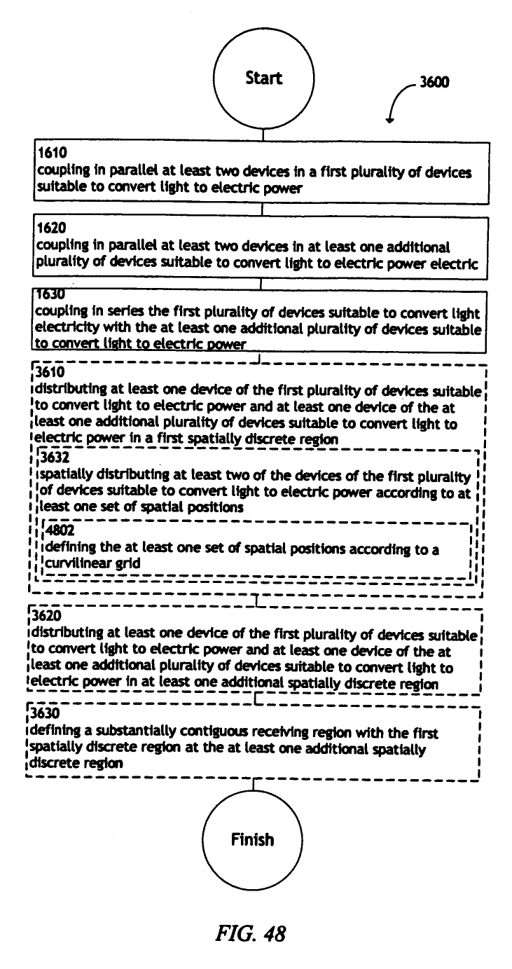

FIG. 48 illustrates alternative embodiments of the example operational flow 3600 of FIG. 36. FIG. 48 illustrates example embodiments where the operation 3610 may include at least one additional operation. Additional operations may include an operation 4802. Further, the operation 4802 illustrates defining the at least one set of spatial positions according to a curvilinear grid. For example, as shown in FIG. 12, the first device A₁ of the first set 102 of devices suitable to convert light to electric power, the second device A₂ of the first set of 102 of devices suitable to convert light to electric power, and up to the Nth device A_{N} of the first set 102 of devices suitable to convert light to electric power may be distributed with respect to each other according to a curvilinear grid 1228.

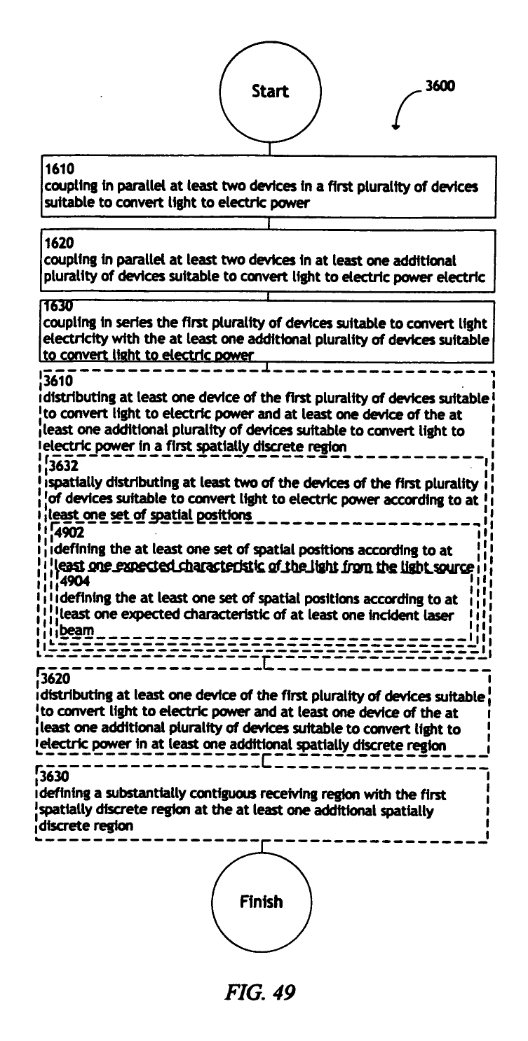

FIG. 49 illustrates alternative embodiments of the example operational flow 3600 of FIG. 36. FIG. 49 illustrates example embodiments where the operation 3610 may include at least one additional operation. Additional operations may include an operation 4902, and/or an operation 4904. Further, the operation 4902 illustrates defining the at least one set of spatial positions according to at least one expected characteristic of the light from the light source. For example, as shown in FIG. 12, the first device A₁ of the first set 102 of devices suitable to convert light to electric power, the second device A₂ of the first set of 102 of devices suitable to convert light to electric power, and up to the Nth device A_{N} of the first set 102 of devices suitable to convert light to electric power may be distributed with respect to each other according to one or more expected characteristics of the tight from the light source 1230. Further, the operation 4904 illustrates defining the at least one set of spatial positions according to at least one expected characteristic of at least one incident laser beam. For example, as shown in FIG. 12, the first device A₁ of the first set 102 of devices suitable to convert light to electric power, the second device A₂ of the first set of 102 of devices suitable to convert light to electric power, and up to the Nth device A_{N} of the first set 102 of devices suitable to convert light to electric power may be distributed with respect to each other according to one or more expected characteristics of the light from a laser 1240.

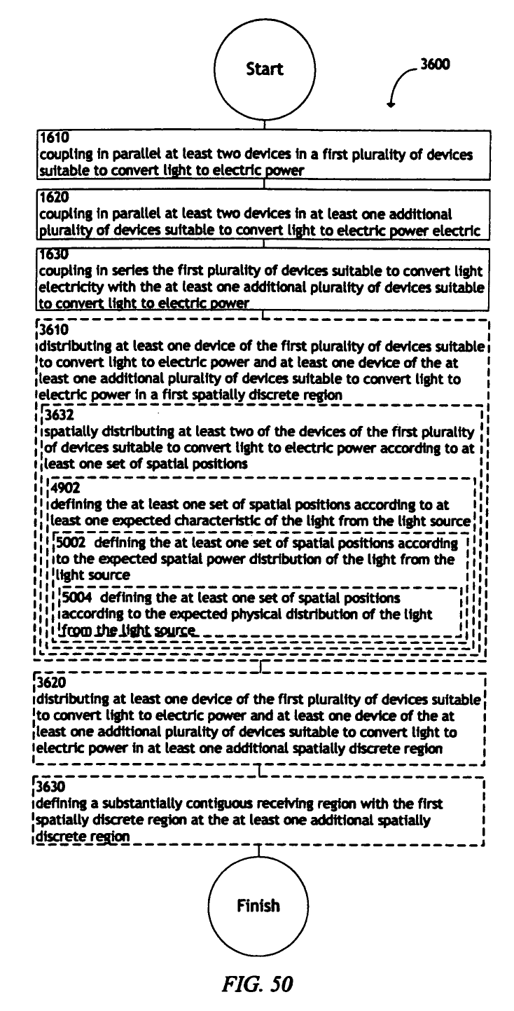

FIG. 50 illustrates alternative embodiments of the example operational flow 3600 of FIG. 36. FIG. 50 illustrates example embodiments where the operation 3610 may include at least one additional operation. Additional operations may include an operation 5002, and/or an operation 5004. Further, the operation 5002 illustrates defining the at least one set of spatial positions according to the expected spatial power distribution of the light from the light source. For example, as shown in FIG. 12, the first device A₁ of the first set 102 of devices suitable to convert light to electric power, the second device A₂ of the first set of 102 of devices suitable to convert light to electric power, and up to the Nth device A_{N} of the first set 102 of devices suitable to convert light to electric power may be distributed with respect to each other according to the expected spatial power distribution of the tight from the light source 1232. Further, the operation 5004 illustrates defining the at least one set of spatial positions according to the expected physical distribution of the light from the light source. For example, as shown in FIG. 12, the first device A₁ of the first set 102 of devices suitable to convert light to electric power, the second device A₂ of the first set of 102 of devices suitable to convert light to electric power, and up to the Nth device A_{N} of the first set 102 of devices suitable to convert light to electric power may be distributed with respect to each other according to the expected physical power distribution of the light from the light source 1234.

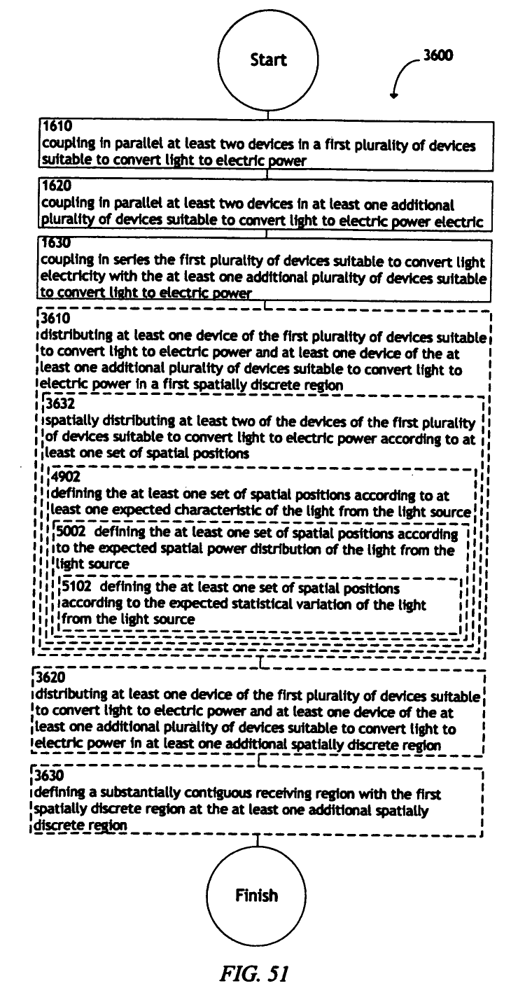

FIG. 51 illustrates alternative embodiments of the example operational flow 3600 of FIG. 36. FIG. 51 illustrates example embodiments where the operation 3610 may include at least one additional operation. Additional operations may include an operation 5102. Further, the operation 5102 illustrates defining the at least one set of spatial positions according to the expected statistical variation of the light from the light source. For example, as shown in FIG. 12, the first device A₁ of the first set 102 of devices suitable to convert light to electric power, the second device A₂ of the first set of 102 of devices suitable to convert light to electric power, and up to the Nth device A_{N} of the first set 102 of devices suitable to convert tight to electric power may be distributed with respect to each other according to the expected statistical variation of the light from the tight source 1236.

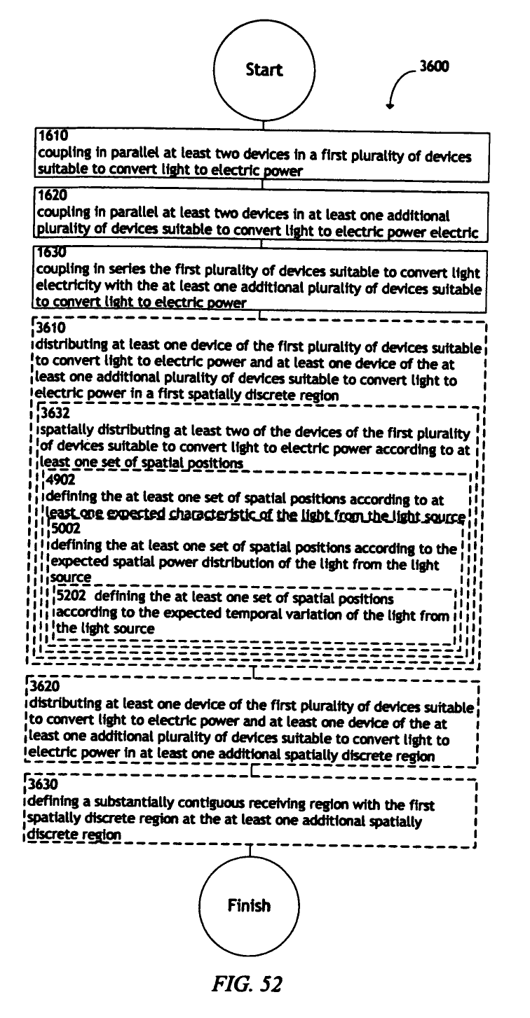

FIG. 52 illustrates alternative embodiments of the example operational flow 3600 of FIG. 36. FIG. 52 illustrates example embodiments where the operation 3610 may include at least one additional operation. Additional operations may include an operation 5202. Further, the operation 5202 illustrates defining the at least one set of spatial positions according to the expected temporal variation of the light from the light source. For example, as shown in FIG. 12, the first device A₁ of the first set 102 of devices suitable to convert tight to electric power, the second device A₂ of the first set of 102 of devices suitable to convert tight to electric power, and up to the Nth device A_{N} of the first set 102 of devices suitable to convert light to electric power may be distributed with respect to each other according to the expected temporal variation of the light from the light source 1238.

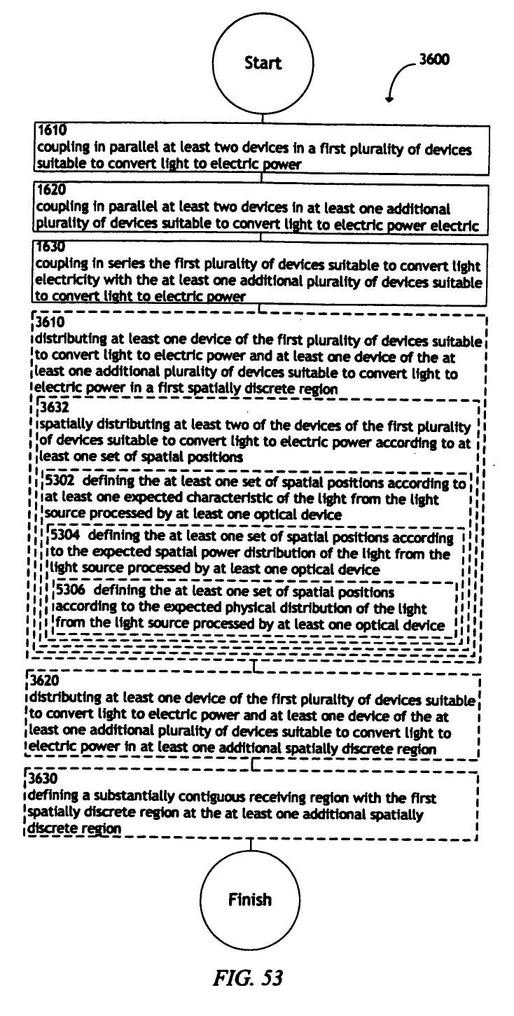

FIG. 53 illustrates alternative embodiments of the example operational flow 3600 of FIG. 36. FIG. 53 illustrates example embodiments where the operation 3610 may include at least one additional operation. Additional operations may include an operation 5302, an operation 5304, and/or an operation 5306. Further, the operation 5302 illustrates defining the at least one set of spatial positions according to at least one expected characteristic of the light from the tight source processed by at least one optical device. For example, as shown in FIG. 12, the first device A₁ of the first set 102 of devices suitable to convert light to electric power, the second device A₂ of the first set of 102 of devices suitable to convert light to electric power, and up to the Nth device A_{N} of the first set 102 of devices suitable to convert light to electric power may be distributed with respect to each other according to one or more expected characteristics of the light from the light source processed by an optical device. Further, the operation 5304 illustrates defining the at least one set of spatial positions according to the expected spatial power distribution of the light from the light source processed by at least one optical device. For example, as shown in FIG. 12, the first device A₁ of the first set 102 of devices suitable to convert light to electric power, the second device A₂ of the first set of 102 of devices suitable to convert light to electric power, and up to the Nth device A_{N} of the first set 102 of devices suitable to convert light to electric power may be distributed with respect to each other according to expected spatial power distribution of the light from the light source processed by an optical device 1244. Further, the operation 5306 illustrates defining the at least one set of spatial positions according to the expected physical distribution of the light from the light source processed by at least one optical device. For example, as shown in FIG. 12, the first device A₁ of the first set 102 of devices suitable to convert light to electric power, the second device A₂ of the first set of 102 of devices suitable to convert light to electric power, and up to the Nth device A_{N} of the first set 102 of devices suitable to convert light to electric power may be distributed with respect to each other according to the expected physical distribution of the light from the light source processed by an optical device 1246.

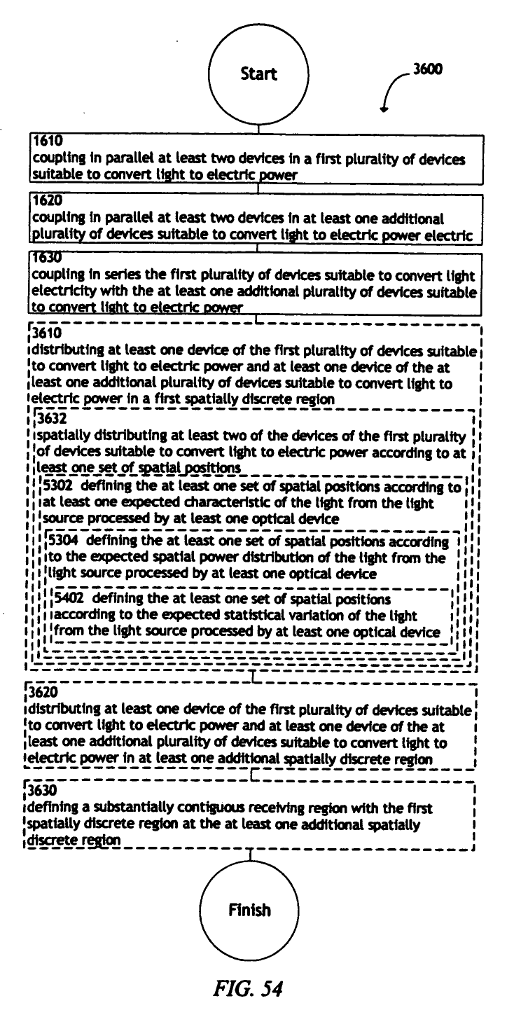

FIG. 54 illustrates alternative embodiments of the example operational flow 3600 of FIG. 36. FIG. 54 illustrates example embodiments where the operation 3610 may include at least one additional operation. Additional operations may include an operation 5402. Further, the operation 5402 illustrates defining the at least one set of spatial positions according to the expected statistical variation of the light from the light source processed by at least one optical device. For example, as shown in FIG. 12, the first device A₁ of the first set 102 of devices suitable to convert light to electric power, the second device A₂ of the first set of 102 of devices suitable to convert light to electric power, and up to the Nth device A_{N} of the first set 102 of devices suitable to convert light to electric power may be distributed with respect to each other according to the expected statistical variation of the light from the light source processed by an optical device 1248.

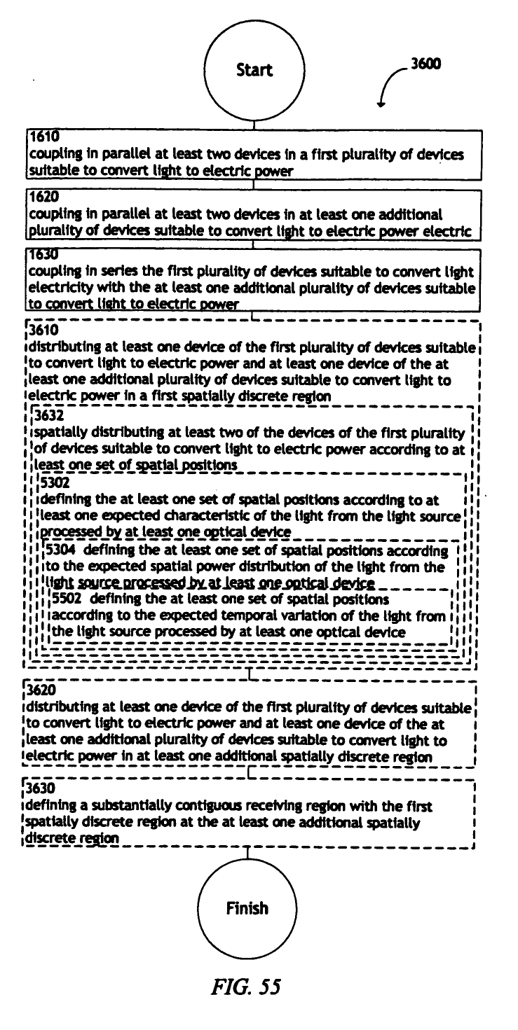

FIG. 55 illustrates alternative embodiments of the example operational flow 3600 of FIG. 36. FIG. 55 illustrates example embodiments where the operation 3610 may include at least one additional operation. Additional operations may include an operation 5502. Further, the operation 5502 illustrates defining the at least one set of spatial positions according to the expected temporal variation of the light from the light source processed by at least one optical device. For example, as shown in FIG. 12, the first device A₁ of the first set 102 of devices suitable to convert tight to electric power, the second device A₂ of the first set of 102 of devices suitable to convert light to electric power, and up to the Nth device A_{N} of the first set 102 of devices suitable to convert light to electric power may be distributed with respect to each other according to the expected temporal variation of the light from the light source processed by an optical device 1250.

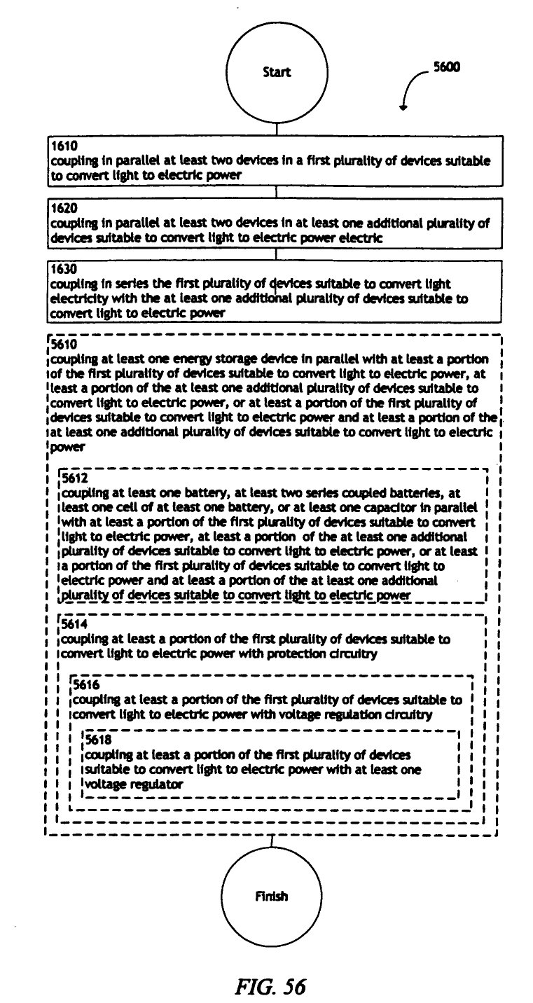

FIG. 56 illustrates an operational flow 5600 representing example operations related to the system and method to convert light to electrical power. FIG. 56 illustrates an example embodiment where the example operational flow 1600 of FIG. 16 may include at least one additional operation. Additional operations may include an operation 5610, an operation 5612, an operation 5614, an operation 5616, and/or an operation 5618.

After a start operation, an operation 1610, an operation 1620, and an operation 1630, the operational flow 5600 moves to an operation 5610. Operation 5610 illustrates coupling at least one energy storage device in parallel with at least a portion of the first plurality of devices suitable to convert light to electric power, at least a portion of the at least one additional plurality of devices suitable to convert light to electric power, or at least a portion of the first plurality of devices suitable to convert light to electric power and at least a portion of the at least one additional plurality of devices suitable to convert light to electric power. For example, as shown in FIG. 13A, the first set of devices 102 suitable to convert light to electric power, and/or the second set of devices 104 suitable to convert light to electric power may be coupled in parallel with an energy storage device 1302. Further, a number of sets of devices may be individually or collectively coupled in parallel with an energy storage device 1302, up to and including the Mth set of devices 110 suitable to convert light to electric power.

The operation 5612 illustrates coupling at least one battery, at least two series coupled batteries, at least one cell of at least one battery, or at least one capacitor in parallel with at least a portion of the first plurality of devices suitable to convert light to electric power, at least a portion of the at least one additional plurality of devices suitable to convert light to electric power, or at least a portion of the first plurality of devices suitable to convert light to electric power and at least a portion of the at least one additional plurality of devices suitable to convert light to electric power. For example, as shown in FIG. 13A, the first set of devices 102 suitable to convert light to electric power, and/or the second set of devices 104 suitable to convert light to electric power may be coupled in parallel with a battery 1304, a set of series coupled batteries 1306, an individual battery cell 1308, or a capacitor 1310. Further, a number of sets of devices may be individually or collectively coupled in parallel with a battery 1304, a set of series coupled batteries 1306, an individual battery cell 1308, or a capacitor 1310, up to and including the Mth set of devices 110 suitable to convert light to electric power. For example, the battery 1304 may include a rechargeable battery, such as a Lithium-Ion battery. By way of another example, the capacitor 1310 may include an electrolytic capacitor, ceramic capacitor, organic film capacitor, high dielectric constant ferroelectric capacitor or nanostructured supercapacitor. Further, the operation 5614 illustrates coupling at least a portion of the first plurality of devices suitable to convert light to electric power with protection circuitry. For example, as shown in FIG. 13A, the first set of devices 102 suitable to convert light to electric power, and/or the second set of devices 104 suitable to convert light to electric power may be coupled in parallel with protection circuitry 1311. Further, a number of sets of devices may be individually or collectively coupled in parallel with protection circuitry 1311, up to and including the Mth set of devices 110 suitable to convert light to electric power. Further, the operation 5616 illustrates coupling at least a portion of the first plurality of devices suitable to convert light to electric power with voltage regulation circuitry. For example, as shown in FIG. 13A, the first set of devices 102 suitable to convert light to electric power, and/or the second set of devices 104 suitable to convert light to electric power may be coupled in parallel with voltage regulation circuitry 1312. Further, a number of sets of devices may be individually or collectively coupled in parallel with voltage regulation circuitry 1312, up to and including the Mth set of devices 110 suitable to convert light to electric power. Further, the operation 5618 illustrates coupling at least a portion of the first plurality of devices suitable to convert light to electric power with at least one voltage regulator. For example, as shown in FIG. 13A, the first set of devices 102 suitable to convert light to electric power, and/or the second set of devices 104 suitable to convert light to electric power may be coupled in parallel with a voltage regulator 1314. Further, a number of sets of devices may be individually or collectively coupled in parallel with a voltage regulator 1314, up to and including the Mth set of devices 110 suitable to convert light to electric power.

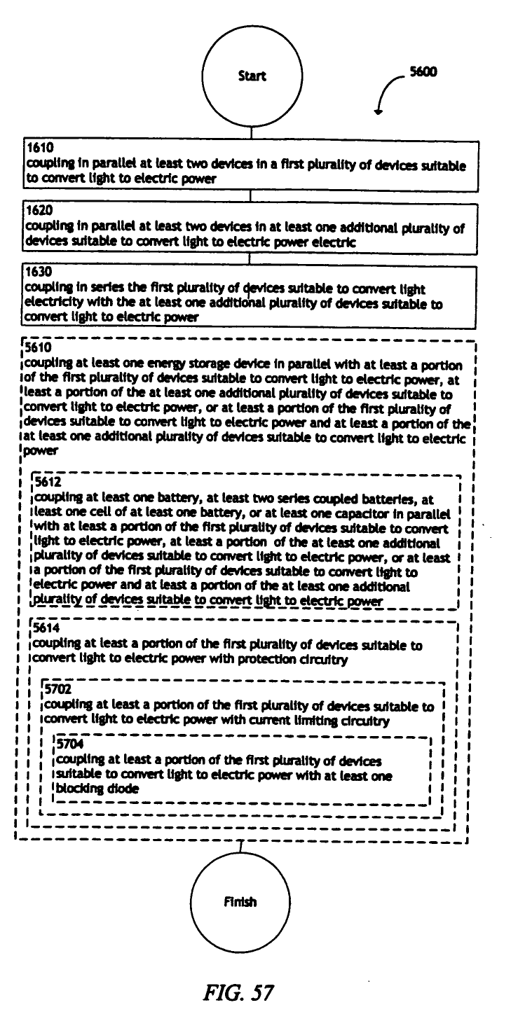

FIG. 57 illustrates alternative embodiments of the example operational flow 5600 of FIG. 56. FIG. 57 illustrates example embodiments where the operation 5610 may include at least one additional operation. Additional operations may include an operation 5702, and/or an operation 5704. Further, the operation 5702 illustrates coupling at least a portion of the first plurality of devices suitable to convert light to electric power with current limiting circuitry. For example, as shown in FIG. 13A, the first set of devices 102 suitable to convert light to electric power, and/or the second set of devices 104 suitable to convert light to electric power may be coupled in parallel with current limiting circuitry 1316. Further, a number of sets of devices may be individually or collectively coupled in parallel with current limiting circuitry 1316, up to and including the Mth set of devices 110 suitable to convert light to electric power. Further, the operation 5704 illustrates coupling at least a portion of the first plurality of devices suitable to convert light to electric power with at least one blocking diode. For example, as shown in FIG. 13A, the first set of devices 102 suitable to convert light to electric power, and/or the second set of devices 104 suitable to convert light to electric power may be coupled in parallel with a blocking diode 1318. Further, a number of sets of devices may be individually or collectively coupled in parallel with a blocking diode 1318, up to and including the Mth set of devices 110 suitable to convert tight to electric power.

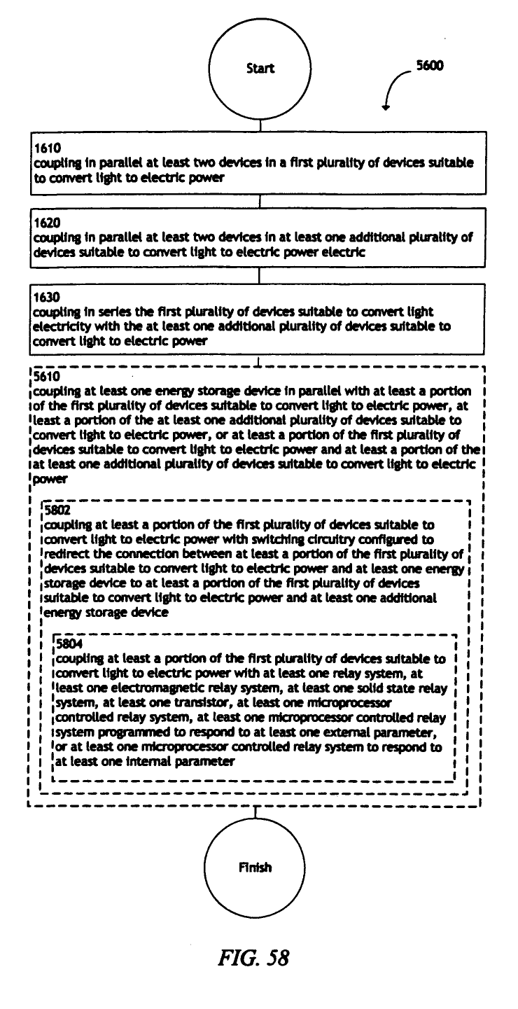

FIG. 58 illustrates alternative embodiments of the example operational flow 5600 of FIG. 56. FIG. 58 illustrates example embodiments where the operation 5610 may include at least one additional operation. Additional operations may include an operation 5802, and/or an operation 5804.

The operation 5802 illustrates coupling at least a portion of the first plurality of devices suitable to convert light to electric power with switching circuitry configured to redirect the connection between at least a portion of the first plurality of devices suitable to convert light to electric power and at least one energy storage device to at least a portion of the first plurality of devices suitable to convert light to electric power and at least one additional energy storage device. For example, as shown in FIG. 13A, the first set of devices 102 suitable to convert light to electric power may be coupled to switching circuitry 1320 in order to redirect the connection between the first set of devices 102 and a first energy storage device 1302 to a connection between the first set of devices and a second energy storage device 1302. Further, a number of sets of devices may be individually or collectively coupled to switching circuitry 1320, up to and including the Mth set of devices 110 suitable to convert light to electric power.

Further, the operation 5804 illustrates coupling at least a portion of the first plurality of devices suitable to convert light to electric power with at least one relay system, at least one electromagnetic relay system, at least one solid state relay system, at least one transistor, at least one microprocessor controlled relay system, at least one microprocessor controlled relay system programmed to respond to at least one external parameter, or at least one microprocessor controlled relay system to respond to at least one internal parameter. For example, as shown in FIG. 13A, the first set of devices 102 suitable to convert light to electric power may be coupled to a relay system 1322, an electromagnetic relay system 1324, a solid state relay system 1326, a transistor 1328, a microprocessor controlled relay system 1330, a microprocessor controlled relay system programmed to respond to a selected internal parameter 1332, or a microprocessor controlled relay system programmed to respond to a selected external parameter 1334. Further, a number of sets of devices may be individually or collectively coupled to a relay system, an electromagnetic relay system, a solid state relay system, a transistor, a microprocessor controlled relay system, a microprocessor controlled relay system programmed to respond to a selected internal parameter, or a microprocessor controlled relay system programmed to respond to a selected external parameter, up to and including the Mth set of devices 110 suitable to convert light to electric power.

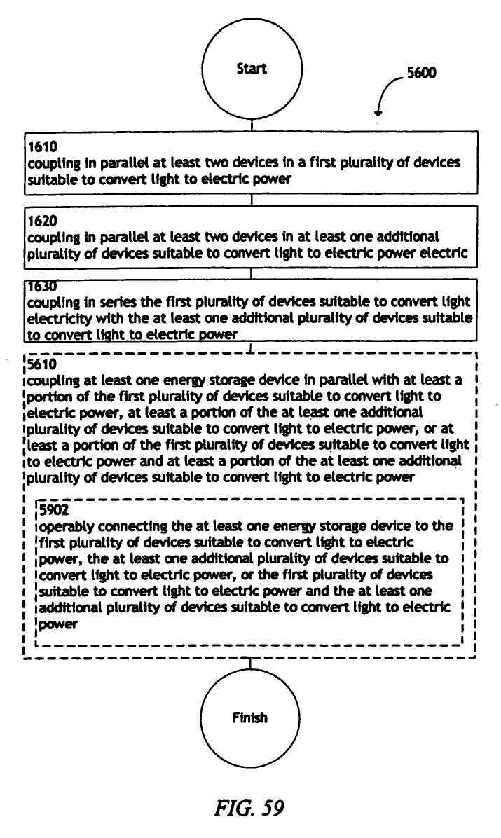

FIG. 59 illustrates alternative embodiments of the example operational flow 5600 of FIG. 56. FIG. 59 illustrates example embodiments where the operation 5610 may include at least one additional operation. Additional operations may include an operation 5902.

The operation 5902 illustrates operably connecting the at least one energy storage device to the first plurality of devices suitable to convert light to electric power, the at least one additional plurality of devices suitable to convert light to electric power, or the first plurality of devices suitable to convert light to electric power and the at least one additional plurality of devices suitable to convert light to electric power. For example, as shown in FIG. 13A, an energy storage device 1302 may be operably connected to the first set of devices 102 suitable to convert light to electric power, and/or the second set of devices 104 suitable to convert light to electric power. Further, an energy storage device 1302 may be operably connected to a number of sets of devices individually or collectively, up to and including the Mth set of devices 110 suitable to convert light to electric power.

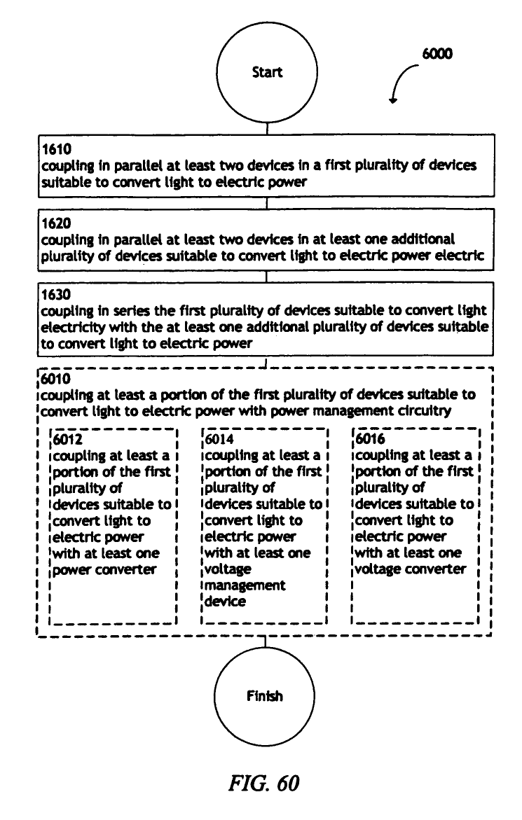

FIG. 60 illustrates an operational flow 6000 representing example operations related to the system and method to convert light to electrical power. FIG. 60 illustrates an example embodiment where the example operational flow 1600 of FIG. 16 may include at least one additional operation. Additional operations may include an operation 6010, an operation 6012, an operation 6014, and/or an operation 6016.

After a start operation, an operation 1610, an operation 1620, and an operation 1630, the operational flow 6000 moves to an operation 6010. Operation 6010 illustrates coupling at least a portion of the first plurality of devices suitable to convert light to electric power with power management circuitry. For example, as shown in FIG. 13B, the first set of devices 102 suitable to convert light to electric power, and/or the second set of devices 104 suitable to convert light to electric power may be coupled with power management circuitry 1336. Further, a number of sets of devices may be individually or collectively coupled with protection circuitry 1336, up to and including the Mth set of devices 110 suitable to convert light to electric power.

The operation 6012 illustrates coupling at least a portion of the first plurality of devices suitable to convert light to electric power with at least one power converter. For example, as shown in FIG. 13B, the first set of devices 102 suitable to convert light to electric power, and/or the second set of devices 104 suitable to convert light to electric power may be coupled with a power converter 1338. Further, a number of sets of devices may be individually or collectively coupled with a power converter 1338, up to and including the Mth set of devices 110 suitable to convert light to electric power.

The operation 6014 illustrates coupling at least a portion of the first plurality of devices suitable to convert light to electric power with at least one voltage management device. For example, as shown in FIG. 13B, the first set of devices 102 suitable to convert light to electric power, and/or the second set of devices 104 suitable to convert light to electric power may be coupled with a voltage management device 1340. Further, a number of sets of devices may be individually or collectively coupled with a voltage management device 1340, up to and including the Mth set of devices 110 suitable to convert light to electric power.

The operation 6016 illustrates coupling at least a portion of the first plurality of devices suitable to convert light to electric power with at least one voltage converter. For example, as shown in FIG. 13B, the first set of devices 102 suitable to convert light to electric power, and/or the second set of devices 104 suitable to convert light to electric power may be coupled with a voltage converter 1342. Further, a number of sets of devices may be individually or collectively coupled with a voltage converter 1342, up to and including the Mth set of devices 110 suitable to convert light to electric power.

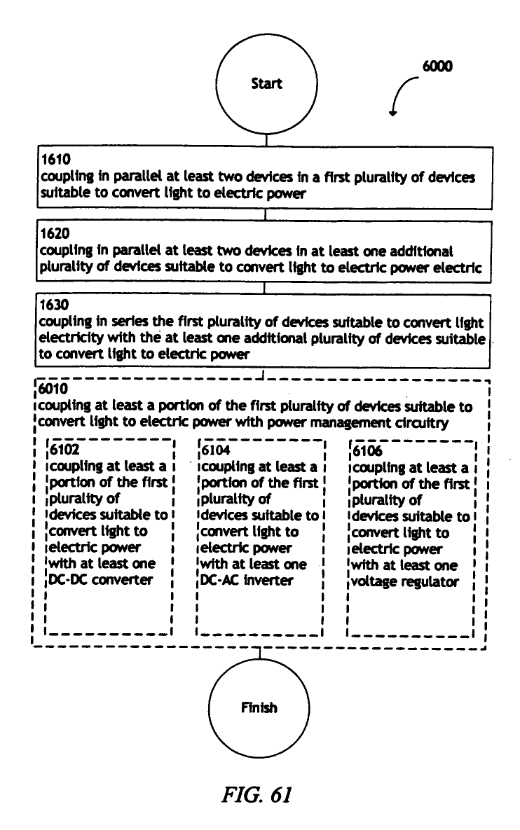

FIG. 61 illustrates alternative embodiments of the example operational flow 6000 of FIG. 60. FIG. 61 illustrates example embodiments where the operation 6010 may include at least one additional operation. Additional operations may include an operation 6102, an operation 6104, and/or an operation 6106.

The operation 6102 illustrates coupling at least a portion of the first plurality of devices suitable to convert light to electric power with at least one DC-DC converter. For example, as shown in FIG. 13B, the first set of devices 102 suitable to convert light to electric power, and/or the second set of devices 104 suitable to convert light to electric power may be coupled with a DC-DC converter 1344. Further, a number of sets of devices may be individually or collectively coupled with a DC-DC converter 1344, up to and including the Mth set of devices 110 suitable to convert light to electric power.

The operation 6104 illustrates coupling at least a portion of the first plurality of devices suitable to convert light to electric power with at least one DC-AC inverter. For example, as shown in FIG. 13B, the first set of devices 102 suitable to convert light to electric power, and/or the second set of devices 104 suitable to convert light to electric power may be coupled with a DC-AC inverter 1346. Further, a number of sets of devices may be individually or collectively coupled with a DC-AC inverter 1346, up to and including the Mth set of devices 110 suitable to convert light to electric power.

The operation 6106 illustrates coupling at least a portion of the first plurality of devices suitable to convert light to electric power with at least one voltage regulator. For example, as shown in FIG. 13B, the first set of devices 102 suitable to convert light to electric power, and/or the second set of devices 104 suitable to convert light to electric power may be coupled with a voltage regulator 1348. Further, a number of sets of devices may be individually or collectively coupled with a voltage regulator 1348, up to and including the Mth set of devices 110 suitable to convert light to electric power.

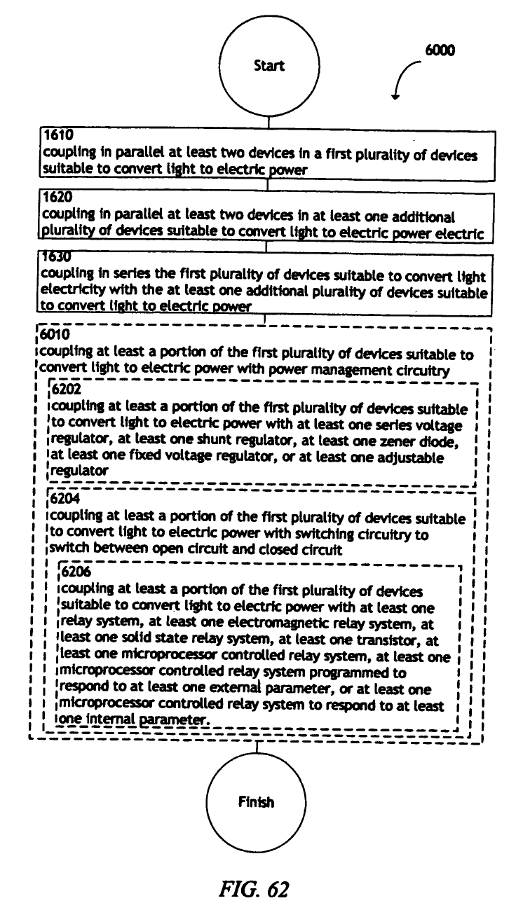

FIG. 62 illustrates alternative embodiments of the example operational flow 6000 of FIG. 60. FIG. 62 illustrates example embodiments where the operation 6010 may include at least one additional operation. Additional operations may include an operation 6202, an operation 6204, and/or an operation 6206.

The operation 6202 illustrates coupling at least a portion of the first plurality of devices suitable to convert light to electric power with at least one series voltage regulator, at least one shunt regulator, at least one zener diode, at least one fixed voltage regulator, or at least one adjustable regulator. For example, as shown in FIG. 13B, the first set of devices 102 suitable to convert light to electric power, and/or the second set of devices 104 suitable to convert light to electric power may be coupled with a series voltage regulator 1350, a shunt regulator 1352, a Zener diode 1352, a fixed voltage regulator 1354, or an adjustable voltage regulator 1358. Further, a number of sets of devices may be individually or collectively coupled with a series voltage regulator 1350, a shunt regulator 1352, a Zener diode 1352, a fixed voltage regulator 1354, or an adjustable voltage regulator 1358, up to and including the Mth set of devices 110 suitable to convert light to electric power.

The operation 6204 illustrates coupling at least a portion of the first plurality of devices suitable to convert light to electric power with switching circuitry to switch between open circuit and closed circuit. For example, as shown in FIG. 13B, the first set of devices 102 suitable to convert light to electric power, and/or the second set of devices 104 suitable to convert light to electric power may be coupled with switching circuitry 1360 to switch between open and closed circuit. Further, a number of sets of devices may be individually or collectively coupled with switching circuitry 1360, up to and including the Mth set of devices 110 suitable to convert light to electric power. Further, the operation 6206 illustrates coupling at least a portion of the first plurality of devices suitable to convert light to electric power with at least one relay system, at least one electromagnetic relay system, at least one solid state relay system, at least one transistor, at least one microprocessor controlled relay system, at least one microprocessor controlled relay system programmed to respond to at least one external parameter, or at least one microprocessor controlled relay system to respond to at least one internal parameter. For example, as shown in FIG. 13B, the first set of devices 102 suitable to convert light to electric power, and/or the second set of devices 104 suitable to convert light to electric power may be coupled to a relay system 1362, an electromagnetic relay system 1364, a solid state relay system 1366, a transistor 1368, a microprocessor controlled relay system 1370, a microprocessor controlled relay system programmed to respond to a selected internal parameter 1372, or a microprocessor controlled relay system programmed to respond to a selected external parameter 1374 in order to switch between open and closed circuit. Further, a number of sets of devices may be individually or collectively coupled to a relay system 1362, an electromagnetic relay system 1364, a solid state relay system 1366, a transistor 1368, a microprocessor controlled relay system 1370, a microprocessor controlled relay system programmed to respond to a selected internal parameter 1372, or a microprocessor controlled relay system programmed to respond to a selected external parameter 1374 in order to switch between open and closed circuit, up to and including the Mth set of devices 110 suitable to convert light to electric power.

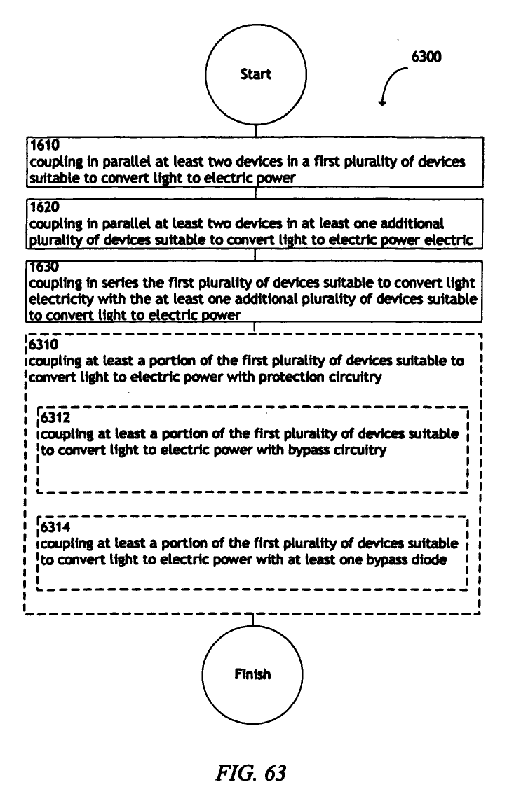

FIG. 63 illustrates an operational flow 6300 representing example operations related to the system and method to convert light to electrical power. FIG. 63 illustrates an example embodiment where the example operational flow 1600 of FIG. 16 may include at least one additional operation. Additional operations may include an operation 6310, an operation 6312, and/or an operation 6314.

After a start operation, an operation 1610, an operation 1620, and an operation 1630, the operational flow 6300 moves to an operation 6310. Operation 6310 illustrates coupling at least a portion of the first plurality of devices suitable to convert light to electric power with protection circuitry. For example, as shown in FIG. 13B, the first set of devices 102 suitable to convert tight to electric power, and/or the second set of devices 104 suitable to convert light to electric power may be coupled with protection circuitry 1376 to protect the first set of devices 102 and the second set of devices 104 from short circuit and/or open circuit failure. Further, a number of sets of devices may be individually or collectively coupled with protection circuitry 1376, up to and including the Mth set of devices 110 suitable to convert light to electric power.

The operation 6312 illustrates coupling at least a portion of the first plurality of devices suitable to convert light to electric power with bypass circuitry. For example, as shown in FIG. 13B, the first set of devices 102 suitable to convert light to electric power, and/or the second set of devices 104 suitable to convert light to electric power may be coupled with bypass circuitry 1378 to protect the first set of devices 102 and the second set of devices 104 from open circuit failure from open circuit failure. Further, a number of sets of devices may be individually or collectively coupled with bypass circuitry 1378, up to and including the Mth set of devices 110 suitable to convert light to electric power. Further, the operation 6314 illustrates coupling at least a portion of the first plurality of devices suitable to convert light to electric power with at least one bypass diode. For example, as shown in FIG. 13B and FIG. 14, the first set of devices 102 suitable to convert tight to electric power, and/or the second set of devices 104 suitable to convert light to electric power may be coupled with a bypass diode 1380 to protect the first set of devices 102 and the second set of devices 104 from open circuit failure. Further, a number of sets of devices may be individually or collectively coupled with a bypass diode 1380, up to and including the Mth set of devices 110 suitable to convert light to electric power.

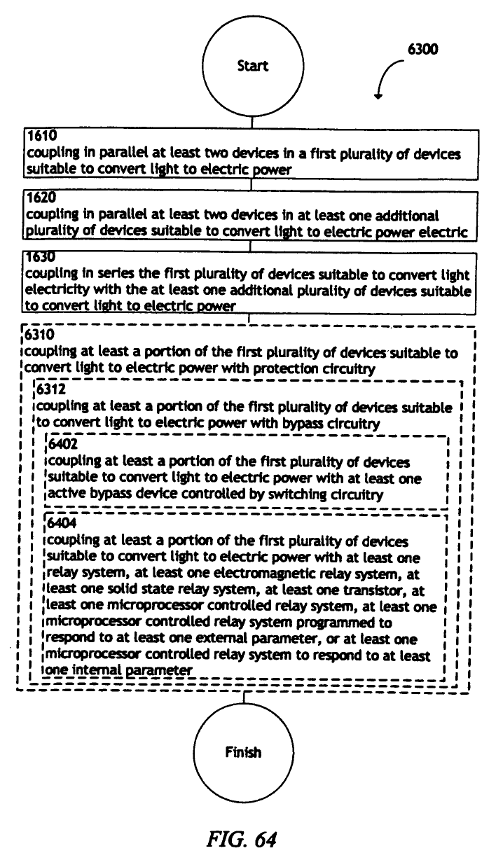

FIG. 64 illustrates alternative embodiments of the example operational flow 6300 of FIG. 63. FIG. 64 illustrates example embodiments where the operation 6310 may include at least one additional operation. Additional operations may include an operation 6402, and/or an operation 6404. Further, the operation 6402 illustrates coupling at least a portion of the first plurality of devices suitable to convert light to electric power with at least one active bypass device controlled by switching circuitry. For example, as shown in FIG. 13B, the first set of devices 102 suitable to convert light to electric power, and/or the second set of devices 104 suitable to convert light to electric power may be coupled with an active bypass device 1382 to protect the first set of devices 102 and the second set of devices 104 from open circuit failure. Further, a number of sets of devices may be individually or collectively coupled with an active bypass device 1382, up to and including the Mth set of devices 110 suitable to convert light to electric power. Further, the operation 6404 illustrates coupling at least a portion of the first plurality of devices suitable to convert light to electric power with at least one relay system, at least one electromagnetic relay system, at least one solid state relay system, at least one transistor, at least one microprocessor controlled relay system, at least one microprocessor controlled relay system programmed to respond to at least one external parameter, or at least one microprocessor controlled relay system to respond to at least one internal parameter. For example, as shown in FIG. 13B, the first set of devices 102 suitable to convert light to electric power, and/or the second set of devices 104 suitable to convert light to electric power may be coupled with a relay system 1384, an electromagnetic relay system 1386, a solid state relay system 1388, a transistor 1390, a microprocessor controlled relay system 1392, a microprocessor controlled relay system programmed to respond to a selected external parameter 1394, or a microprocessor controlled relay system programmed to respond to a selected internal parameter 1396 to protect the first set of devices 102 and the second set of devices 104 from open circuit failure. Further, a number of sets of devices may be individually or collectively coupled with a relay system 1384, an electromagnetic relay system 1386, a solid state relay system 1388, a transistor 1390, a microprocessor controlled relay system 1392, a microprocessor controlled relay system programmed to respond to a selected external parameter 1394, or a microprocessor controlled relay system programmed to respond to a selected internal parameter 1396, up to and including the Mth set of devices 110 suitable to convert light to electric power.

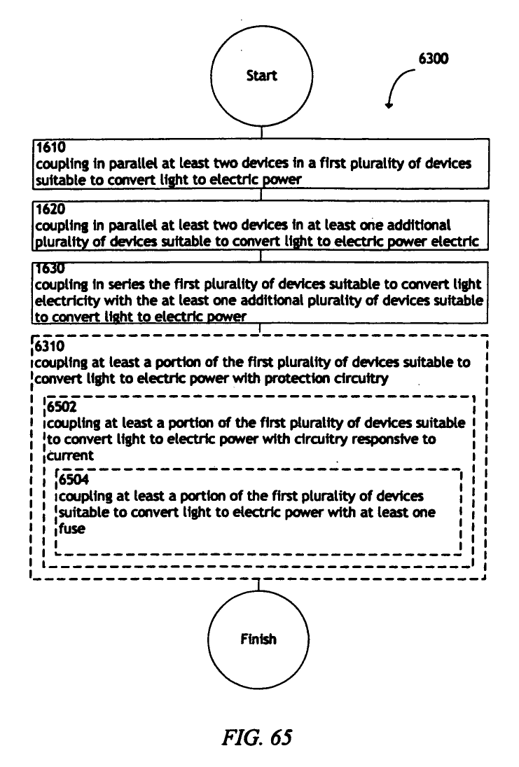

FIG. 65 illustrates alternative embodiments of the example operational flow 6300 of FIG. 63. FIG. 65 illustrates example embodiments where the operation 6310 may include at least one additional operation. Additional operations may include an operation 6502, and/or an operation 6504.

The operation 6502 illustrates coupling at least a portion of the first plurality of devices suitable to convert light to electric power with circuitry responsive to current. For example, as shown in FIG. 13B, the first set of devices 102 suitable to convert light to electric power, and/or the second set of devices 104 suitable to convert light to electric power may be coupled with circuitry responsive to current 1398 to protect the first set of devices 102 and the second set of devices 104 from short circuit failure. Further, a number of sets of devices may be individually or collectively coupled with circuitry responsive to current 1398, up to and including the Mth set of devices 110 suitable to convert light to electric power. Further, the operation 6504 illustrates coupling at least a portion of the first plurality of devices suitable to convert light to electric power with at least one fuse. For example, as shown in FIG. 13B and FIG. 14, devices (e.g. A₂ and/or A₃) in the first set of devices 102 suitable to convert light to electric power, and/or devices (e.g. B₁ and/or B₄) in the second set of devices 104 suitable to convert light to electric power may be coupled with a fuse 1400 to protect the first set of devices 102 and the second set of devices 104 from short circuit failure. Further, a number of devices up to an including the Nth device M_{N} of the Mth set of devices 110 may be coupled with a fuse 1400 to protect the Mth set of devices 110 and from short circuit failure.

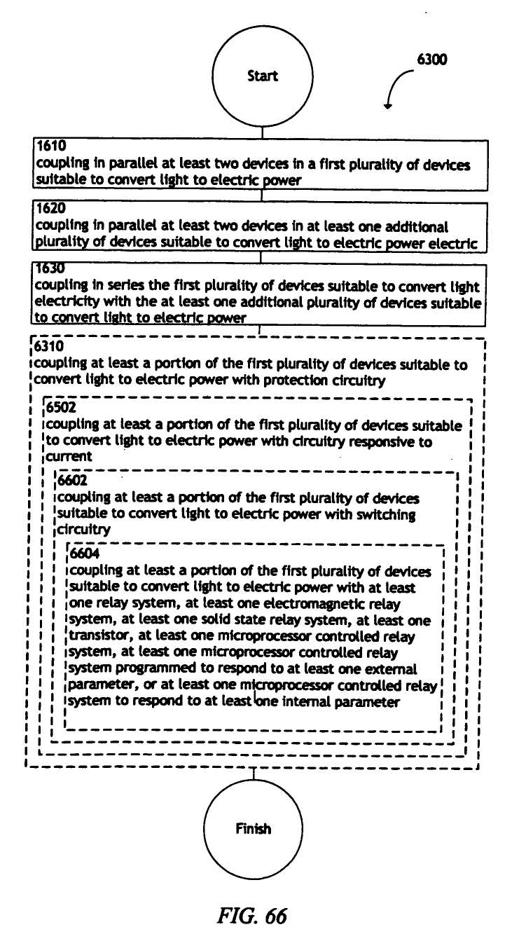

FIG. 66 illustrates alternative embodiments of the example operational flow 6300 of FIG. 63. FIG. 66 illustrates example embodiments where the operation 6310 may include at least one additional operation. Additional operations may include an operation 6602, and/or an operation 6604. Further, the operation 6602 illustrates coupling at least a portion of the first plurality of devices suitable to convert light to electric power with switching circuitry. For example, as shown in FIG. 13B, the first set of devices 102 suitable to convert light to electric power, and/or the second set of devices 104 suitable to convert light to electric power may be coupled with switching circuitry 1402 to protect the first set of devices 102 and the second set of devices 104 from short circuit failure. Further, a number of sets of devices may be individually or collectively coupled with switching circuitry 1402, up to and including the Mth set of devices 110 suitable to convert light to electric power. Further, the operation 6604 illustrates coupling at least a portion of the first plurality of devices suitable to convert light to electric power with at least one relay system, at least one electromagnetic relay system, at least one solid state relay system, at least one transistor, at least one microprocessor controlled relay system, at least one microprocessor controlled relay system programmed to respond to at least one external parameter, or at least one microprocessor controlled relay system to respond to at least one internal parameter. For example, as shown in FIG. 13B, the first set of devices 102 suitable to convert light to electric power, and/or the second set of devices 104 suitable to convert light to electric power may be coupled with a relay system 1404, an electromagnetic relay system 1406, a solid state relay system 1408, a transistor 1410, a microprocessor controlled relay system 1412, a microprocessor controlled relay system programmed to respond to a selected external parameter 1414, or a microprocessor controlled relay system programmed to respond to a selected internal parameter 1416 to protect the first set of devices 102 and the second set of devices 104 from short circuit failure. Further, a number of sets of devices, up to and including the Mth set of devices 110 suitable to convert light to electric power, may be individually or collectively coupled with a relay system 1404, an electromagnetic relay system 1406, a solid state relay system 1408, a transistor 1410, a microprocessor controlled relay system 1412, a microprocessor controlled relay system programmed to respond to a selected external parameter 1414, or a microprocessor controlled relay system programmed to respond to a selected internal parameter 1416.

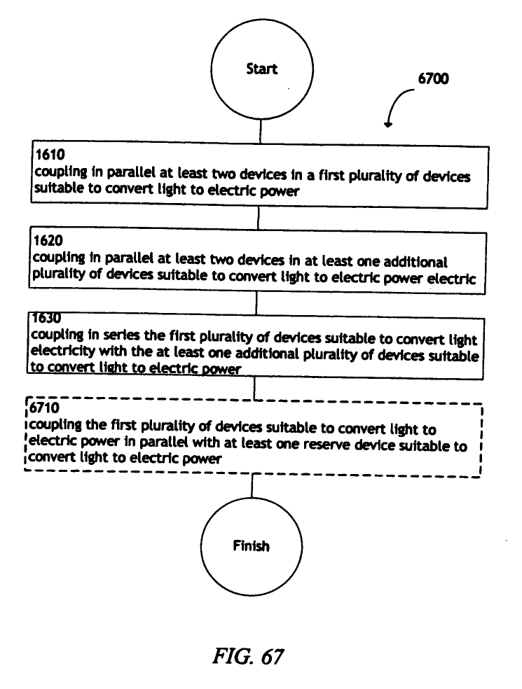

FIG. 67 illustrates an operational flow 6700 representing example operations related to the system and method to convert light to electrical power. FIG. 67 illustrates an example embodiment where the example operational flow 1600 of FIG. 16 may include at least one additional operation. Additional operations may include an operation 6710.

After a start operation, an operation 1610, an operation 1620, and an operation 1630, the operational flow 6700 moves to an operation 6710. Operation 6710 illustrates coupling the first plurality of devices suitable to convert light to electric power in parallel with at least one reserve device suitable to convert light to electric power. For example, as shown in FIG. 15A, the first set of devices 102 suitable to convert light to electric power, and/or the second set of devices 104 suitable to convert light to electric power may be coupled with a reserve device 1502 suitable to convert light to electric power in order to supply supplemental power during total or partial malfunction of the first set of devices 102 and/or the second set of devices 104. Further, a number of sets of devices may be individually or collectively coupled with a reserve device 1502, up to and including the Mth set of devices 110 suitable to convert light to electric power. For example, the reserve device may include one or more photovoltaic cells.

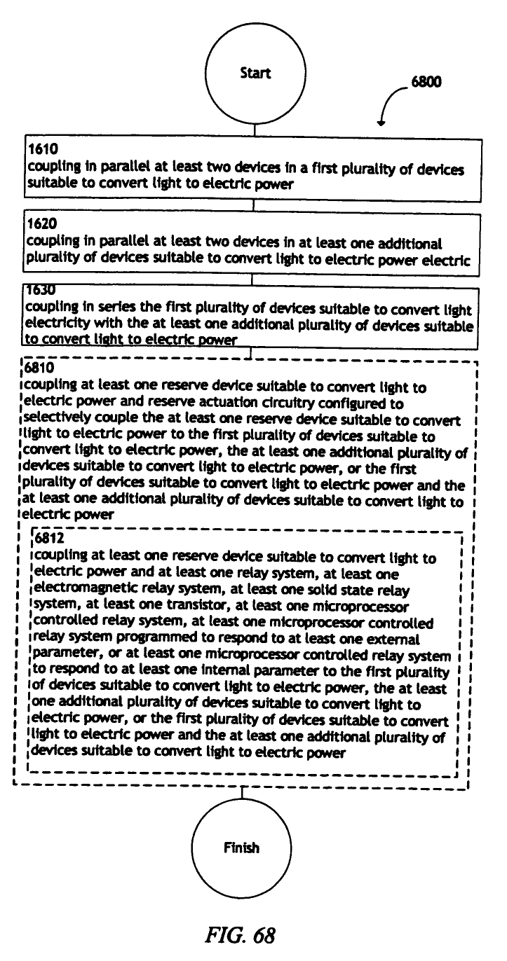

FIG. 68 illustrates an operational flow 6800 representing example operations related to the system and method to convert light to electrical power. FIG. 68 illustrates an example embodiment where the example operational flow 1600 of FIG. 16 may include at least one additional operation. Additional operations may include an operation 6810, and/or an operation 6812.

After a start operation, an operation 1610, an operation 1620, and an operation 1630, the operational flow 6800 moves to an operation 6810. Operation 6810 illustrates coupling at least one reserve device suitable to convert light to electric power and reserve actuation circuitry configured to selectively couple the at least one reserve device suitable to convert light to electric power to the first plurality of devices suitable to convert light to electric power, the at least one additional plurality of devices suitable to convert light to electric power, or the first plurality of devices suitable to convert light to electric power and the at least one additional plurality of devices suitable to convert light to electric power. For example, as shown in FIG. 15A and FIG. 15B, the first set of devices 102 suitable to convert light to electric power, and/or the second set of devices 104 suitable to convert light to electric power may be coupled with a combination 1504 of one or more reserve devices 1502 suitable to convert light to electric power and reserve actuation circuitry 1522 in order to supply supplemental power during total or partial malfunction of the first set of devices 102 and/or the second set of devices 104. Further, a number of sets of devices may be individually or collectively coupled with a combination 1504 of a reserve device 1502 suitable to convert light to electric power and reserve actuation circuitry 1522, up to and including the Mth set of devices 110 suitable to convert light to electric power.

The operation 6812 illustrates coupling at least one reserve device suitable to convert light to electric power and at least one relay system, at least one electromagnetic relay system, at least one solid state relay system, at least one transistor, at least one microprocessor controlled relay system, at least one microprocessor controlled relay system programmed to respond to at least one external parameter, or at least one microprocessor controlled relay system to respond to at least one internal parameter to the first plurality of devices suitable to convert light to electric power, the at least one additional plurality of devices suitable to convert light to electric power, or the first plurality of devices suitable to convert light to electric power and the at least one additional plurality of devices suitable to convert light to electric power. For example, as shown in FIG. 15A and FIG. 15B, the first set of devices 102 suitable to convert light to electric power, and/or the second set of devices 104 suitable to convert light to electric power may be coupled with a combination of one or more reserve devices 1502 and a relay system 1506, an electromagnetic relay system 1508, a solid state relay system 1510, a transistor 1512, a microprocessor controlled relay system 1514, a microprocessor controlled relay system programmed to respond to a selected external parameter 1516, or a microprocessor controlled relay system programmed to respond to a selected internal parameter 1518 in order to supply supplemental power during total or partial malfunction of the first set of devices 102 and/or the second set of devices 104. Further, a number of sets of devices may be individually or collectively coupled with a combination of a reserve device 1502 and a relay system 1506, an electromagnetic relay system 1508, a solid state relay system 1510, a transistor 1512, a microprocessor controlled relay system 1514, a microprocessor controlled relay system programmed to respond to a selected external parameter 1516, or a microprocessor controlled relay system programmed to respond to a selected internal parameter 1518, up to and including the Mth set of devices 110 suitable to convert light to electric power.

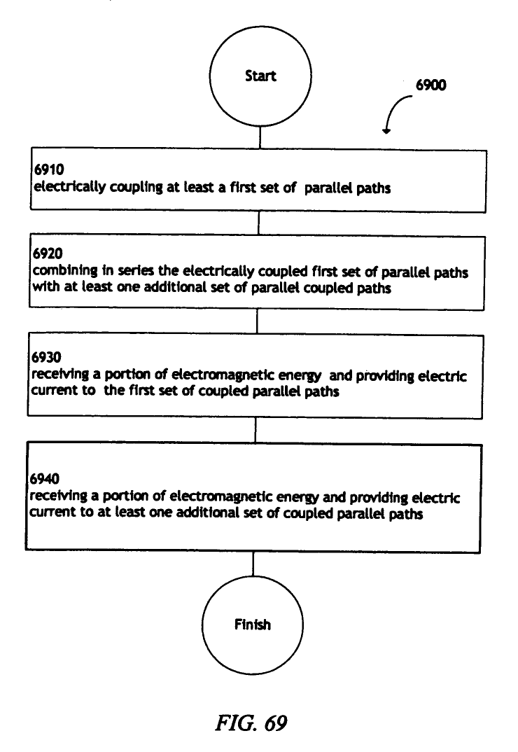

FIG. 69 illustrates an operational flow 6900 representing example operations related to the method for converting electromagnetic flux into electric power. In FIG. 69 and in following figures that include various examples of operational flows, discussion and explanation may be provided with respect to the above-described examples of FIGS. 1 through 15, and/or with respect to other examples and contexts. However, it should be understood that the operational flows may be executed in a number of other environments and contexts, and/or in modified versions of FIGS. 1 through 15. Also, although the various operational flows are presented in the sequence(s) illustrated, it should be understood that the various operations may be performed in other orders than those which are illustrated, or may be performed concurrently.

After a start operation, the operational flow 6900 moves to an operation 6910. Operation 6910 depicts electrically coupling at least a first set of parallel paths. For example, as shown in FIG. 1, a first device A₁ in a first set of devices 102 suitable to convert light to electric power may be coupled in parallel with a second device A₂ and a first device B₁. In an additional set of devices suitable to convert light to electric power 104 may be coupled in parallel with a second device B₂.

Then, operation 6920 depicts combining in series the electrically coupled first set of parallel paths with at least one additional set of parallel coupled paths. For example, as shown in FIG. 1, the first set of devices 102 suitable to convert light to electric power may be coupled in series with the second set of devices 104 suitable to convert light to electric power.

Then, operation 6930 depicts receiving a portion of electromagnetic flux and providing electric power to the first set of coupled parallel paths. For example, electromagnetic flux may be converted to electric current using the devices A₁-A_{N} suitable to convert light to electric power of the first set of devices 104. In one embodiment, as shown in FIG. 4, electromagnetic flux may be converted to electric power by at least one photovoltaic cell 404, at least one multiple energy band-gap photovoltaic cell 406, at least one multilayer photovoltaic cell 408, at least one thermovoltaic device 410, at least one thermophotovoltaic device 412, at least one photocapacitor 414, or at least one optical rectenna 416.

Then, operation 6940 depicts receiving a portion of electromagnetic flux and providing electric power to at least one additional set of coupled parallel paths. For example, electromagnetic flux may be converted to electric power using the devices B₁-B_{N} suitable to convert light to electric power of the second set of devices 104. In one embodiment, as shown in FIG. 4, electromagnetic flux may be converted to electric power by at least one photovoltaic cell 404, at least one multiple energy band-gap photovoltaic cell 406, at least one multilayer photovoltaic cell 408, at least one thermovoltaic device 410, at least one thermophotovoltaic device 412, at least one photocapacitor 414, or at least one optical rectenna 416.

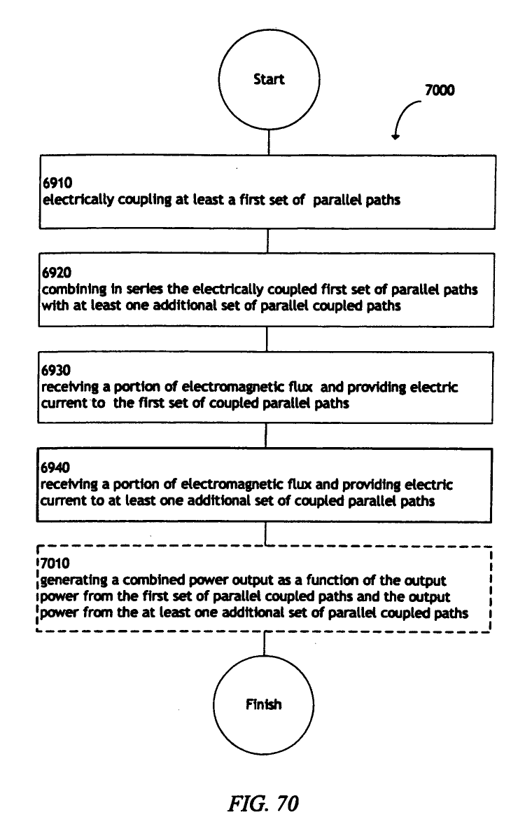

FIG. 70 illustrates an operational flow 7000 representing example operations related to the method for converting electromagnetic flux into electric power. FIG. 70 illustrates an example embodiment where the example operational flow 6900 of FIG. 69 may include at least one additional operation. Additional operations may include an operation 7010.

After a start operation, an operation 6910, an operation 6920, an operation 6930, and an operation 6940, the operational flow 7000 moves to an operation 7010. Operation 7010 illustrates generating a combined electric power output as a function of the electric power output from the first set of parallel coupled paths and the electric power output from the at least one additional set of parallel coupled paths. For example, as shown in FIG. 1, the first set of devices 102 may have a first electric power output as a function of the devices A₁ through A_{N} of the first set of devices 102 and the second set of devices 104 may have a second electric power output as a function of the devices B₁ through B_{N} of the second set of devices 104. The first electric power output and the second electric power output may be combined using a series electrical connection between the first set of devices 102 and the second set of devices 104, creating a combined electric power output.

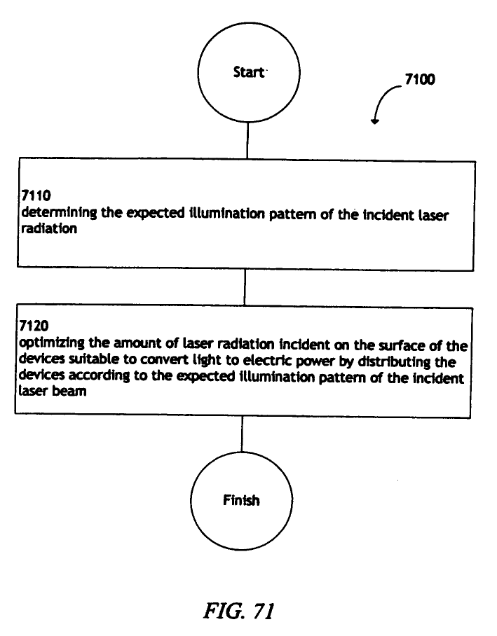

FIG. 71 illustrates an operational flow 7100 representing example operations related to the method for optimizing the electric power output of a system. In FIG. 71 and in following figures that include various examples of operational flows, discussion and explanation may be provided with respect to the above-described examples of FIGS. 1 through 15, and/or with respect to other examples and contexts. However, it should be understood that the operational flows may be executed in a number of other environments and contexts, and/or in modified versions of FIGS. 1 through 15. Also, although the various operational flows are presented in the sequence(s) illustrated, it should be understood that the various operations may be performed in other orders than those which are illustrated, or may be performed concurrently.

After a start operation, the operational flow 7100 moves to an operation 7110. Operation 7110 depicts determining the expected illumination pattern of the incident laser radiation. For example, the expected illumination pattern of the incident laser radiation may include the expected distribution of spectral irradiance. Further, the expected distribution of spectral irradiance may be predicted by determining the spatial distribution of the spectral irradiance of the incident laser radiation, the expected statistical variation of the spectral irradiance of the incident laser radiation, or the temporal variation of the spectral irradiance of the of the incident laser radiation.

Then, operation 7120 depicts optimizing the amount of laser radiation incident on the surface of the devices suitable to convert light to electric power by distributing the devices according to the expected illumination pattern of the incident laser beam. For example, the distribution and orientation of the devices suitable to convert light to electric power in accordance with the expected illumination pattern of the incident laser beam may include determining the spatial extent and orientation of the sets of devices (e.g. 102 through 110) and determining the spatial extent and orientation of the devices (e.g. A₁ through A_{N}) in each set of devices. Further, the distribution and orientation of the devices in accordance with the expected illumination pattern of the incident laser beam may include determining the size of the devices (e.g. A₁ through A_{N}) in each set (e.g. 102 through 110) of devices. By way of further example, the distribution of the devices in accordance with the expected illumination pattern of the incident laser beam may include determining the maximum laser light flux incident on the devices (e.g. A₁ through A_{N}) in each set (e.g. 102 through 110) of devices. Further, the distribution and orientation of the devices (e.g. A1 through AN) in the sets (e.g. 102 through 110) of devices may include positioning and orienting the devices (e.g. A₁ and A_{N}) in the sets of devices (e.g. 102 through 110) in accordance with a selected figure of merit. For example, the selected figure of merit may include the minimum electric power produced by the light-to electric power converting devices, the maximum electric power produced by the light-to electric power converting devices, the expected statistical average of the electric power produced by the light-to electric power converting devices, the time-averaged electric power produced by the light-to-electric power converting devices, or selected physical parameters of the light-to-electric power converting system. For example, the selected physical parameters of the light-to-electric power converting system may include the lengths of the wire connections between devices (e.g. A₁ through A_{N}) in a set of devices (e.g. 102) or the lengths of wire connections between sets of devices (e.g. 102 through 110). By way of further example, the distribution and orientation of the devices (e.g. A₁ through A_{N}) in each set of devices (e.g. 102 through 110) may be determined such that the series connection between each set of devices (e.g. 102 through 110) optimizes the selected figures of merit. Even further, this process may be repeated until substantially all of the devices (e.g. A₁ through A_{N}) of each set of devices are positioned and oriented. Additionally, by further example, the distribution and orientation of the devices (e.g. A₁ through A_{N}) in each set of devices (e.g. 102 through 110) may be determined by optimizing the selected figure of merit by iteratively changing the positions and orientations of the devices (e.g. A₁ through A_{N}) of each set (e.g. 102 through 110) of devices according to randomized positioning, gradient positioning, simulated annealing, or a selected genetic algorithm.

Those having skill in the art will recognize that the state of the art has progressed to the point where there is little distinction left between hardware, software, and/or firmware implementations of aspects of systems; the use of hardware, software, and/or firmware is generally (but not always, in that in certain contexts the choice between hardware and software can become significant) a design choice representing cost vs. efficiency tradeoffs. Those having skill in the art will appreciate that there are various vehicles by which processes and/or systems and/or other technologies described herein can be effected (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; alternatively, if flexibility is paramount, the implementer may opt for a mainly software implementation; or, yet again alternatively, the implementer may opt for some combination of hardware, software, and/or firmware. Hence, there are several possible vehicles by which the processes and/or devices and/or other technologies described herein may be effected, none of which is inherently superior to the other in that any vehicle to be utilized is a choice dependent upon the context in which the vehicle will be deployed and the specific concerns (e.g., speed, flexibility, or predictability) of the implementer, any of which may vary. Those skilled in the art will recognize that optical aspects of implementations will typically employ optically-oriented hardware, software, and or firmware.

In some implementations described herein, logic and similar implementations may include software or other control structures suitable to operation. Electronic circuitry, for example, may manifest one or more paths of electrical current constructed and arranged to implement various logic functions as described herein. In some implementations, one or more media are configured to bear a device-detectable implementation if such media hold or transmit a special-purpose device instruction set operable to perform as described herein. In some variants, for example, this may manifest as an update or other modification of existing software or firmware, or of gate arrays or other programmable hardware, such as by performing a reception of or a transmission of one or more instructions in relation to one or more operations described herein. Alternatively or additionally, in some variants, an implementation may include special-purpose hardware, software, firmware components, and/or general-purpose components executing or otherwise invoking special-purpose components. Specifications or other implementations may be transmitted by one or more instances of tangible transmission media as described herein, optionally by packet transmission or otherwise by passing through distributed media at various times.

Alternatively or additionally, implementations may include executing a special-purpose instruction sequence or otherwise invoking circuitry for enabling, triggering, coordinating, requesting, or otherwise causing one or more occurrences of any functional operations described above. In some variants, operational or other logical descriptions herein may be expressed directly as source code and compiled or otherwise invoked as an executable instruction sequence. In some contexts, for example, C++ or other code sequences can be compiled directly or otherwise implemented in high-level descriptor languages (e.g., a logic-synthesizable language, a hardware description language, a hardware design simulation, and/or other such similar mode(s) of expression). Alternatively or additionally, some or all of the logical expression may be manifested as a Verilog-type hardware description or other circuitry model before physical implementation in hardware, especially for basic operations or timing-critical applications. Those skilled in the art will recognize how to obtain, configure, and optimize suitable transmission or computational elements, material supplies, actuators, or other common structures in light of these teachings.

The foregoing detailed description has set forth various embodiments of the devices and/or processes via the use of block diagrams, flowcharts, and/or examples. Insofar as such block diagrams, flowcharts, and/or examples contain one or more functions and/or operations, it will be understood by those within the art that each function and/or operation within such block diagrams, flowcharts, or examples can be implemented, individually and/or collectively, by a wide range of hardware, software, firmware, or virtually any combination thereof. In one embodiment, several portions of the subject matter described herein may be implemented via Application Specific Integrated Circuits (ASICs), Field Programmable Gate Arrays (FPGAs), digital signal processors (DSPs), or other integrated formats. However, those skilled in the art will recognize that some aspects of the embodiments disclosed herein, in whole or in part, can be equivalently implemented in integrated circuits, as one or more computer programs running on one or more computers (e.g., as one or more programs running on one or more computer systems), as one or more programs running on one or more processors (e.g., as one or more programs running on one or more microprocessors), as firmware, or as virtually any combination thereof, and that designing the circuitry and/or writing the code for the software and or firmware would be well within the skill of one of skill in the art in light of this disclosure. In addition, those skilled in the art will appreciate that the mechanisms of the subject matter described herein are capable of being distributed as a program product in a variety of forms, and that an illustrative embodiment of the subject matter described herein applies regardless of the particular type of signal bearing medium used to actually carry out the distribution. Examples of a signal bearing medium include, but are not limited to, the following: a recordable type medium such as a floppy disk, a hard disk drive, a Compact Disc (CD), a Digital Video Disk (DVD), a digital tape, a computer memory, etc.; and a transmission type medium such as a digital and/or an analog communication medium (e.g., a fiber optic cable, a waveguide, a wired communications link, a wireless communication link (e.g., transmitter, receiver, transmission logic, reception logic, and the like).

In a general sense, those skilled in the art will recognize that the various aspects described herein which can be implemented, individually and/or collectively, by a wide range of hardware, software, firmware, and/or any combination thereof can be viewed as being composed of various types of “electrical circuitry.” Consequently, as used herein “electrical circuitry” includes, but is not limited to, electrical circuitry having at least one discrete electrical circuit, electrical circuitry having at least one integrated circuit, electrical circuitry having at least one application specific integrated circuit, electrical circuitry forming a general purpose computing device configured by a computer program (e.g., a general purpose computer configured by a computer program which at least partially carries out processes and/or devices described herein, or a microprocessor configured by a computer program which at least partially carries out processes and/or devices described herein), electrical circuitry forming a memory device (e.g., forms of memory (e.g., random access, flash, read only, etc.)), and/or electrical circuitry forming a communications device (e.g., a modem, communications switch, optical-electrical equipment, etc). Those having skill in the art will recognize that the subject matter described herein may be implemented in an analog or digital fashion or some combination thereof.

Those skilled in the art will recognize that at least a portion of the devices and/or processes described herein can be integrated into a data processing system. Those having skill in the art will recognize that a data processing system generally includes one or more of a system unit housing, a video display device, memory such as volatile or non-volatile memory, processors such as microprocessors or digital signal processors, computational entities such as operating systems, drivers, graphical user interfaces, and applications programs, one or more interaction devices (e.g., a touch pad, a touch screen, an antenna, etc.), and/or control systems including feedback loops and control motors (e.g., feedback for sensing position and/or velocity; control motors for moving and/or adjusting components and/or quantities). A data processing system may be implemented utilizing suitable commercially available components, such as those typically found in data computing/communication and/or network computing/communication systems.

The herein described subject matter sometimes illustrates different components contained within, or connected with, different other components. It is to be understood that such depicted architectures are merely exemplary, and that in fact many other architectures may be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components, and/or wirelessly interactable, and/or wirelessly interacting components, and/or logically interacting, and/or logically interactable components.

In some instances, one or more components may be referred to herein as “configured to,” “configurable to,” “operable/operative to,” “adapted/adaptable,” “able to,” “conformable/conformed to,” etc. Those skilled in the art will recognize that “configured to” can generally encompass active-state components and/or inactive-state components and/or standby-state components, unless context requires otherwise.

While particular aspects of the present subject matter described herein have been shown and described, it will be apparent to those skilled in the art that, based upon the teachings herein, changes and modifications may be made without departing from the subject matter described herein and its broader aspects and, therefore, the appended claims are to encompass within their scope all such changes and modifications as are within the true spirit and scope of the subject matter described herein. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to claims containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc). It will be further understood by those within the art that typically a disjunctive word and/or phrase presenting two or more alternative terms, whether in the description, claims, or drawings, should be understood to contemplate the possibilities of including one of the terms, either of the terms, or both terms. For example, the phrase “A or B” will be typically understood to include the possibilities of “A” or “B” or “A and B.”

With respect to the appended claims, those skilled in the art will appreciate that recited operations therein may generally be performed in any order. Also, although various operational flows are presented in a sequence(s), it should be understood that the various operations may be performed in other orders than those which are illustrated, or may be performed concurrently. Examples of such alternate orderings may include overlapping, interleaved, interrupted, reordered, incremental, preparatory, supplemental, simultaneous, reverse, or other variant orderings, unless context dictates otherwise. Furthermore, terms like “responsive to,” “related to,” or other past-tense adjectives are generally not intended to exclude such variants, unless context dictates otherwise.

What is claimed is:

1-121. (canceled)

122. A system suitable for converting tight to electric power, comprising:
a first plurality of devices suitable to convert light to electric power, at least one of the devices of the first plurality of devices suitable to convert light to electric power adapted to receive light from at least one natural light source;
at least two of the devices of the first plurality of devices suitable to convert light to electric power are coupled in parallel; and
at least one additional plurality of devices suitable to convert light to electric power;
at least two of the devices of the at least one additional plurality of devices suitable to convert light to electric power are coupled in parallel;
the first plurality of devices suitable to convert light to electric power and the at least one additional plurality of devices suitable to convert light to electric power are coupled in series.

123. The system of claim 122, wherein the natural light source includes the Sun.

124-128. (canceled)

129. A system suitable for converting light to electric power, comprising:
a first plurality of devices suitable to convert light to electric power, at least one of the devices of the first plurality of devices suitable to convert light to electric power adapted to convert at least one of the group including far infrared light, long-wavelength infrared light, mid-wavelength infrared light, short-wavelength infrared light, near infrared light, visible light, long wave ultraviolet light, medium wave ultraviolet light, or short wave ultraviolet light to electric power;
at least two of the devices of the first plurality of devices suitable to convert light to electric power are coupled in parallel; and
at least one additional plurality of devices suitable to convert light to electric power;
at least two of the devices of the at least one additional plurality of devices suitable to convert light to electric power are coupled in parallel;
the first plurality of devices suitable to convert light to electric power and the at least one additional plurality of devices suitable to convert light to electric power are coupled in series.

130. A system suitable for converting light to electric power, comprising:
a first plurality of devices suitable to convert light to electric power;
at least two of the devices of the first plurality of devices suitable to convert light to electric power are coupled in parallel; and
at least one additional plurality of devices suitable to convert light to electric power; and
at least one optical device;
at least two of the devices of the at least one additional plurality of devices suitable to convert light to electric power are coupled in parallel;
the first plurality of devices suitable to convert light to electric power and the at least one additional plurality of devices suitable to convert light to electric power are coupled in series.

131. The system of claim 130, wherein the at least one optical device includes at least one lens.

132-134. (canceled)

135. The system of claim 130, wherein the at least one optical device includes at least one prism.

136. The system of claim 130, wherein the at least one optical device includes at least one diffraction grating.

137. The system of claim 130, wherein the at least one optical device includes at least one optical filter.

138. A system suitable for converting light to electric power, comprising:
a first plurality of devices suitable to convert light to electric power, at least one of the devices of the first plurality of devices suitable to convert light to electric power including at least one photovoltaic cell, at least one multiple energy band gap photovoltaic cell, at least one multilayer photovoltaic cell, at least one thermovoltaic device, at least one thermophotovoltaic device, at least one photocapacitor, or at least one optical rectenna;
at least two of the devices of the first plurality of devices suitable to convert light to electric power are coupled in parallel; and
at least one additional plurality of devices suitable to convert light to electric power;
at least two of the devices of the at least one additional plurality of devices suitable to convert light to electric power are coupled in parallel;
the first plurality of devices suitable to convert light to electric power and the at least one additional plurality of devices suitable to convert light to electric power are coupled in series.

139. A system suitable for converting light to electric power, comprising:
a first plurality of devices suitable to convert light to electric power, at least one of the devices of the first plurality of devices suitable to convert light to electric power including a set of at least one series connected photovoltaic cell, multiple energy band gap photovoltaic cell, one multilayer photovoltaic cell, thermovoltaic device, thermophotovoltaic device, photocapacitor, or optical rectenna;
at least two of the devices of the first plurality of devices suitable to convert light to electric power are coupled in parallel; and
at least one additional plurality of devices suitable to convert light to electric power;
at least two of the devices of the at least one additional plurality of devices suitable to convert light to electric power are coupled in parallel;
the first plurality of devices suitable to convert light to electric power and the at least one additional plurality of devices suitable to convert light to electric power are coupled in series.

140-173. (canceled)

174. A system suitable for converting light to electric power, comprising:
a first plurality of devices suitable to convert light to electric power, the first plurality of devices suitable to convert light to electric power including at least a first device having a first surface normal and at least a second device having a second surface normal different from the first surface normal;
at least two of the devices of the first plurality of devices suitable to convert light to electric power are coupled in parallel; and
at least one additional plurality of devices suitable to convert light to electric power;
at least two of the devices of the at least one additional plurality of devices suitable to convert light to electric power are coupled in parallel;
the first plurality of devices suitable to convert light to electric power and the at least one additional plurality of devices suitable to convert light to electric power are coupled in series.

175. The system of claim 174, wherein the first surface normal is oriented according to a first set of angular positions and the second surface normal is oriented according to a second set of angular positions, the second set of angular positions different than the first set of angular positions.

176. The system of claim 175, wherein the first set of angular positions and the second set of angular positions are defined according to the expected angular power distribution of the incident light.

177. The system of claim 176, wherein the at least one expected angular power distribution of the incident light includes the expected angular physical distribution of the incident light.

178. The system of claim 176, wherein the at least one expected angular power distribution of the incident light includes the expected statistical variation of the angular distribution of the incident light.

179. The system of claim 176, wherein the at least one expected angular power distribution of the incident light includes the expected temporal variation of angular distribution of the incident light.

180. The system of claim 175, wherein the first set of angular positions and the second set of angular positions are defined according to the expected angular power distribution of the light processed by at least one optical device.

181. The system of claim 180, wherein the at least one expected angular power distribution of the incident light includes the expected angular physical distribution of the light processed by at least one optical device.

182. The system of claim 180, wherein the at least one expected angular power distribution of the incident light includes the expected statistical variation of the angular distribution of the light processed by at least one optical device.

183. The system of claim 180, wherein the at least one expected angular power distribution of the incident light includes the expected temporal variation of the angular distribution of the light processed by at least one optical device.

184-217. (canceled)
